(19) United States
(12) Patent Application Publication
(10) Pub. No.: US 2015/0318508 A1
(43) Pub. Date: Nov. 5, 2015

(54) ORGANIC LIGHT-EMITTING DEVICE

(71) Applicant: SAMSUNG DISPLAY CO., LTD., Yongin-City (KR)

(72) Inventors: Seul-Ong KIM, Yongin-City (KR); Youn-Sun KIM, Yongin-City (KR); Dong-Woo SHIN, Yongin-City (KR); Jung-Sub LEE, Yongin-City (KR); Naoyuki ITO, Yongin-City (KR)

(21) Appl. No.: 14/458,582

(22) Filed: Aug. 13, 2014

(30) Foreign Application Priority Data
May 2, 2014 (KR) 10-2014-0053614

(51) Int. Cl. H01L 51/50; H01L 27/32; H01L 51/52

(52) U.S. Cl. CPC H01L 51/5008; H01L 51/5206; H01L 27/3248; H01L 51/5221; H01L 51/5016; H01L 51/5088; H01L 51/5056; H01L 51/5096; H01L 51/5072; H01L 51/5092; H01L 51/0072

(57) ABSTRACT

An OLED and a flat panel display, the OLED including an anode; a cathode; and an organic, the organic layer including an EML, the EML including first and second hosts, a hole transport region between the anode and the EML and including at least one of a hole injection layer (HIL), a hole transport layer (HTL), a buffer layer, or an electron blocking layer (EBL), an electron transport region between the EML and the cathode, the electron transport region including at least one of a hole blocking layer (HBL), an electron transport layer (ETL), or an electron injection layer (EIL), and an intermediate layer between the EML and the electron transport region; wherein an electron affinity of a compound of the intermediate layer [EA_{intermediate layer}] and an electron affinity of the first host [EAₕₒₛₜ₁] satisfy a relationship represented by the following expression:

EA_{intermediate layer}≧EAₕₒₛₜ₁+0.3 eV.

### RELATED APPLICATIONS

Korean Patent Application No. 10-2014-0053614, filed on May 2, 2014, in the Korean Intellectual Property Office, and entitled: “Organic Light-Emitting Device,” is incorporated by reference herein in its entirety.

### BACKGROUND

1. Field

Embodiments relate to an organic light-emitting device.

2. Description of the Related Art

Organic light-emitting devices (OLEDs), which are self-emitting devices, may have advantages such as wide viewing angles, excellent contrast, quick response, high brightness, excellent driving voltage characteristics, and may provide multicolored images.

An organic light-emitting device may have a structure of a first electrode, a hole transport region, an emission, an electron transport region, and a second electrode that are sequentially stacked on a substrate. Holes injected from the first electrode may move to the emission layer via the hole transport region, and electrons injected from the second electrode may move to the emission layer via the electron transport region. Carriers, such as the holes and electrons, may recombine in the emission layer to generate excitons. When the excitons drop from an excited state to a ground state, light is emitted.

### SUMMARY

Embodiments are directed to an organic light-emitting device.

The embodiments may provide a novel organic light-emitting device.

According to one or more embodiments, an organic light-emitting device that includes an anode; a cathode; and an organic layer that is disposed between the anode and the cathode and includes an emission layer, wherein the organic layer includes i) a hole transport region that is disposed between the anode and the emission layer and includes at least one selected from a hole injection layer, a hole transport layer, a buffer layer, and an electron blocking layer; and ii) an electron transport region that is disposed between the emission layer and the cathode and includes at least one selected from a hole blocking layer, an electron transport layer, and an electron injection layer;

an intermediate layer is disposed between the emission layer and the electron transport region;

the emission layer includes a first host and s second host; and

an electron affinity of a compound of the intermediate layer [EA_{intermediate layer}] and an electron affinity of the first host [EAₕₒₛₜ₁] satisfy a relationship represented by the following expression:

EA_{intermediate layer}≧EAₕₒₛₜ₁+0.3 eV

According to another embodiment, a flat panel display apparatus includes the organic light-emitting device, wherein the first electrode of the organic light-emitting device is electrically connected to a source electrode or a drain electrode.

### BRIEF DESCRIPTION OF THE DRAWING

Features will be apparent to those of skill in the art by describing in detail exemplary embodiments with reference to the attached drawing in which:

FIG. 1 illustrates a schematic view of a structure of an organic light-emitting device according to an embodiment.

### DETAILED DESCRIPTION

Example embodiments will now be described more fully hereinafter with reference to the accompanying drawing; however, they may be embodied in different forms and should not be construed as limited to the embodiments set forth herein. Rather, these embodiments are provided so that this disclosure will be thorough and complete, and will fully convey exemplary implementations to those skilled in the art.

In the drawing figures, the dimensions of layers and regions, may be exaggerated for clarity of illustration. Like reference numerals refer to like elements throughout.

As used herein, the term “and/or” includes any and all combinations of one or more of the associated listed items. Expressions such as “at least one of,” when preceding a list of elements, modify the entire list of elements and do not modify the individual elements of the list.

According to an embodiment, an organic light-emitting device may include an anode; a cathode; and an organic layer between the anode and the cathode. The organic layer may include an emission layer (EML).

In an implementation, the organic layer may include i) a hole transport region between the anode and the EML and includes at least one selected from a hole injection layer (HIL), a hole transport layer (HTL), a buffer layer, and an electron blocking layer (EBL) and ii) an electron transport region between the EML and the cathode and includes at least one selected from a hole blocking layer (HBL), an electron transport layer (ETL), and an electron injection layer (EIL);

In an implementation, an intermediate layer may be between the EML and the electron transport region.

The EML may include a first host and a second host.

An electron affinity of a compound of the intermediate layer [EA_{intermediate layer}] and an electron affinity of the first host [EAₕₒₛₜ₁] may satisfy a relationship represented by the following expression:

EA_{intermediate layer}≧EAₕₒₛₜ₁+0.3 eV

The organic light-emitting device according to an embodiment may include a first host and a second host in the EML. The EML may include the first host having a relatively low electron affinity so that electrons being transported to the HTL are efficiently blocked; and the second host having a relatively high electron affinity so that electrons are easily injected from an electron injection region and an electron transportation region. In an implementation, an intermediate layer of high EA (that efficiently blocks the electron delivery to the first host, and simultaneously facilitates the electron injection to the second host) may be additionally introduced between the ETL and the EML.

In this regard, most electrons delivered from the cathode may be injected to the host having a high electron affinity, and accordingly, an increase in the driving voltage of the organic light-emitting device and the recombination of the holes and electrons occurring intensely on a side of the cathode may be prevented. Then, the emission efficiency and the emission lifespan of the organic light-emitting device may also be prevented. At the same time, the first host having a low electron affinity may help efficiently block the electrons being transported to the HTL, thereby maximizing the emission efficiency of the organic light-emitting device

Materials for the first host and the material of the intermediate layer may have a difference of at least 0.3 eV electron injection barriers, e.g., at least 0.5 eV electron injection barriers. When the electron injection barriers differ by less than the above range, the electrons may not be efficiently blocked, but transported to the HTL. For example, excitons may not be efficiently confined within the EML, thereby possibly degrading the emission efficiency of the organic light-emitting device. In this regard, the electrons that are supposed to have a difference of at least 0.3 eV barrier may be easily injected to the second host having a high electron affinity, while the residual electrons that are blocked by the first host having a low electron affinity may remain long or for extended periods within the EML. Thus, emission regions may be evenly distributed over the entire EML, and accordingly, the organic light-emitting device may improve efficiency and lifespan thereof.

A compound in which a backbone structure of an aromatic hydrocarbon having at least 3 condensed polycyclic rings is substituted with a heteroaryl group may be a suitable material for the intermediate layer. For example, a material having such a structure may have a suitable electron affinity to facilitate configuration of the organic light-emitting device according to an embodiment. The heteroaryl group may be, e.g., pyridine, pyrimidine, pyrazine, triazine, quinoline, isoquinoline, quinazoline, or quinoxaline. In regard to a structure of the corresponding heteroaryl group above, the heteroaryl group may have a N-containing heteroring, which may facilitate transportation of the electrons. In addition, the intermediate layer may be positioned on a side of the ETL, and appropriate transportation of the electrons may also be necessary in consideration of balance of the whole organic light-emitting device.

In an exemplary embodiment, the EML may be a phosphorescent EML.

In an exemplary embodiment, the EML may be a phosphorescent EML, and the phosphorescent EML may include a dopant that emits phosphorescence having a main peak of at least 450 nm.

The dopant may be, e.g, a compound capable of emitting phosphorescence having a main peak in a range of about 450 nm to about 700 nm.

In an exemplary embodiment, the electron affinity of the first host (EAₕₒₛₜ₁) and an electron affinity of the second host (EAₕₒₛₜ₂) may satisfy a relationship represented by the following expression:

EAₕₒₛₜ₁<EAₕₒₛₜ₂

In an exemplary embodiment, the intermediate layer may contact the EML and may include a compound in which an aromatic heteroaryl group having 3 or fewer nitrogen atoms is substituted with a backbone structure of an aromatic hydrocarbon having at least 3 condensed polycyclic rings.

In an exemplary embodiment, a compound for the HTL may have an ionization potential in a range of 5.3 eV to about 5.8 eV.

In an exemplary embodiment, the EML may be a phosphorescent EML and may include an Ir-complex, a Pt-complex, an Os-complex, or a Cu-complex as a dopant.

In an exemplary embodiment, a compound for the intermediate layer may be represented by Formula 1 or 2 below:

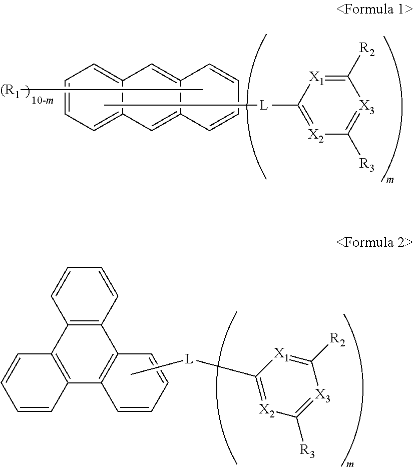

In Formula 1 or 2, X₁ to X₃ may be each independently CR₄ or N, and at least one of X₁ to X₃ may be N.

L may be a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₆-C₆₀ arylene group, or a substituted or unsubstituted C₂-C₆₀ heteroarylene group.

R₁ to R₄ may be each independently a hydrogen, a deuterium, a halogen atom, a cyano group, a thiol group, a substituted or unsubstituted C₁-C₆₀ alkyl group, a substituted or unsubstituted C₁-C₆₀ alkoxy group, a substituted or unsubstituted C₂-C₆₀ alkenyl group, a substituted or unsubstituted C₆-C₆₀ aryl group, a substituted or unsubstituted C₆-C₆₀ aryloxy group, a substituted or unsubstituted C₁-C₆₀ heteroalkyl group having at least one selected from sulfur (S), nitrogen (N), oxygen (O), phosphorous (P), and silicon (Si), a substituted or unsubstituted C₂-C₆₀ heteroaryl group, or a substituted or unsubstituted C₂-C₆₀ heteroaryloxy group.

m may be an integer of 1 to 9.

In an implementation, adjacent substituents of to R₂ to R₄ may link together and form a ring.

In an exemplary embodiment, R₁ to R₄ may be each independently a hydrogen, a deuterium, a substituted or unsubstituted C₁-C₃₀ alkyl group, or a group represented by one of Formulae 2a to 2x below:

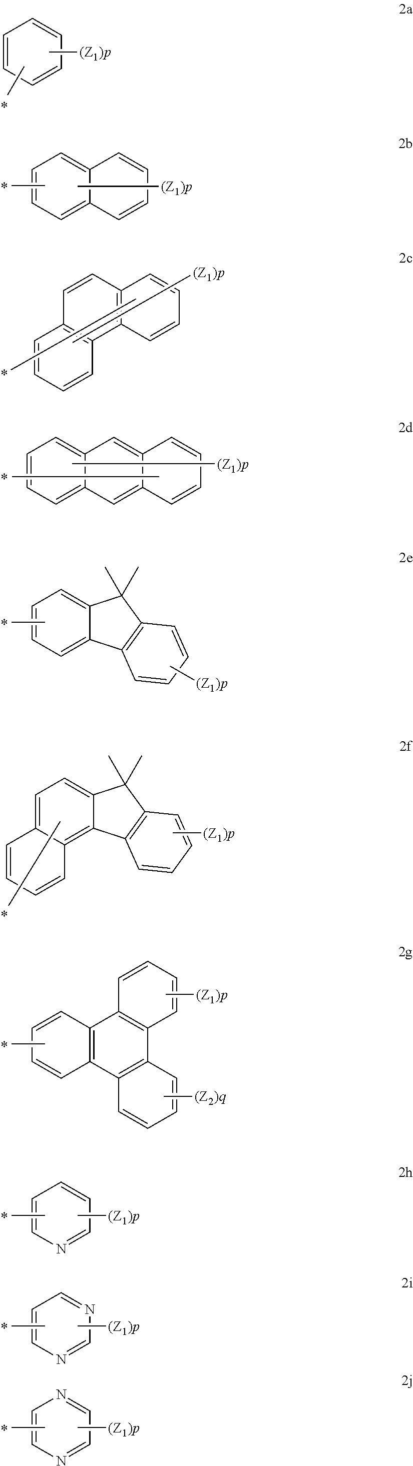

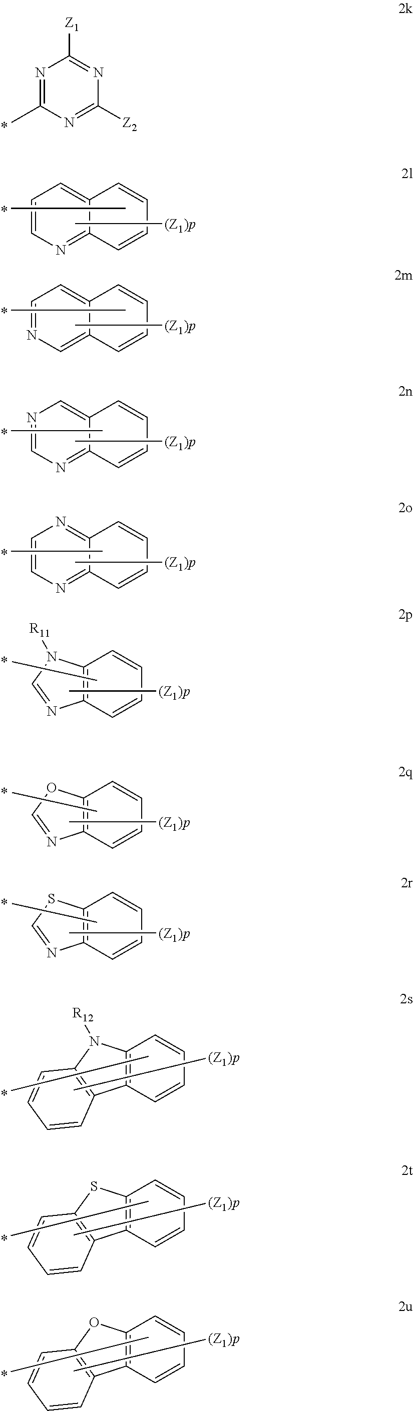

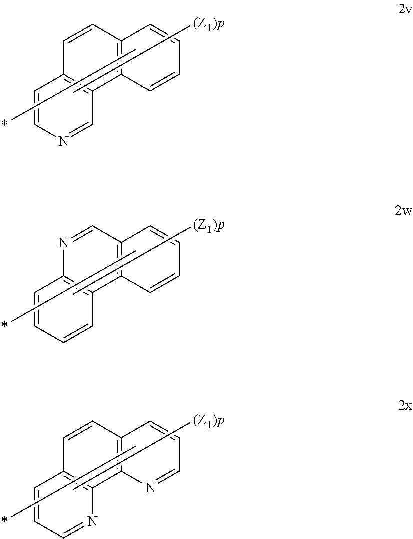

In Formulae 2a to 2x, R₁₁, R₁₂, Z₁, and Z₂ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted monovalent non-aromatic condensed polycyclic group, and a substituted or unsubstituted monovalent non-aromatic hetero-condensed polycyclic group.

p and q may be each independently an integer of 1 to 9.

In an implementation, when p and q are 2 or greater, a plurality of Z₁ and Z₂ may be identical to or different from each other.

* indicates a binding site with a neighboring atom.

In an exemplary embodiment, L may be a single bond or a group represented by one of Formulae 3a to 3x below:

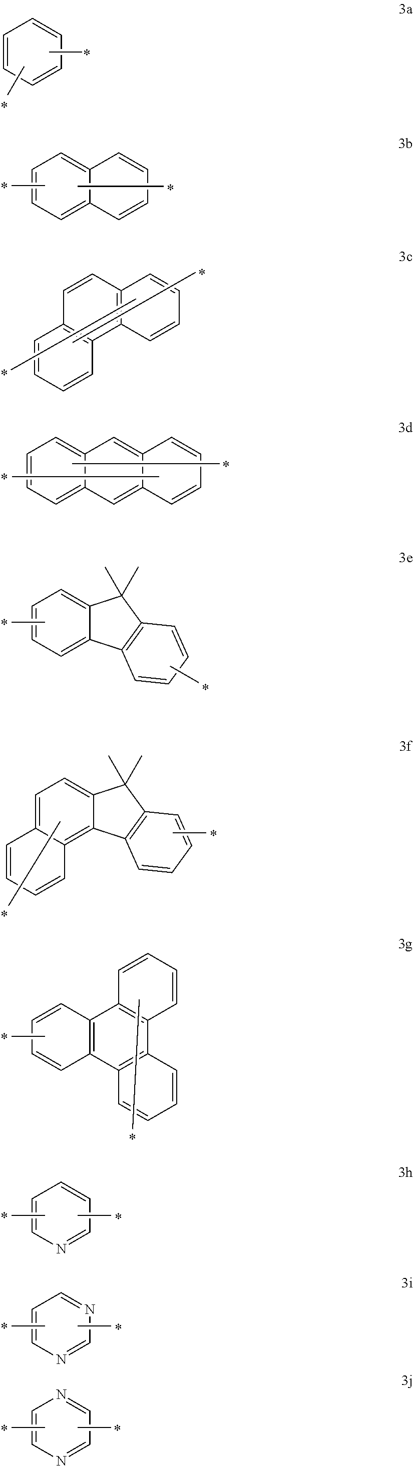

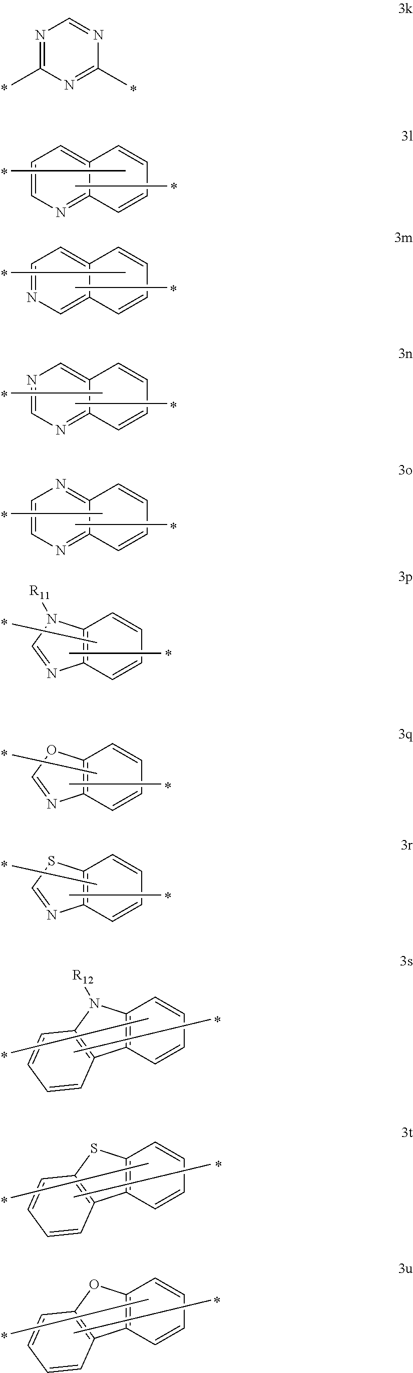

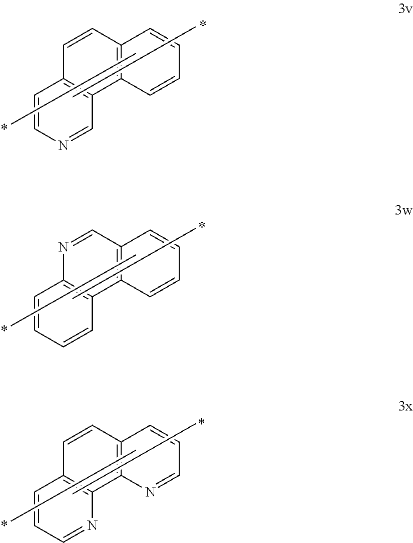

In Formulae 3a to 3x, R₁₁ and R₁₂ may be each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted non-aromatic condensed polycyclic group, and a substituted or unsubstituted monovalent non-aromatic hetero-condensed polycyclic group.

* indicates a binding site with a neighboring atom.

m may be an integer of 1 or 2, e.g., m may be 1 or 2.

In an exemplary embodiment, the compound represented by Formula 1 may be represented by Formula 3 below:

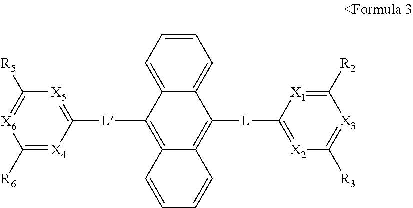

In Formula 3, R₅, R₆, X₄ to X₆, and L′ may be defined the same as the definition of R₁ to R₄, X₁ to X₃, and L described above with respect to Formula 1. For example, R₅ and R₆ may be defined the same as R₁ to R₄, X₄ to X₆ may be defined the same as X₁ to X₃, and L′ may be defined the same as L.

Hereinafter, definitions of representative substituents used herein will now be described (In this regard, the number of carbons restricting a substituent is not limited, and does not limit properties of the substituent, and unless defined otherwise, the definition of the substituent is consistent with a general definition thereof).

As used herein, a C₁-C₆₀ alkyl group denotes a monovalent linear or branched aliphatic hydrocarbon group, and detailed examples of thereof include a methyl group, an ethyl group, a propyl group, an isobutyl group, a sec-butyl group, a tert-butyl group, a pentyl group, an iso-amyl group, and a hexyl group. As used herein, a C₁-C₆₀ alkylene group includes a divalent group that has the same structure as the C₁-C₆₀ alkyl group.

As used herein, a C₁-C₆₀ alkoxy group denotes a monovalent group having a formula of —OA₁₀₁ (here, A₁₀₁ is the C₁-C₆₀ alkyl group), and detailed examples thereof include a methoxy group, an ethoxy group, and an isopropyloxy group.

As used herein, a C₂-C₆₀ alkenyl group has a structure including at least one carbon-carbon double bond in the middle or at an end of the C₂-C₆₀ alkyl group, and detailed examples of the C₂-C₆₀ alkenyl group include an ethenyl group, a propenyl group, and a butenyl group. As used herein, a C₂-C₆₀ alkenylene group denotes a divalent group that has the same structure as the C₂-C₆₀ alkenyl group.

As used herein, a C₂-C₆₀ alkynyl group has a structure including at least one carbon-carbon triple bond in the middle or at an end of the C₂-C₆₀ alkyl group, and detailed examples thereof include an ethynyl group and a propynyl group. As used herein, a C₂-C₆₀ alkynylene group denotes a divalent group that has the same structure as the C₂-C₆₀ alkynyl group.

As used herein, a C₃-C₁₀ cycloalkyl group denotes a C₃-C₁₀ monovalent saturated hydrocarbon monocyclic group, and detailed examples thereof include a cyclopropyl group, a cyclobutyl group, a cyclopentyl group, a cyclohexyl group, and a cycloheptyl group. As used herein, a C₃-C₁₀ cycloalkylene group denotes a divalent group that has the same structure as the C₃-C₁₀ cycloalkyl group.

As used herein, the C₂-C₁₀ heterocycloalkyl group denotes a C₂-C₁₀ monovalent monocyclic group including at least one hetero atom selected from N, O, P, and S as a ring-forming atom, and detailed examples of the C₂-C₁₀ heterocycloalkyl group include a tetrahydrofuranyl group and a tetrahydrothiophenyl group. As used herein, a C₂-C₁₀ heterocycloalkylene group denotes a divalent group that has the same structure as the C₂-C₁₀ heterocycloalkyl group.

As used herein, a C₃-C₁₀ cycloalkenyl group denotes a C₃-C₁₀ monovalent monocyclic group having at least one double bond in the ring while not losing its aromacity, and detailed examples of the C₃-C₁₀ cycloalkenyl group include a cyclopentyl group, a cyclohexenyl group, and a cycloheptenyl group. As used herein, the C₃-C₁₀ cycloalkenylene group denotes a divalent group that has the same structure as the C₃-C₁₀ cycloalkenyl group.

As used herein, a C₂-C₁₀ heterocycloalkenyl group denotes a C₂-C₁₀ monovalent monocyclic group including at least one hetero atom selected from N, O, P, and S as a ring-forming atom and at least one double bond in the ring, and detailed examples of the C₂-C₁₀ heterocycloalkenyl group include a 2,3-hydrofuranyl group and a 2,3-hydrothiophenyl group. As used herein, a C₂-C₁₀ heterocycloalkenylene group denotes a divalent group that has the same structure as the C₂-C₁₀ heterocycloalkenyl group.

As used herein, a C₆-C₆₀ aryl group denotes a monovalent group having a C₆-C₆₀ carbocyclic aromatic system, and a C₆-C₆₀ arylene group denotes a divalent group that has a C₆-C₆₀ carbocyclic aromatic system. Detailed examples of the C₆-C₆₀ aryl group include a phenyl group, a naphthyl group, an anthracenyl group, a phenanthrenyl group, a pyrenyl group, and a chrysenyl group. When the C₆-C₆₀ aryl group and the C₆-C₆₀ arylene group include two or more rings, the rings may be fused to each other.

As used herein, a C₂-C₆₀ heteroaryl group denotes a monovalent group including at least one heteroatom selected from N, O, P, and S as a ring-forming atom and having a C₂-C₆₀ carbocyclic aromatic system, and a C₁-C₆₀ heteroarylene group denotes a divalent group including at least one heteroatom selected from N, O, P, and S as a ring-forming atom and having a C₂-C₆₀ carbocyclic aromatic system. Detailed examples of the C₁-C₆₀ heteroaryl group include a pyridinyl group, a pyrimidinyl group, a pyrazinyl group, a pyridazinyl group, a triazinyl group, a quinolinyl group, and an isoquinolinyl group. When the C₂-C₆₀ heteroaryl group and a C₂-C₆₀ heteroarylene group include at two or more rings, the rings may be fused to each other.

As used herein, a C₆-C₆₀ aryloxy group denotes —OA₁₀₂ (here, A₁₀₂ is the C₆-C₆₀ aryl group), and a C₆-C₆₀ arylthio group denotes —SA₁₀₃ (here, A₁₀₃ is the C₆-C₆₀ aryl group).

As used herein, a monovalent non-aromatic condensed polycyclic group denotes a monovalent group having two or more rings that are condensed to each other, including only carbon as a ring-forming atom (e.g., the number of the included carbon atoms may be 8 to 60), and having non-aromaticity, as a whole molecule. Detailed examples of the non-aromatic condensed polycyclic group include a fluorenyl group. As used herein, a divalent non-aromatic condensed polycyclic group denotes a divalent group that has the same structure as the monovalent non-aromatic condensed polycyclic group.

As used herein, a monovalent non-aromatic hetero-condensed polycyclic group denotes a monovalent group having two or more rings that are condensed to each other, including a hetero atom selected from N, O, P, and S in addition to carbon as a ring-forming atom (e.g., the number of the included carbon atoms included may be 2 to 60), and having non-aromacity as a whole molecule. An example of the non-aromatic hetero-condensed polycyclic group includes a carbazolyl group. As used herein, a divalent non-aromatic hetero-condensed polycyclic group denotes a divalent group that has the same structure as the monovalent non-aromatic hetero-condensed polycyclic group.

As used herein, at least one substituent of the substituted C₃-C₁₀ cycloalkylene group, the substituted C₂-C₁₀ heterocycloalkylene group, the substituted C₃-C₁₀ cycloalkenylene group, the substituted C₂-C₁₀ heterocycloalkenylene group, the substituted C₆-C₆₀ arylene group, the substituted C₂-C₆₀ heteroarylene group, the substituted divalent non-aromatic condensed polycyclic group, the substituted divalent non-aromatic hetero-condensed polycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₂-C₆₀ heteroaryl group, the substituted monovalent non-aromatic condensed polycyclic group, and the substituted monovalent non-aromatic hetero-condensed polycyclic group is selected from,

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy, a C₆-C₆₀ arylthio, a C₂-C₆₀ heteroaryl group, a monovalent non-aromatic condensed polycyclic group, a monovalent non-aromatic hetero-condensed polycyclic group, —N(Q₁₁)(Q₁₂)—Si(Q₁₃)(Q₁₄)(Q₁₅), and —B(Q₁₆)(Q₁₇);

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy, a C₆-C₆₀ arylthio, a C₂-C₆₀ heteroaryl group, a monovalent non-aromatic condensed polycyclic group, and a monovalent non-aromatic hetero-condensed polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy, a C₆-C₆₀ arylthio, a C₂-C₆₀ heteroaryl group, a monovalent non-aromatic condensed polycyclic group, and a monovalent non-aromatic hetero-condensed polycyclic group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy, a C₆-C₆₀ arylthio, a C₂-C₆₀ heteroaryl group, a monovalent non-aromatic condensed polycyclic group, a monovalent non-aromatic hetero-condensed polycyclic group, N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇); and

Q₁ to Q₇, Q₁₁ to Q₁₇, Q₂₁ to Q₂₇, and Q₃₁ to Q₃₇ are, each independently, selected from a hydrogen, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₂-C₆₀ heteroaryl group, a monovalent non-aromatic condensed polycyclic group, and a monovalent non-aromatic hetero-condensed polycyclic group.

For example, at least one substituent of the substituted C₃-C₁₀ cycloalkylene group, the substituted C₂-C₁₀ heterocycloalkylene group, the substituted C₃-C₁₀ cycloalkenylene group, the substituted C₂-C₁₀ heterocycloalkenylene group, the substituted C₆-C₆₀ arylene group, the substituted C₂-C₆₀ heteroarylene group, the substituted divalent non-aromatic condensed polycyclic group, the substituted divalent non-aromatic hetero-condensed polycyclic group, the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₂-C₁₀ heterocycloalkyl group, the substituted C₃-C₁₀ cycloalkenyl group, the substituted C₂-C₁₀ heterocycloalkenyl group, the substituted C₆-C₆₀ aryl group, the substituted C₆-C₆₀ aryloxy group, the substituted C₆-C₆₀ arylthio group, the substituted C₂-C₆₀ heteroaryl group, the substituted monovalent non-aromatic condensed polycyclic group, and the substituted monovalent non-aromatic hetero-condensed polycyclic group is selected from,

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₆₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a cyclopentyl group, a cyclohexyl group, a cycloheptyl group, a cyclopentenyl group, a cycloheptenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coroneryl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₁₁)(Q₁₂), —Si(Q₁₃)(Q₁₄)(Q₁₅), and —B(Q₁₆)(Q₁₇);

a cyclopentyl group, a cyclohexyl group, a cycloheptyl group, a cyclopentenyl group, a cycloheptenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coroneryl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

a cyclopentyl group, a cyclohexyl group, a cycloheptyl group, a cyclopentenyl group, a cycloheptenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coroneryl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cycloheptenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coroneryl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, an imidazopyrimidinyl group, —N(Q₂₁)(Q₂₂), —Si(Q₂₃)(Q₂₄)(Q₂₅), and —B(Q₂₆)(Q₂₇); and

—N(Q₃₁)(Q₃₂), —Si(Q₃₃)(Q₃₄)(Q₃₅), and —B(Q₃₆)(Q₃₇); and

Q₁ to Q₇, Q₁₁ to Q₁₇, Q₂₁ to Q₂₇, and Q₃₁ to Q₃₇ are, each independently, selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a cyclopentyl group, a cyclohexyl group, a cycloheptyl group, a cyclopentenyl group, a cycloheptenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coroneryl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group.

The term “Ph” used herein refers to a phenyl group, the term “Me” used herein refers to a methyl group, the term “Et” sed herein refers to an ethyl group, and the term “ter-Bu” or “Bu^{t}” used herein refers to a tert-butyl group.

The expression “(an organic layer) includes at least one condensed cyclic compound” used herein includes a case in which “(an organic layer) includes one condensed cyclic compound of Formula 1 or a case in which (an organic layer) includes two or more different condensed cyclic compounds of Formula 1”.

The term “organic layer” used herein denotes a single layer and/or all multi-layers disposed between the first electrode and the second electrode in the organic light-emitting device. A material included in a layer of the “organic layer” is not limited to an organic material.

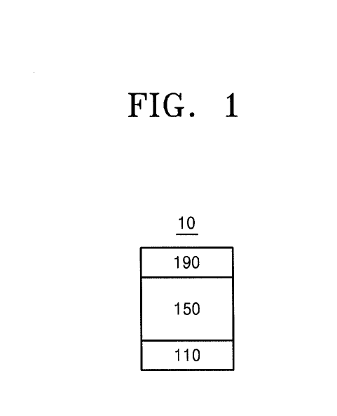

FIG. 1 schematically illustrates a cross-sectional view of an organic light-emitting device 10 according to an embodiment. The organic light-emitting device 10 may include a first electrode 110, an organic layer 150, and a second electrode 190.

Hereinafter, a structure and a preparation method of an organic light-emitting device are described by referring to FIG. 1.

A substrate may be additionally disposed on a lower part of the first electrode 110 or an upper part of the second electrode 190 of the organic light-emitting device 10 shown in FIG. 1. The substrate may be a glass substrate or a transparent plastic substrate having excellent mechanical strength, thermal stability, transparency, surface smoothness, ease of handling, and water resistance.

The first electrode 110 may be formed by, e.g., depositing or sputtering a first electrode material on the substrate. When the first electrode 110 is an anode, the first electrode material may be selected from materials having a high work function to facilitate hole injection. The first electrode 110 may be a reflective electrode, a semi-transmissive (e.g., semi-transparent) electrode, or a transmissive (e.g., transparent) electrode. Examples of the first electrode material may include indium-tin oxide (ITO), indium-zinc-oxide (IZO), tin oxide (SnO₂), and zinc oxide (ZnO). Also, at least one selected from magnesium (Mg), aluminum (Al), aluminum-lithium (Al—Li), a Calcium (Ca), magnesium-indium (Mg—In), and magnesium-silver (Mg—Ag) may be selected as the first electrode material to form the first electrode 110 as a semi-transmissive electrode or a transmissive electrode.

The first electrode 110 may have a single-layered structure or a multi-layered structure including a plurality of layers. For example the first electrode 110 may have a three-layered structure of ITO/Ag/ITO, but a structure of the first electrode 110 is not limited thereto.

The organic layer 150 is disposed on the first electrode 110. The organic layer 150 includes an EML.

The organic layer 150 may further include a hole transport region that is disposed between the first electrode 110 and the EML, an electron transport region that is disposed between the EML and the second electrode 190, and an intermediate layer that is disposed between the EML and the electron transport region.

The hole transport region may include at least one selected from an HIL, an HTL, a buffer layer, and an EBL, and the electron transport region may include at least one selected from an HBL, an ETL, and an EIL, but the hole transport region and the electron transport region are not limited thereto.

The hole transport region may have a single-layered structure formed of one material, a single-layered structure formed of a plurality of different materials, or a multiple-layered structure formed of a plurality of different materials.

For example, the hole transport region may have a single-layered structure formed of a plurality of different materials or a structure of HIL/HTL, a structure of HIL/HTL/buffer layer, a structure of HIL/buffer layer, a structure of HTL/buffer layer, or a structure of HIL/HTL/EBL, wherein layers of each structure are sequentially stacked on the first electrode in the stated order, but a structure of the hole transport region is not limited thereto.

When the hole transport region includes an HIL, the HIL may be formed on the first electrode 110 by using various methods such as vacuum deposition, spin coating, casting, Langmuir-Blodgett (LB) deposition, inkjet printing, laser printing, or laser induced thermal imaging (LITI).

When the HIL is formed by vacuum deposition, the deposition conditions may be selected from ranges of, for example, a deposition temperature of about 100° C. to about 500° C., a degree of vacuum of about 10⁻⁸ to about 10⁻³ torr, and a deposition speed of about 0.01 to about 100 Å/sec in consideration of a desired compound for the HIL and a desired structure of the HIL.

When the HIL is formed by spin coating, the coating conditions may be selected from ranges of, for example, a coating speed of about 2,000 rpm to about 5,000 rpm and a heat treatment temperature of about 80° C. to about 200° C. in consideration of a desired compound for the HIL and a desired structure of the HIL.

When the hole transport region includes the HTL, the HTL may be formed on the first electrode 110 or on the HIL by using various methods such as vacuum deposition, spin coating, casting, LB deposition, inkjet printing, laser printing, or LITI. When the HTL is formed by vacuum deposition and spin coating, the deposition conditions and the coating conditions of the HTL may be referred to the deposition conditions and the coating conditions of the HIL.

The hole transport region may include at least one of m-MTDATA, TDATA, 2-TNATA, NPB, β-NPB, TPD, Spiro-TPD, Spiro-NPB, α-NPB, TAPC, HMTPD, 4,4′,4″-tris(N-carbazolyl)triphenylamine) (TCTA), polyaniline/Dodecylbenzenesulfonic acid (Pani/DBSA), poly(3,4-ethylenedioxythiophene)/poly(4-styrenesulfonate) (PEDOT/PSS), polyaniline/camphor sulfonicacid (Pani/CSA), polyaniline)/poly(4-styrenesulfonate (PANI/PSS), a compound represented by Formula 201, and a compound represented by Formula 202:

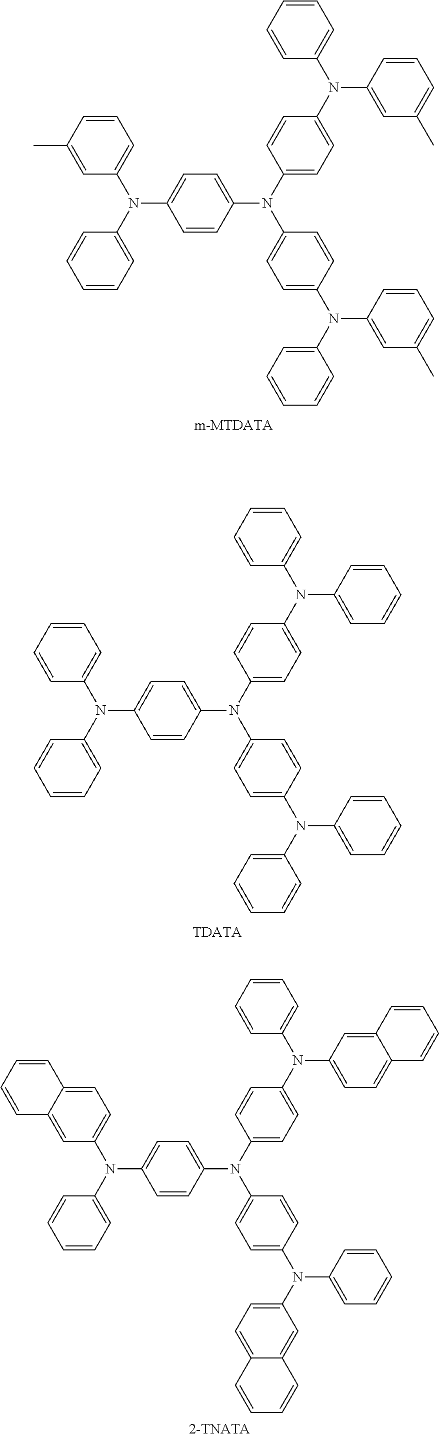

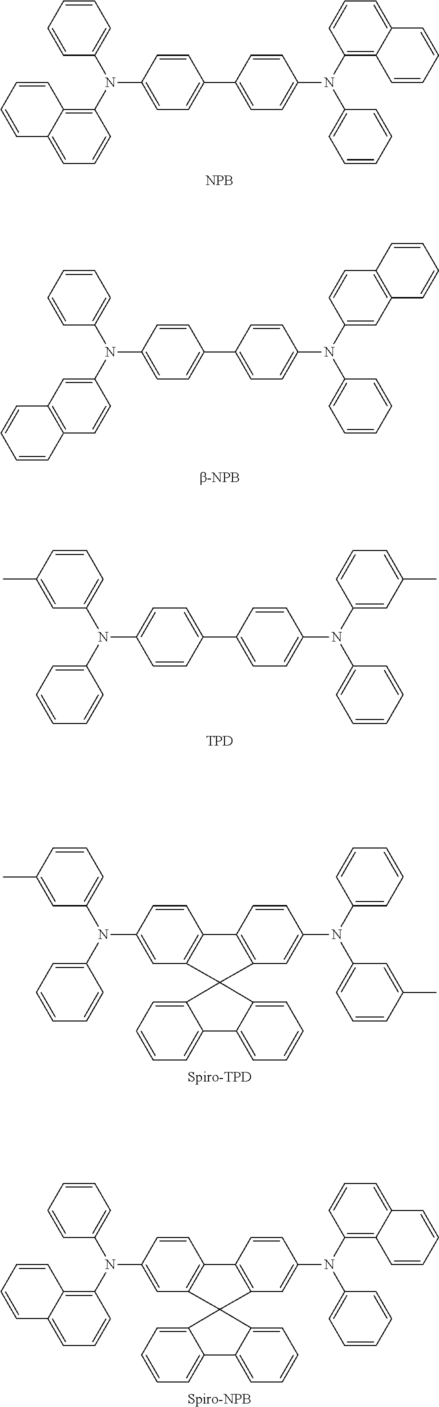

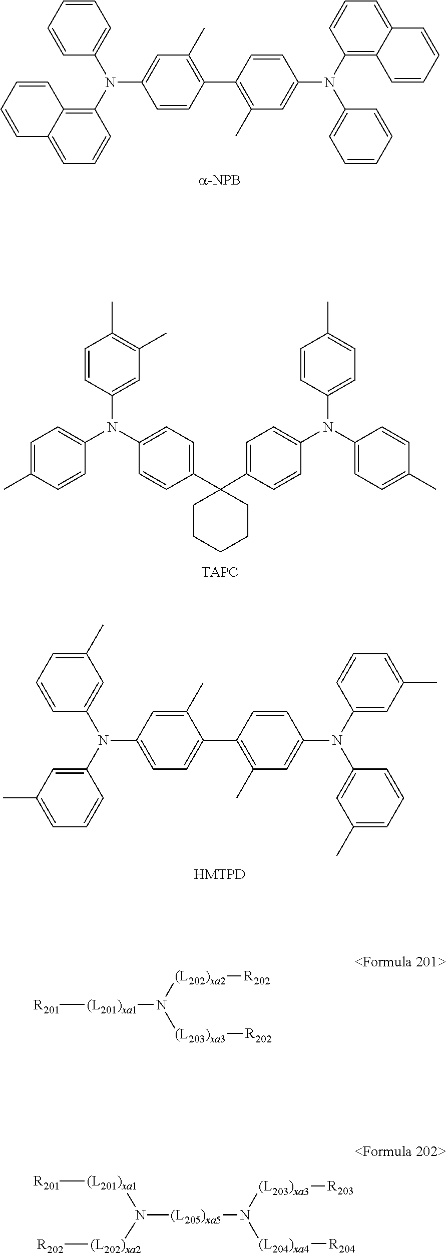

In Formulae 201 and 202, descriptions of L₂₀₁ to L₂₀₅ may be each independently defined the same as L in Formula 1, above.

xa1 to xa4 may be each independently an integer of 0, 1, 2, and 3.

xa5 may be an integer of 1, 2, 3, 4, and 5.

R₂₀₁ to R₂₀₄ may be each independently selected from a substituted or unsubstituted C₃-C₁₀ cycloalkyl group, a substituted or unsubstituted C₂-C₁₀ heterocycloalkyl group, a substituted or unsubstituted C₃-C₁₀ cycloalkenyl group, a substituted or unsubstituted C₂-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₂-C₆₀ heteroaryl group, a substituted or unsubstituted monovalent non-aromatic condensed polycyclic group, and a substituted or unsubstituted monovalent non-aromatic hetero-condensed polycyclic group.

For example, in Formulae 201 and 202,

L₂₀₁ to L₂₀₅ may be each independently selected from:

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, an isoindolyl group, a quinolinyl group, an isoquinolinyl group, a quinoxalinyl group, a quinazolinyl group, a carbazolyl group, and a triazinyl group;

xa1 to xa4 may be each independently an integer selected from 0, 1, and 2;

xa5 may be an integer selected from 1, 2, and 3;

R₂₀₁ to R₂₀₄ may be each independently selected from, but are not limited to,

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, an azulenyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group.

The compound represented by Formula 201 may be represented by Formula 201A below, but the compound is not limited thereto:

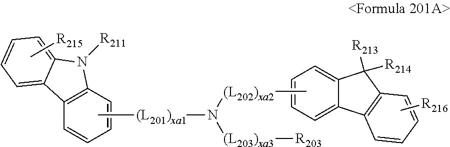

For example, the compound represented by Formula 201 may be represented by Formula 201A-1 below:

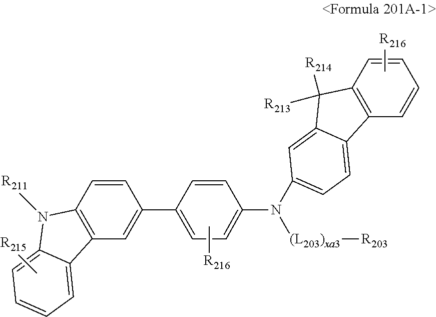

The compound represented by Formula 202 may be represented by Formula 202A below, but the compound is not limited thereto:

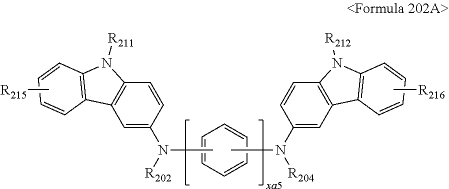

In Formulae 201A, 201A-1, and 202A,

descriptions of L₂₀₁ to L₂₀₃, xa1 to xa3, xa5, and R₂₀₂ to R₂₀₄ may be the same as described above, description of R₂₁₁ may be defined the same as R₂₀₃, R₂₁₃ to R₂₁₆ may be each independently selected from, but are not limited to, a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group.

For example, in Formula 201A, 201A-1, and 202A,

L₂₀₁ to L₂₀₃ may be each independently selected from,

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group; and

a phenylene group, a naphthylene group, a fluorenylene group, a spiro-fluorenylene group, a benzofluorenylene group, a dibenzofluorenylene group, a phenanthrenylene group, an anthracenylene group, a pyrenylene group, a chrysenylene group, a pyridinylene group, a pyrazinylene group, a pyrimidinylene group, a pyridazinylene group, a quinolinylene group, an isoquinolinylene group, a quinoxalinylene group, a quinazolinylene group, a carbazolylene group, and a triazinylene group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xa1 to xa3 may be each independently 0 or 1;

R₂₀₃, R₂₁₁, and R₂₁₂ may be each independently selected from,

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₃ and R₂₁₄ may be each independently selected from,

a C₁-C₂₀ alkyl group and a C₁-C₂₀ alkoxy group;

a C₁-C₂₀ alkyl group and a C₁-C₂₀ alkoxy group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

R₂₁₅ and R₂₁₆ may be each independently selected from,

a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, and a C₁-C₂₀ alkoxy group;

a C₁-Cₘ alkyl group and a C₁-C₂₀ alkoxy group, each substituted with at least one selected from a deuterium, —F, —CI, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

xa5 may be an integer selected from 1 and 2.

In Formulae 201A and 201A-1, R₂₁₃ and R₂₁₄ may link to each other and form a saturated ring or an unsaturated ring.

The compound represented by Formula 201 and the compound represented by Formula 202 may each independently include Compounds HT1 to HT20 below, but the compounds are not limited thereto:

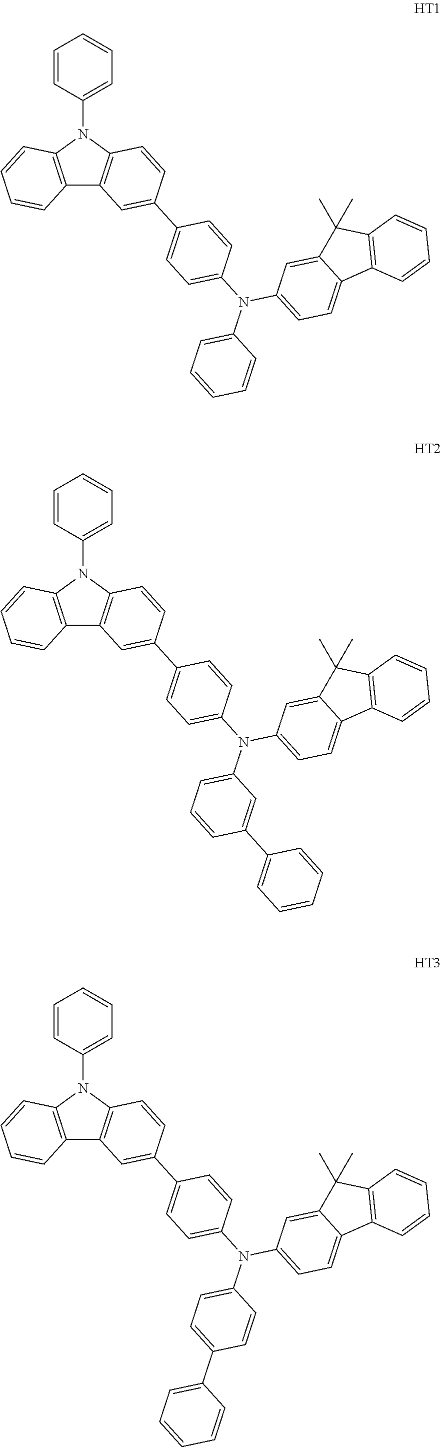 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21]

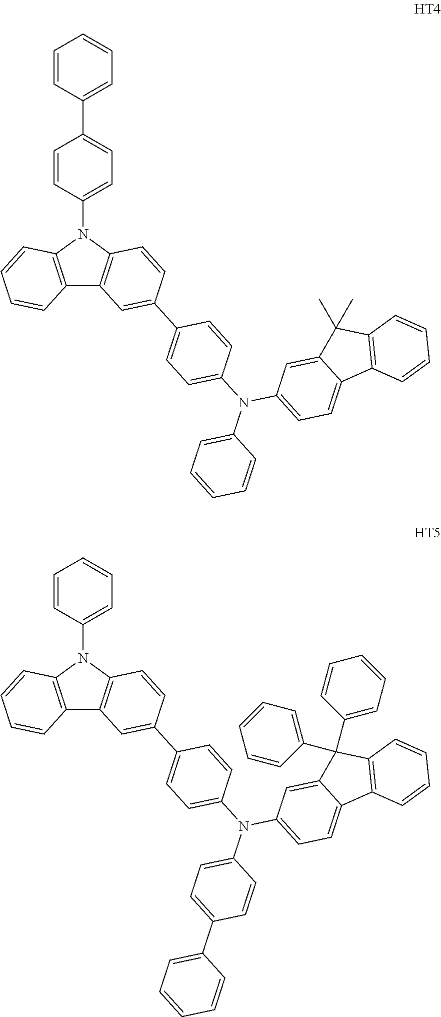 [SMILES: CC1(C)c2ccccc2-c2ccc(N(c3ccccc3)c3ccc(-c4ccc5c(c4)c4ccccc4n5-c4ccc(-c5ccccc5)cc4)cc3)cc21 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

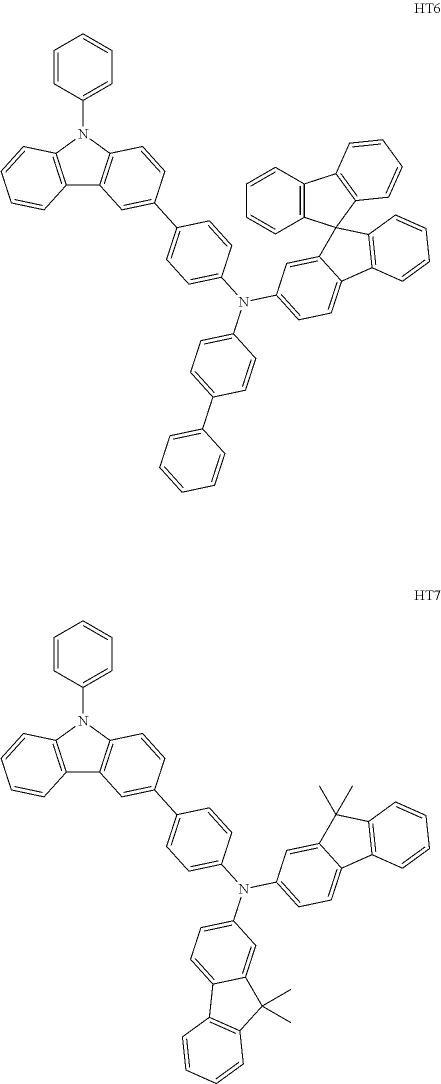 [SMILES: c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1 ; CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21]

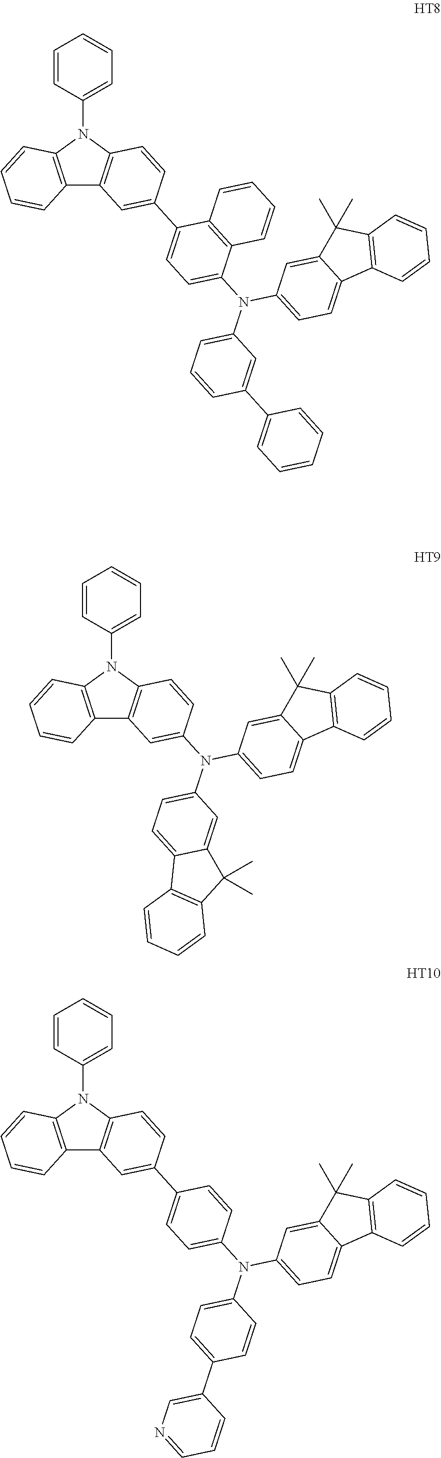 [SMILES: CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; CC1(C)c2ccccc2-c2ccc(N(c3ccc(-c4cccnc4)cc3)c3ccc(-c4ccc5c(c4)c4ccccc4n5-c4ccccc4)cc3)cc21]

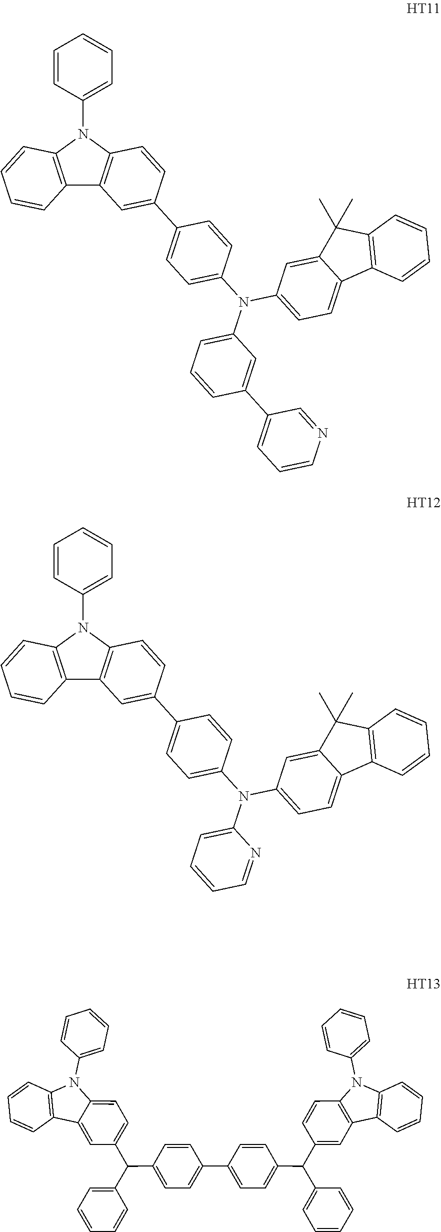 [SMILES: CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(C(c2ccc(-c3ccc(C(c4ccccc4)c4ccc5c(c4)c4ccccc4n5-c4ccccc4)cc3)cc2)c2ccc3c(c2)c2ccccc2n3-c2ccccc2)cc1]

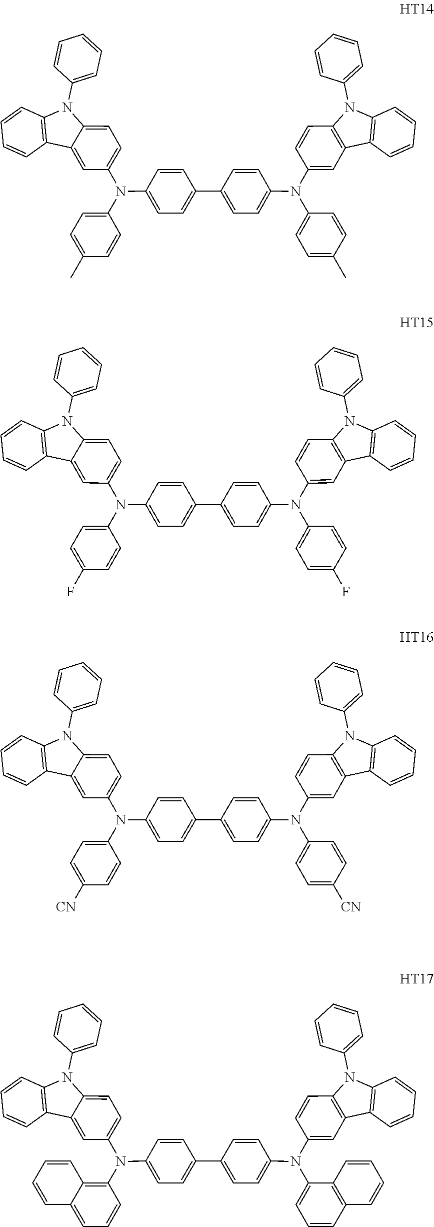

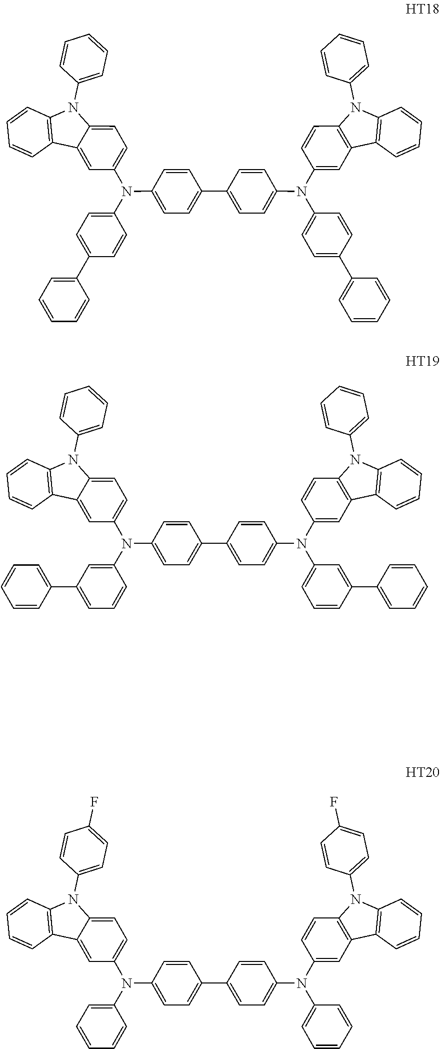 [SMILES: c1ccc(-c2ccc(N(c3ccc(-c4ccc(N(c5ccc(-c6ccccc6)cc5)c5ccc6c(c5)c5ccccc5n6-c5ccccc5)cc4)cc3)c3ccc4c(c3)c3ccccc3n4-c3ccccc3)cc2)cc1 ; c1ccc(-c2cccc(N(c3ccc(-c4ccc(N(c5cccc(-c6ccccc6)c5)c5ccc6c(c5)c5ccccc5n6-c5ccccc5)cc4)cc3)c3ccc4c(c3)c3ccccc3n4-c3ccccc3)c2)cc1 ; Fc1ccc(-n2c3ccccc3c3cc(N(c4ccccc4)c4ccc(-c5ccc(N(c6ccccc6)c6ccc7c(c6)c6ccccc6n7-c6ccc(F)cc6)cc5)cc4)ccc32)cc1]

A thickness of the hole transport region may be about 100 Å to about 10,000 Å, e.g., about 100 Å to about 1,000 Å. When the hole transport region includes both the HIL and the HTL, a thickness of the HIL may be about 100 Å to about 10,000 Å, e.g., about 100 Å to about 1,000 Å, and a thickness of the HTL may be about 50 Å to about 2,000 Å, e.g., about 100 Å to about 1,500 Å. When thicknesses of the hole transport region, the HIL, and the HTL are within these ranges, satisfactory hole transporting properties of the organic light-emitting device may be obtained without a substantial increase in driving voltage.

The hole transport region may further include a charge-generating material in addition to the materials above to help improve conductivity. The charge-generating material may be homogenously or unhomogenously (e.g., heterogeneously) dispersed in the hole transport region.

The charge-generating material may be, e.g., a p-dopant. The p-dopant may be, e.g., one of a quinone derivative, a metal oxide, and a cyano group-containing compound, but the p-dopant is not limited thereto. Examples of the p-dopant may include a quinone derivative, such as a tetracyanoquinonedimethane (TCNQ) and 2,3,5,6-tetrafluoro-tetracyano-1,4-benzoquinondimethane (F4-TCNQ); a metal oxide, such as a tungsten oxide or a molybdenum oxide; and Compound HT-D1 below, but the examples are not limited thereto:

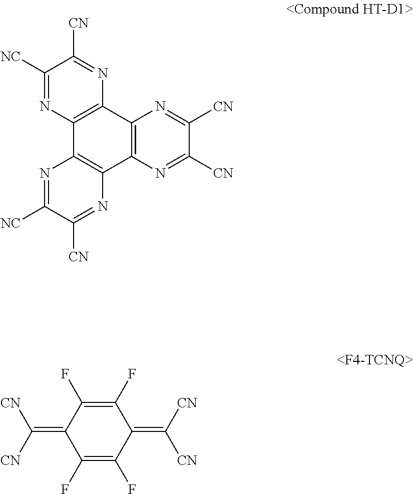

The hole transport region may further include at least one of a buffer layer or an EBL in addition to the HIL and the HTL. The buffer layer may help increase light-emitting efficiency by compensating an optical resonance distance according the wavelength of light emitted from the EML. The buffer layer may include a material that may be included in the hole transport region. The EBL may block injection of electrons from the electron transport region.

The HTL may include a first hole transport layer and a second hole transport layer, and the first hole transport layer and the second hole transport layer may be formed of the same material or different materials from each other.

The EML may be formed on the first electrode 110 or on the hole transport region by using various methods such as vacuum deposition, spin coating, casting, LB deposition, inkjet printing, laser printing, or LITI. When the EML is formed by vacuum deposition and spin coating, the deposition conditions and the coating conditions of the EML may be referred to the deposition conditions and the coating conditions of the HIL.

When the organic light-emitting device 10 is a full-color organic light-emitting device, the EML may be patterned according to individual sub-pixels, such as a red EML, a green EML, and a blue EML. Alternatively, the EML may have a stacked structure of the red EML, the green EML, and the blue EML or a single-layered structure including a red light-emitting material, a green light-emitting material, and a blue light-emitting material formed, thereby emitting white light.

The EML may include a first host and a second host as described above, and examples of the first host and the second host may be selected from the following structures or compounds. The first host and the second host are not limitedly referred by the stated orders. For example, the expression ‘the first host and the second host is CBP and PH1’ refers to a case that the first host is CBP and the second host is PH1, or a case that the first host is PH1 and the second host is CBP.

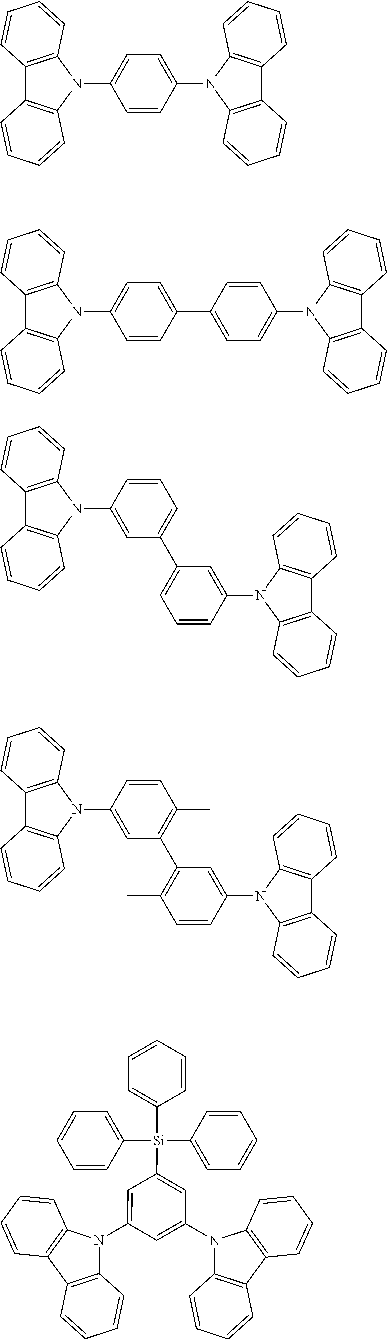

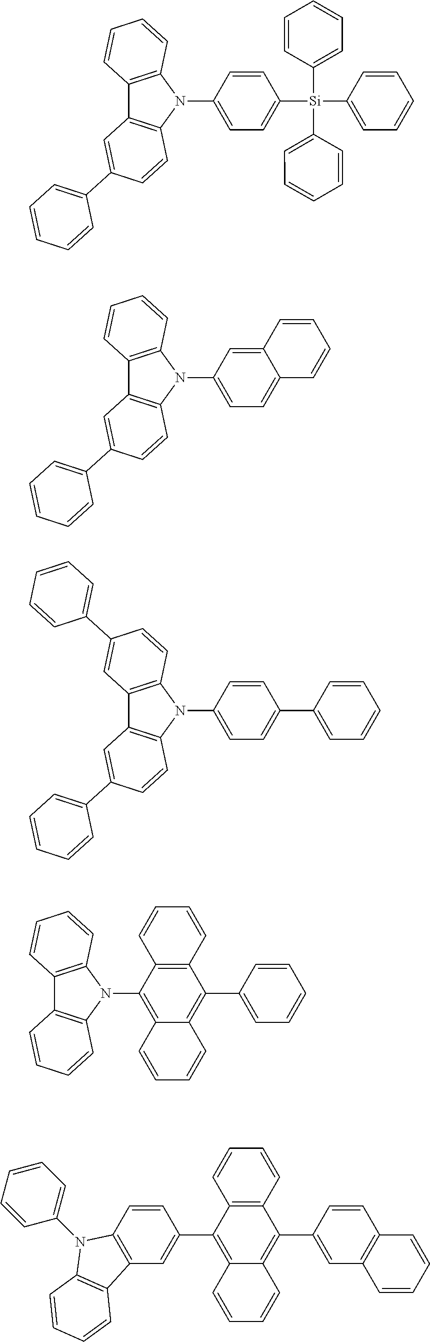

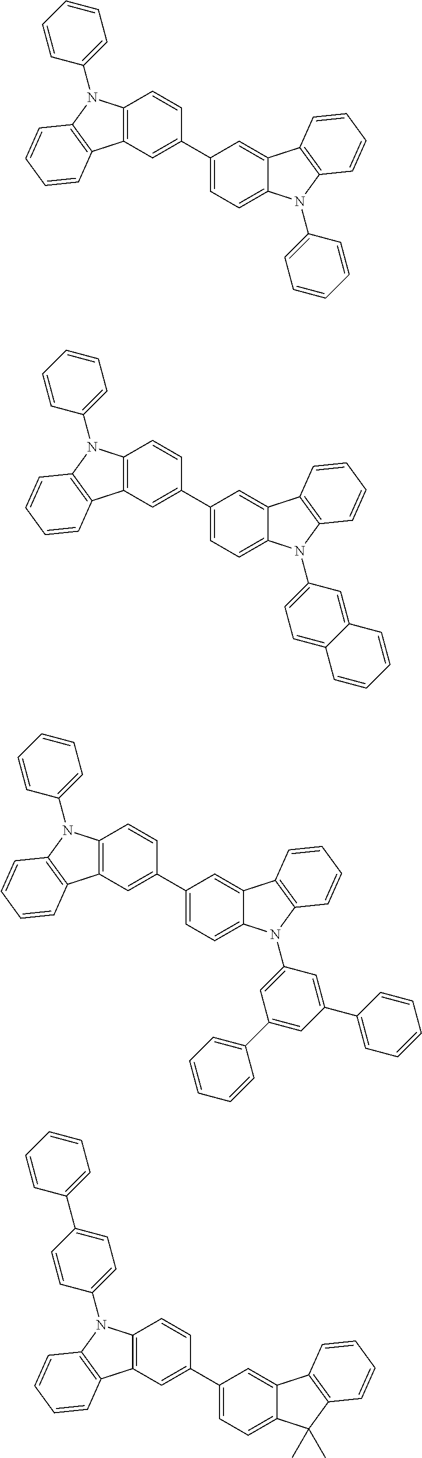 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5ccccc5c4)ccc32)cc1 ; c1ccc(-c2cc(-c3ccccc3)cc(-n3c4ccccc4c4cc(-c5ccc6c(c5)c5ccccc5n6-c5ccccc5)ccc43)c2)cc1 ; CC1(C)c2ccccc2-c2cc(-c3ccc4c(c3)c3ccccc3n4-c3ccc(-c4ccccc4)cc3)ccc21]

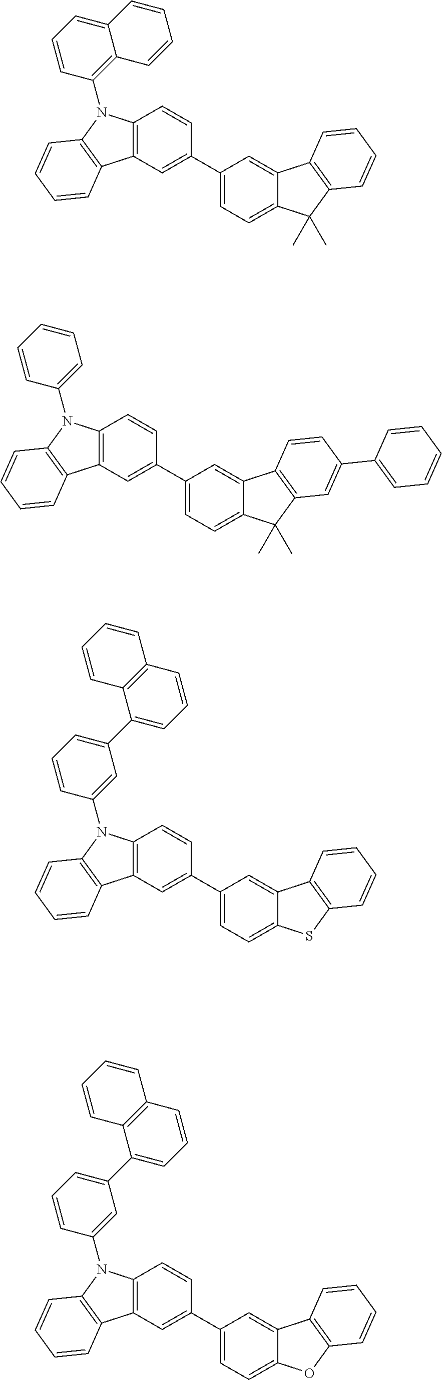 [SMILES: CC1(C)c2ccccc2-c2cc(-c3ccc4c(c3)c3ccccc3n4-c3cccc4ccccc34)ccc21 ; CC1(C)c2ccc(-c3ccc4c(c3)c3ccccc3n4-c3ccccc3)cc2-c2ccc(-c3ccccc3)cc21 ; c1cc(-c2cccc3ccccc23)cc(-n2c3ccccc3c3cc(-c4ccc5sc6ccccc6c5c4)ccc32)c1 ; c1cc(-c2cccc3ccccc23)cc(-n2c3ccccc3c3cc(-c4ccc5oc6ccccc6c5c4)ccc32)c1]

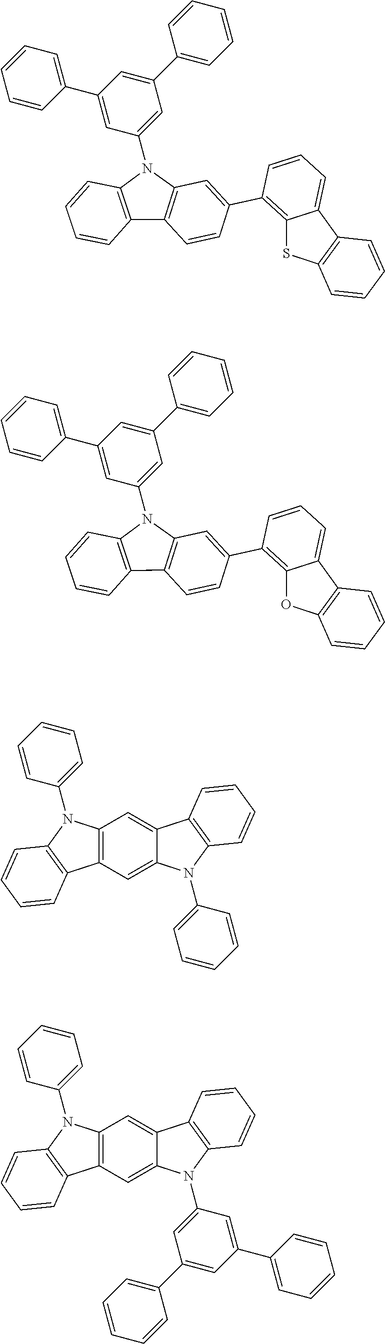 [SMILES: c1ccc(-c2cc(-c3ccccc3)cc(-n3c4ccccc4c4ccc(-c5cccc6c5sc5ccccc56)cc43)c2)cc1 ; c1ccc(-c2cc(-c3ccccc3)cc(-n3c4ccccc4c4ccc(-c5cccc6c5oc5ccccc56)cc43)c2)cc1 ; c1ccc(-n2c3ccccc3c3cc4c(cc32)c2ccccc2n4-c2ccccc2)cc1 ; c1ccc(-c2cc(-c3ccccc3)cc(-n3c4ccccc4c4cc5c(cc43)c3ccccc3n5-c3ccccc3)c2)cc1]

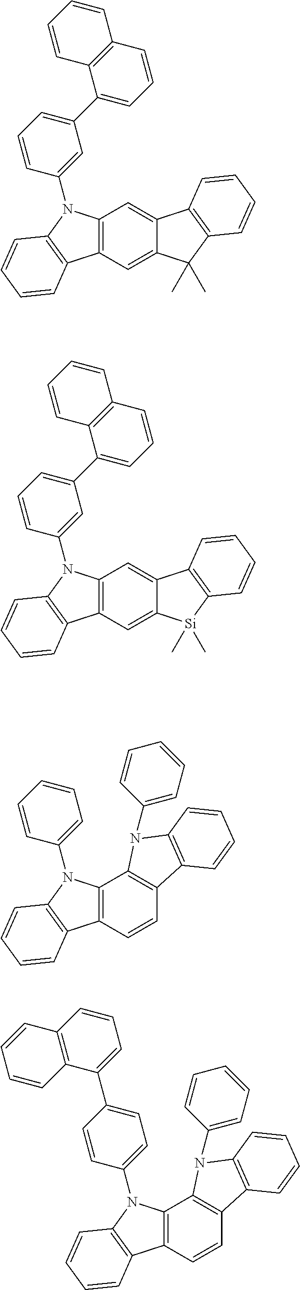

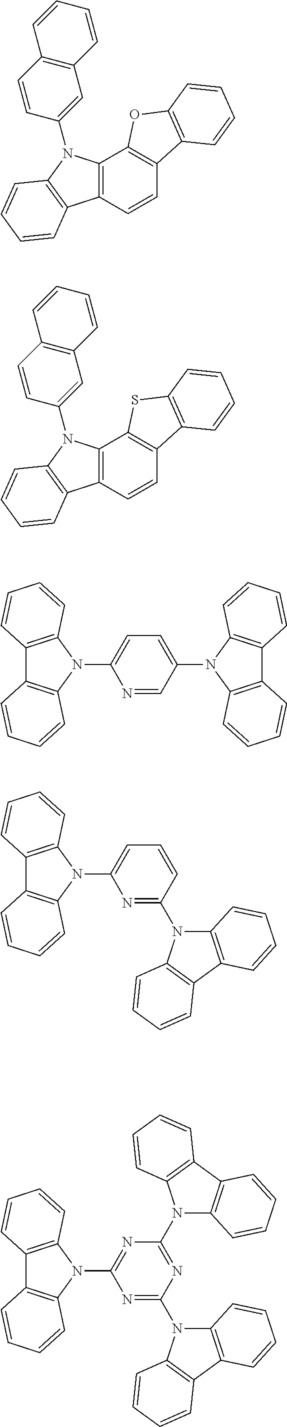

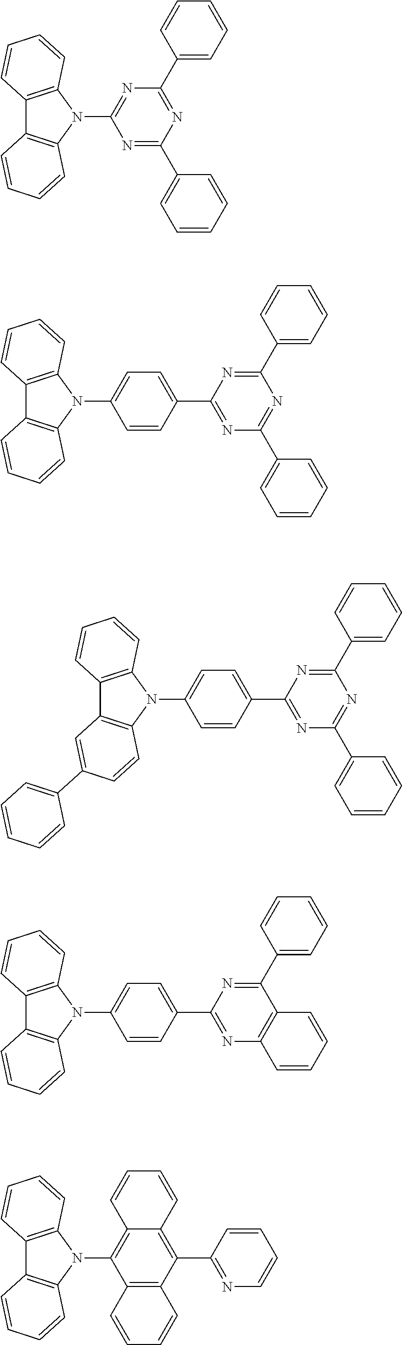 [SMILES: c1ccc(-c2nc(-c3ccccc3)nc(-n3c4ccccc4c4ccccc43)n2)cc1 ; c1ccc(-c2nc(-c3ccccc3)nc(-c3ccc(-n4c5ccccc5c5ccccc54)cc3)n2)cc1 ; c1ccc(-c2ccc3c(c2)c2ccccc2n3-c2ccc(-c3nc(-c4ccccc4)nc(-c4ccccc4)n3)cc2)cc1 ; c1ccc(-c2nc(-c3ccc(-n4c5ccccc5c5ccccc54)cc3)nc3ccccc23)cc1 ; c1ccc(-c2c3ccccc3c(-n3c4ccccc4c4ccccc43)c3ccccc23)nc1]

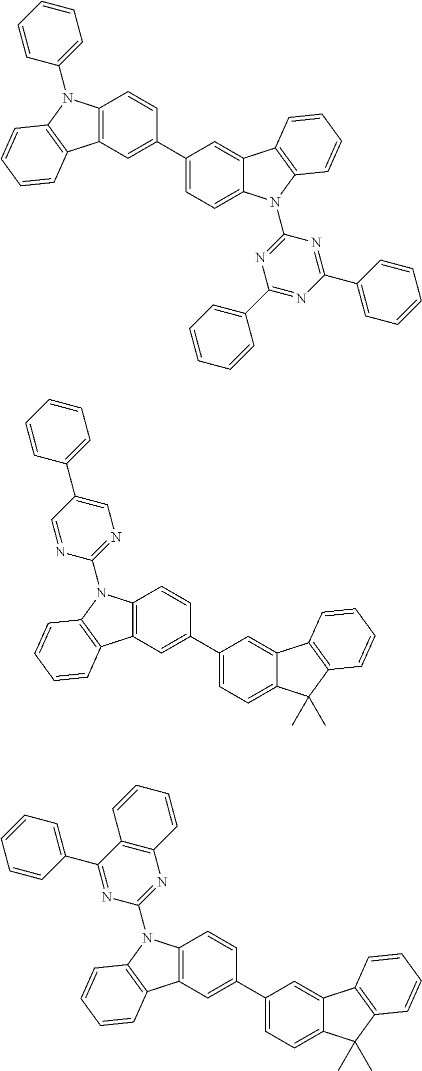 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; CC1(C)c2ccccc2-c2cc(-c3ccc4c(c3)c3ccccc3n4-c3ncc(-c4ccccc4)cn3)ccc21 ; CC1(C)c2ccccc2-c2cc(-c3ccc4c(c3)c3ccccc3n4-c3nc(-c4ccccc4)c4ccccc4n3)ccc21]

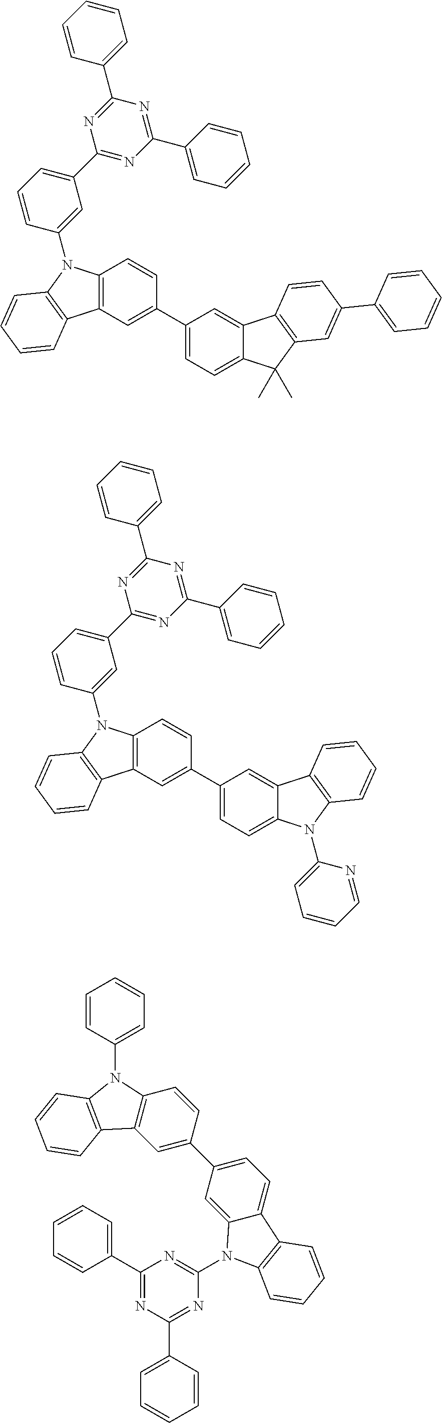 [SMILES: CC1(C)c2ccc(-c3ccc4c(c3)c3ccccc3n4-c3cccc(-c4nc(-c5ccccc5)nc(-c5ccccc5)n4)c3)cc2-c2ccc(-c3ccccc3)cc21 ; c1ccc(-c2nc(-c3ccccc3)nc(-c3cccc(-n4c5ccccc5c5cc(-c6ccc7c(c6)c6ccccc6n7-c6ccccn6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1]

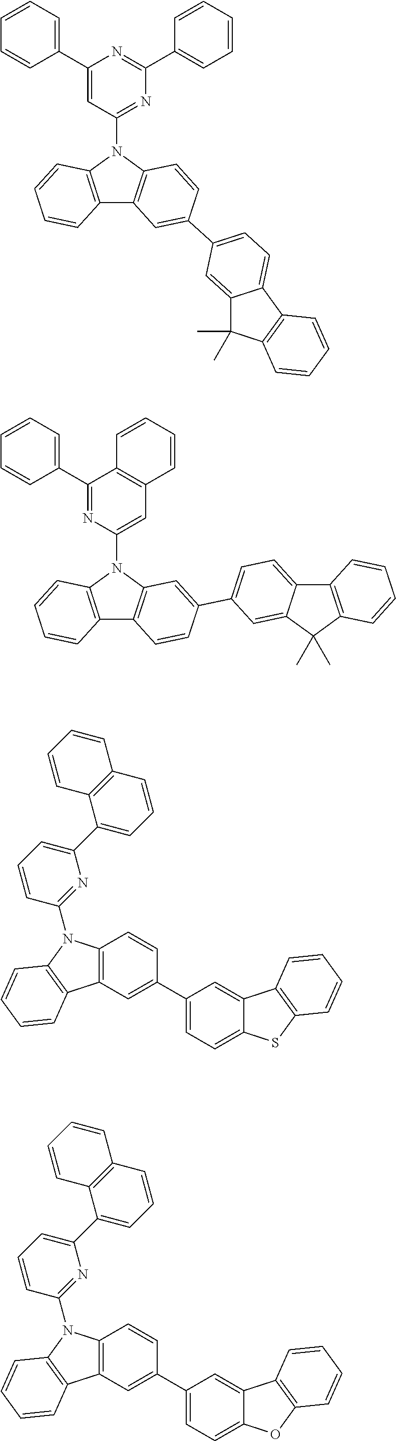 [SMILES: CC1(C)c2ccccc2-c2ccc(-c3ccc4c(c3)c3ccccc3n4-c3cc(-c4ccccc4)nc(-c4ccccc4)n3)cc21 ; CC1(C)c2ccccc2-c2ccc(-c3ccc4c5ccccc5n(-c5cc6ccccc6c(-c6ccccc6)n5)c4c3)cc21 ; c1cc(-c2cccc3ccccc23)nc(-n2c3ccccc3c3cc(-c4ccc5sc6ccccc6c5c4)ccc32)c1 ; c1cc(-c2cccc3ccccc23)nc(-n2c3ccccc3c3cc(-c4ccc5oc6ccccc6c5c4)ccc32)c1]

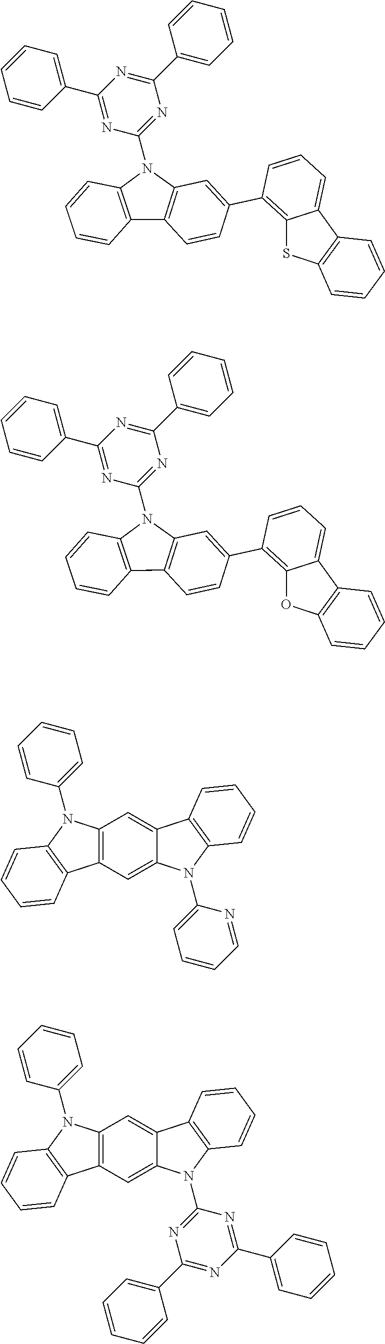 [SMILES: c1ccc(-c2nc(-c3ccccc3)nc(-n3c4ccccc4c4ccc(-c5cccc6c5sc5ccccc56)cc43)n2)cc1 ; c1ccc(-c2nc(-c3ccccc3)nc(-n3c4ccccc4c4ccc(-c5cccc6c5oc5ccccc56)cc43)n2)cc1 ; c1ccc(-n2c3ccccc3c3cc4c(cc32)c2ccccc2n4-c2ccccn2)cc1 ; c1ccc(-c2nc(-c3ccccc3)nc(-n3c4ccccc4c4cc5c(cc43)c3ccccc3n5-c3ccccc3)n2)cc1]

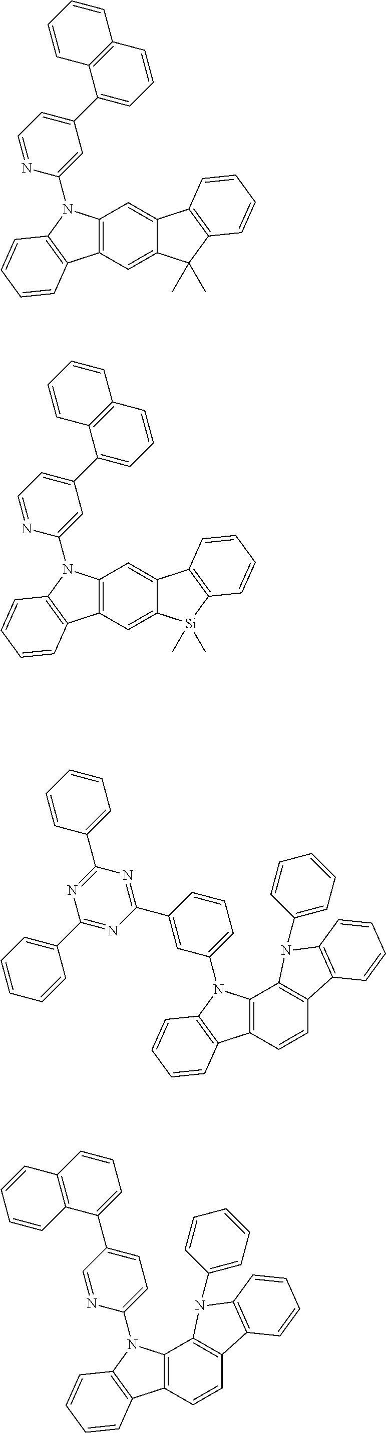

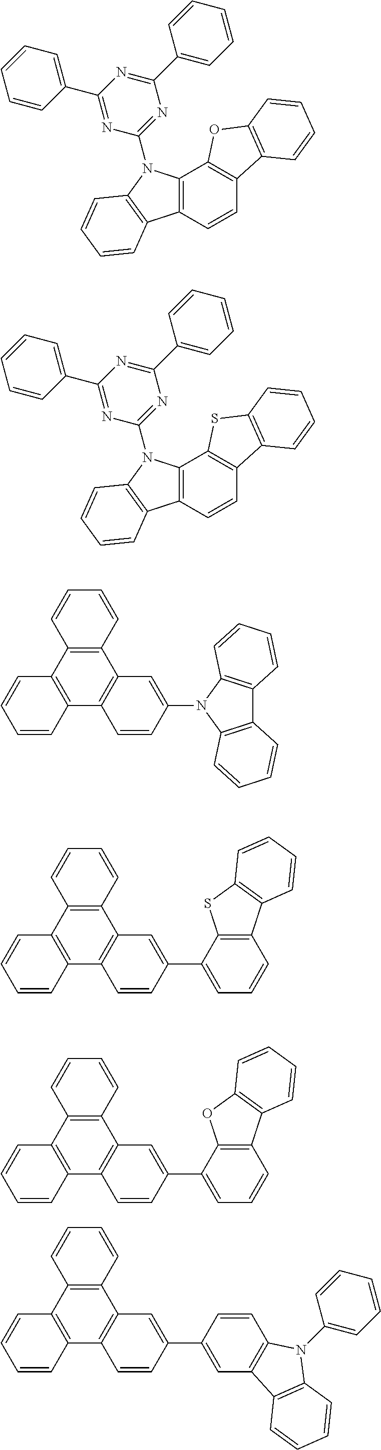

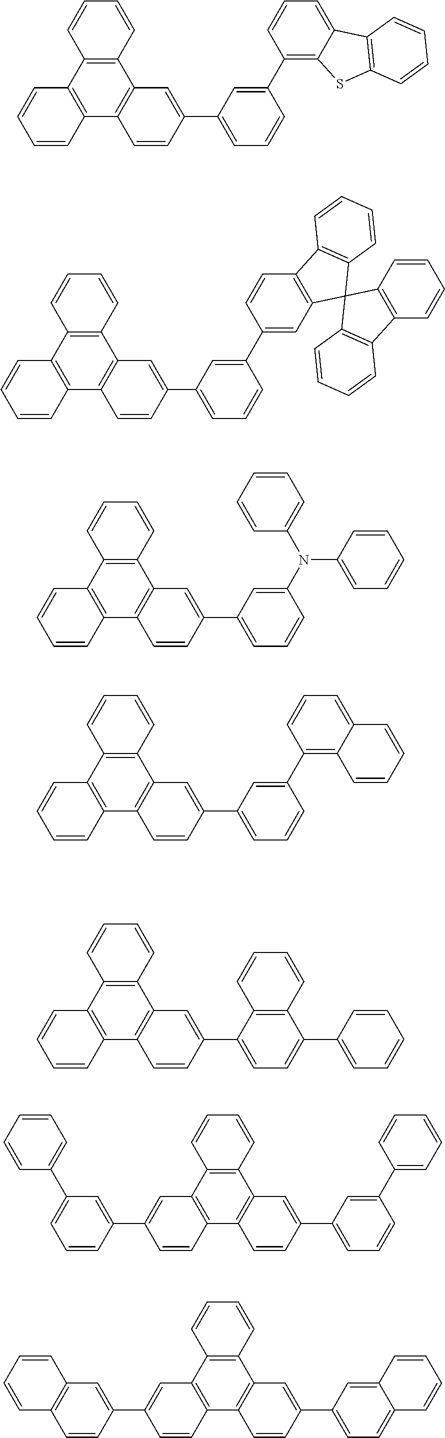

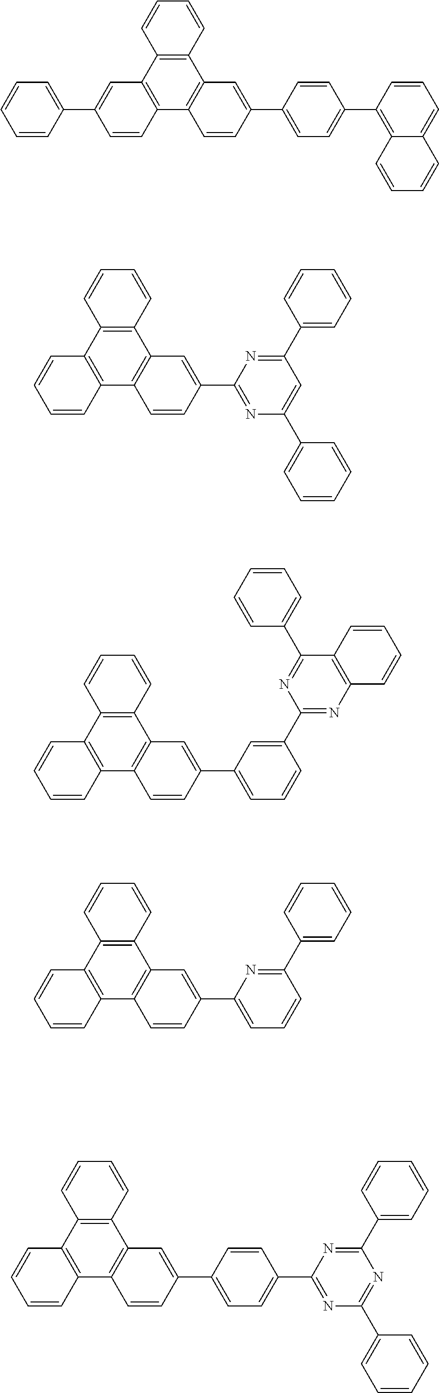

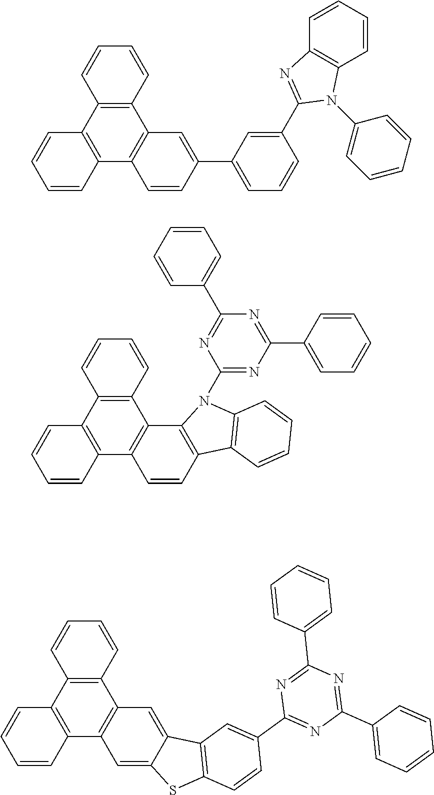

A weight ratio of the first host to the second hose may be, e.g., about 10:90 to about 90:10.

The phosphorescent dopant may include an organic metal complex represented by Formula 401 below:

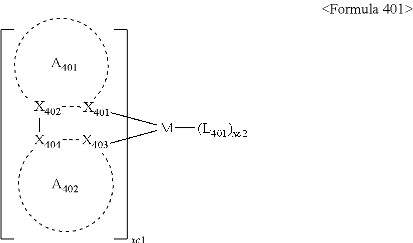

In Formula 401,

M may be selected from iridium (Ir), platinum (Pt), osmium (Os), rhodium (Rh), copper (Cu), ruthenium (Ru), titanium (Ti), zirconium (Zr), hafnium (Hf), europium (Eu), terbium (Tb), and thulium (Tm);

X₄₀₁ to X₄₀₄ may be each independently a nitrogen atom or a carbon atom;

rings A₄₀₁ and A₄₀₂ may be each independently selected from a substituted or unsubstituted benzene, a substituted or unsubstituted naphthalene, a substituted or unsubstituted fluorene, a substituted or unsubstituted spiro-fluorene, a substituted or unsubstituted indene, a substituted or unsubstituted pyrrole, a substituted or unsubstituted thiophene, a substituted or unsubstituted furan, a substituted or unsubstituted imidazole, a substituted or unsubstituted pyrazole, a substituted or unsubstituted thiazole, a substituted or unsubstituted isothiazole, a substituted or unsubstituted oxazole, a substituted or unsubstituted isooxazole, a substituted or unsubstituted pyridine, a substituted or unsubstituted pyrazine, a substituted or unsubstituted pyrimidine, a substituted or unsubstituted pyridazine, a substituted or unsubstituted quinoline, a substituted or unsubstituted isoquinoline, a substituted or unsubstituted benzoquinoline, a substituted or unsubstituted quinoxaline, a substituted or unsubstituted quinazoline, a substituted or unsubstituted carbazole, a substituted or unsubstituted benzoimidazole, a substituted or unsubstituted benzofuran, a substituted or unsubstituted benzothiophene, a substituted or unsubstituted isobenzothiophene, a substituted or unsubstituted benzooxazole, a substituted or unsubstituted isobenzooxazole, a substituted or unsubstituted triazole, a substituted or unsubstituted oxadiazole, a substituted or unsubstituted triazine, a substituted or unsubstituted dibenzofuran, and a substituted or unsubstituted dibenzothiophene;

at least one substituent of the substituted benzene, substituted naphthalene, substituted fluorene, substituted spiro-fluorene, substituted indene, substituted pyrrole, substituted thiophene, substituted furan, substituted imidazole, substituted pyrazole, substituted thiazole, substituted isothiazole, substituted oxazole, substituted isooxazole, substituted pyridine, substituted pyrazine, substituted pyrimidine, substituted pyridazine, substituted quinoline, substituted isoquinoline, substituted benzoquinoline, substituted quinoxaline, substituted quinazoline, substituted carbazole, substituted benzoimidazole, substituted benzofuran, substituted benzothiophene, substituted isobenzothiophene, substituted benzooxazole, substituted isobenzooxazole, substituted triazole, substituted oxadiazole, substituted triazine, substituted dibenzofuran, and substituted dibenzothiophene is selected from,

a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, and a C₁-C₆₀ alkoxy group;

a C₁-C₆₀ alkyl group, a C₂-C₆₀ alkenyl group, a C₂-C₆₀ alkynyl group, and a C₁-C₆₀ alkoxy group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₄₀₁)(Q₄₀₂), —Si(Q₄₀₃)(Q₄₀₄)(Q₄₀₅), and —B(Q₄₀₆)(Q₄₀₇);

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, and a non-aromatic condensed polycyclic group;

a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, and a monovalent non-aromatic hetero-condensed polycyclic group, each substituted with at least one of a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₂-C₁₀ heterocycloalkyl group, a C₃-C₁₀ cycloalkenyl group, a C₂-C₁₀ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, —N(Q₄₁₁)(Q₄₁₂), —Si(Q₄₁₃)(Q₄₁₄)(Q₄₁₅), and —B(Q₄₁₆)(Q₄₁₇); and

—N(Q₄₂₁)(Q₄₂₂), —Si(Q₄₂₃)(Q₄₂₄)(Q₄₂₅), and —B(Q₄₂₆)(Q₄₂₇);

L₄₀₁ may be an organic ligand;

xc1 may be an integer selected from 1, 2, and 3; and

xc2 may be an integer selected from 0, 1, 2, and 3.

L₄₀₁ may be a monovalent, divalent, or trivalent organic ligand. For example, L₄₀₁ may be selected from a halogen ligand (e.g., Cl or F), a diketone ligand (e.g., acetylacetonate, 1,3-diphenyl-1,3-propanedionate, 2,2,6,6-tetramethyl-3,5-heptanedionate, or hexafluoroacetonate), a carboxylic acid ligand (e.g., picolinate, dimethyl-3-pyrazolecarboxylate, or benzoate), a carbon monoxide ligand, an isonitrile ligand, a cyano ligand, and a phosphorus ligand (e.g., phosphine or phosphite), but is not limited thereto.

In Formula 401, when A₄₀₂ has two or more substituents, the substituents of A₄₀₂ may link to each other and form a saturated ring or an unsaturated ring.

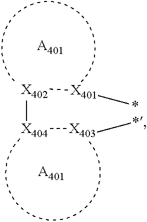

In Formula 401, when xc1 is 2 or greater, a plurality of ligands, may be identical to or different from each other. In Formula 401, when xc1 is 2 or greater, A₄₀₁ and A₄₀₂ may be linked to each other by directly linking to another neighboring ligand of A₄₀₁ and A₄₀₂ or with a connection group (e.g., a C₁-C₅ alkylene group, —N(R′)— (here, R′ is C₁-C₁₀ alkyl group or a C₆-C₂₀ aryl group), or —C(═O)—) therebetween.

In an exemplary embodiment, the phosphorescent dopant may be selected from Compounds PD1 to PD74 below, but is not limited thereto:

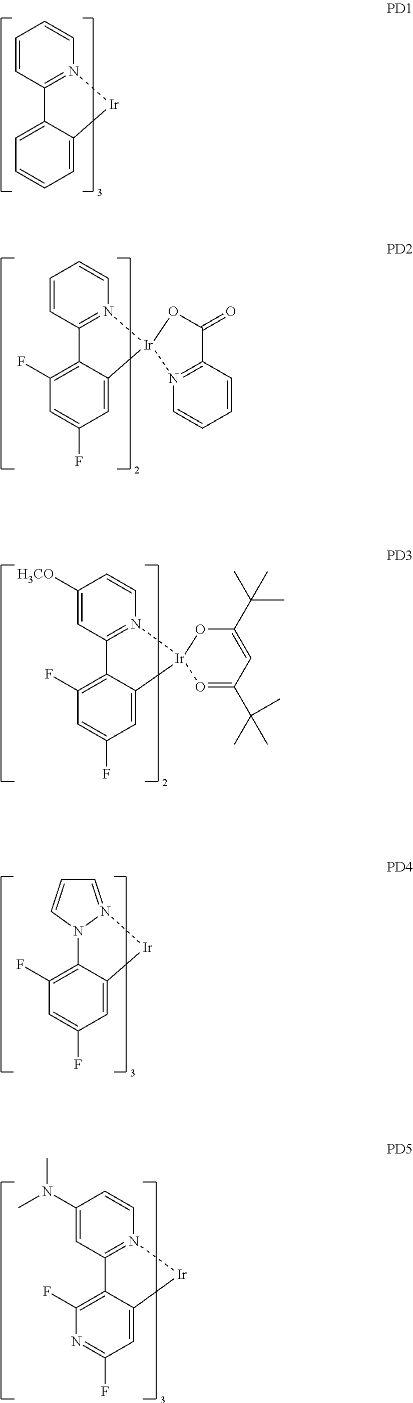

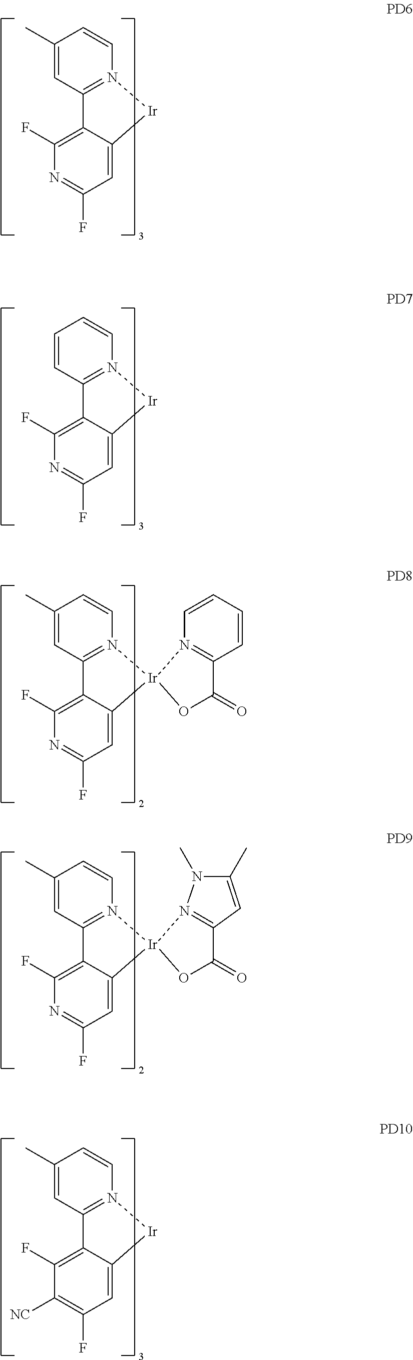

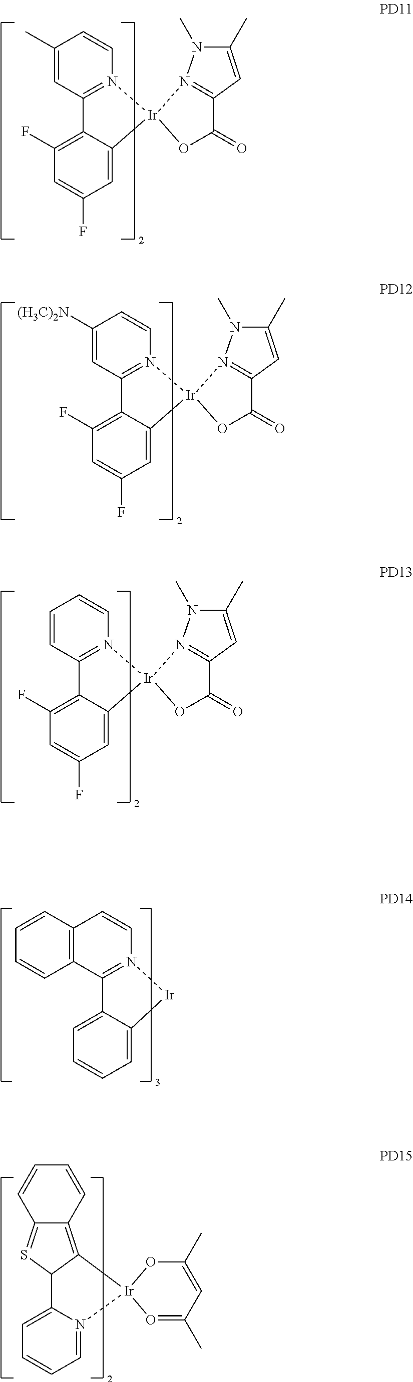

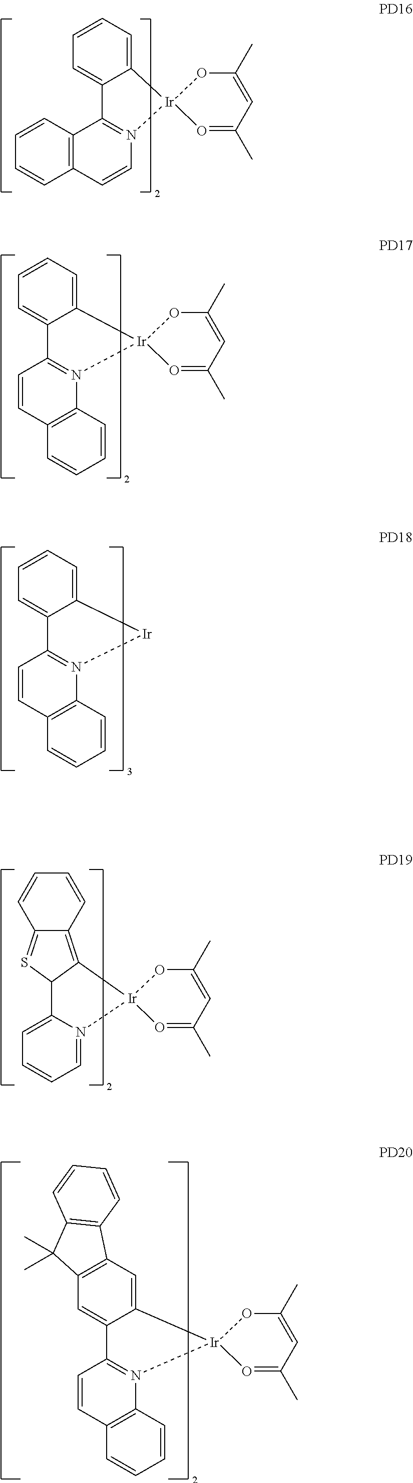

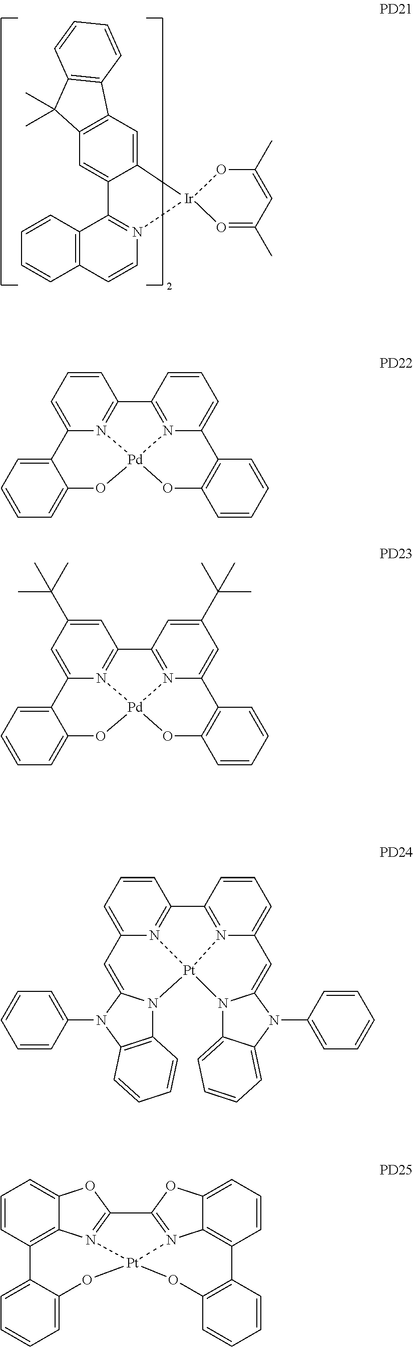

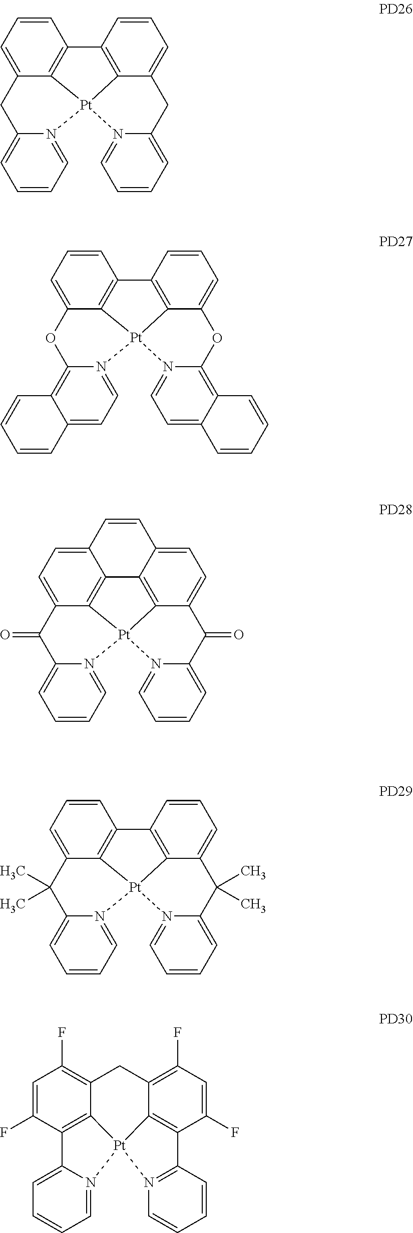

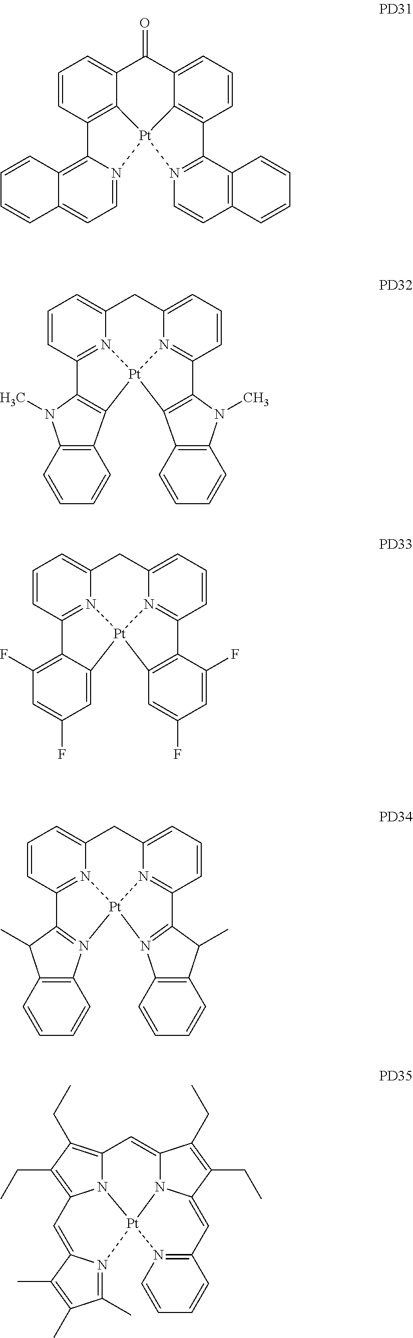

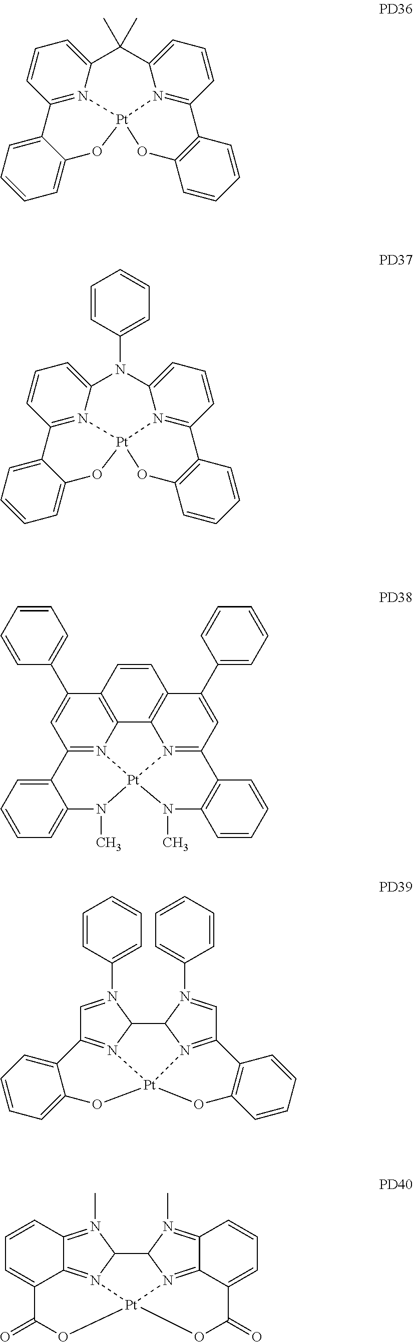

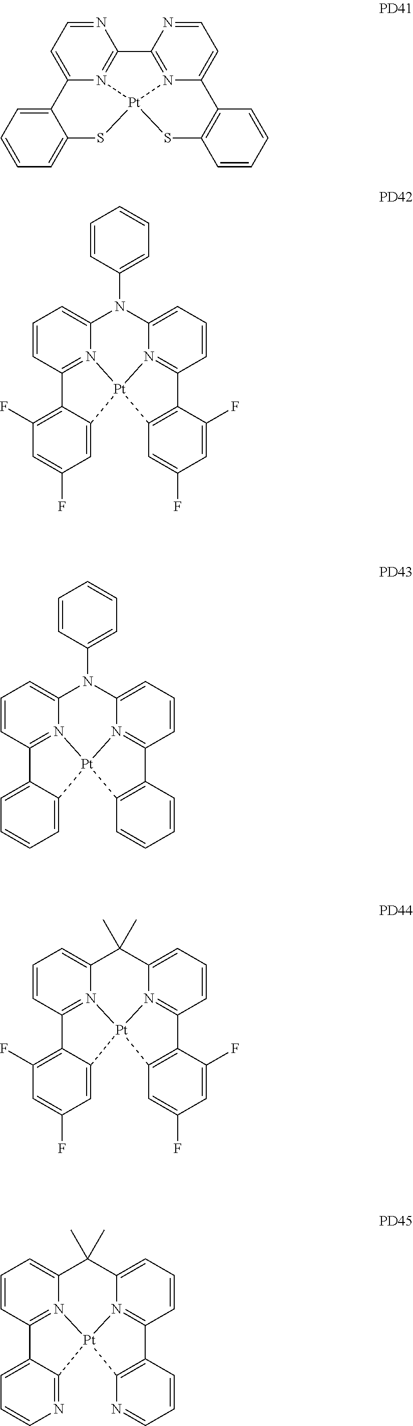

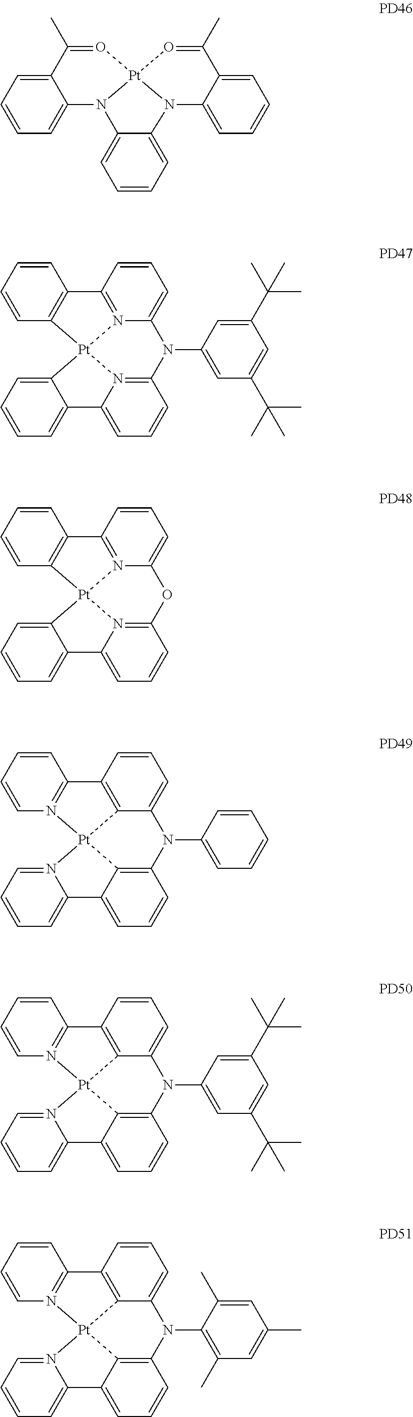

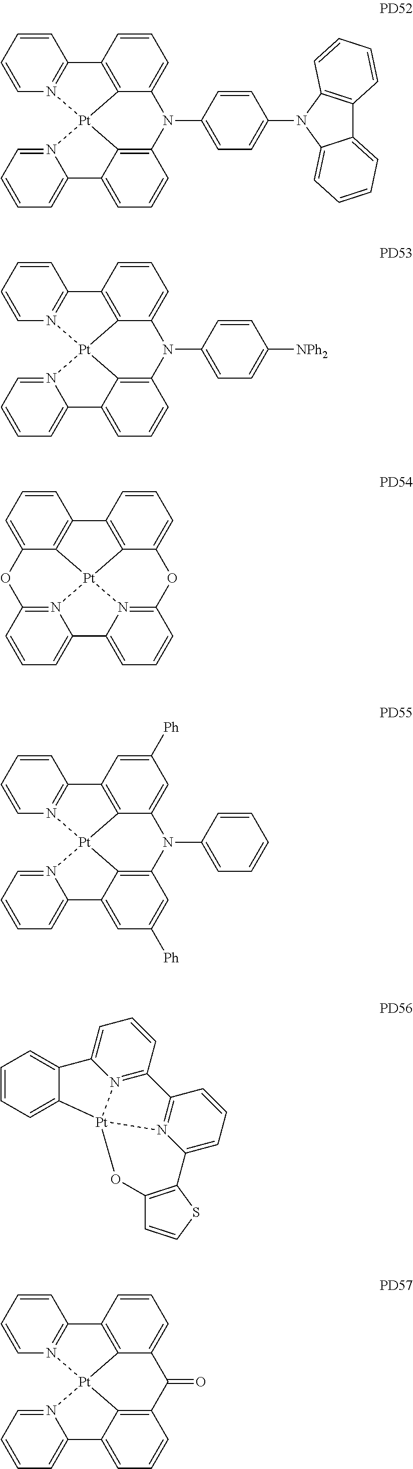

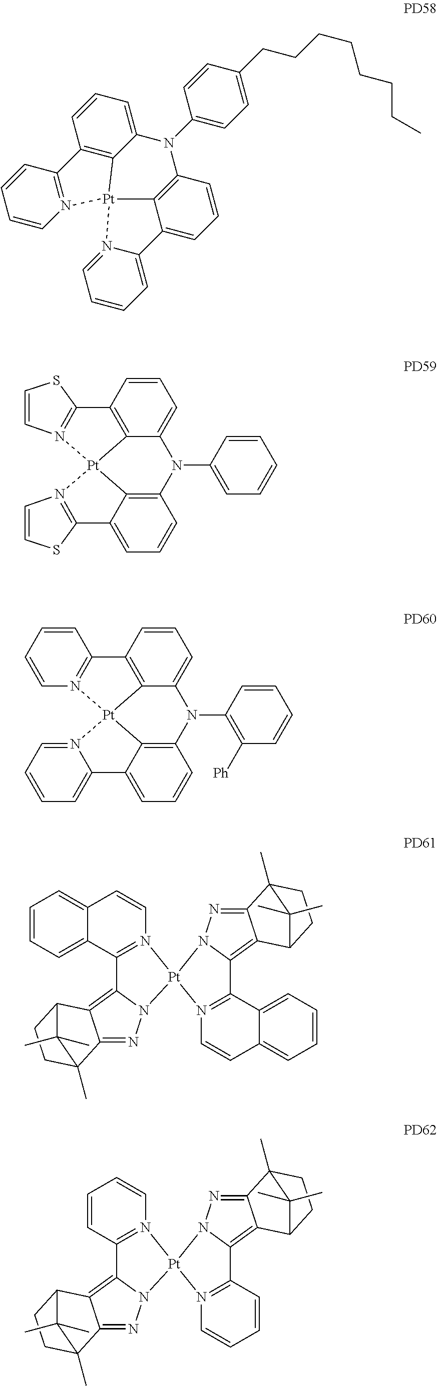

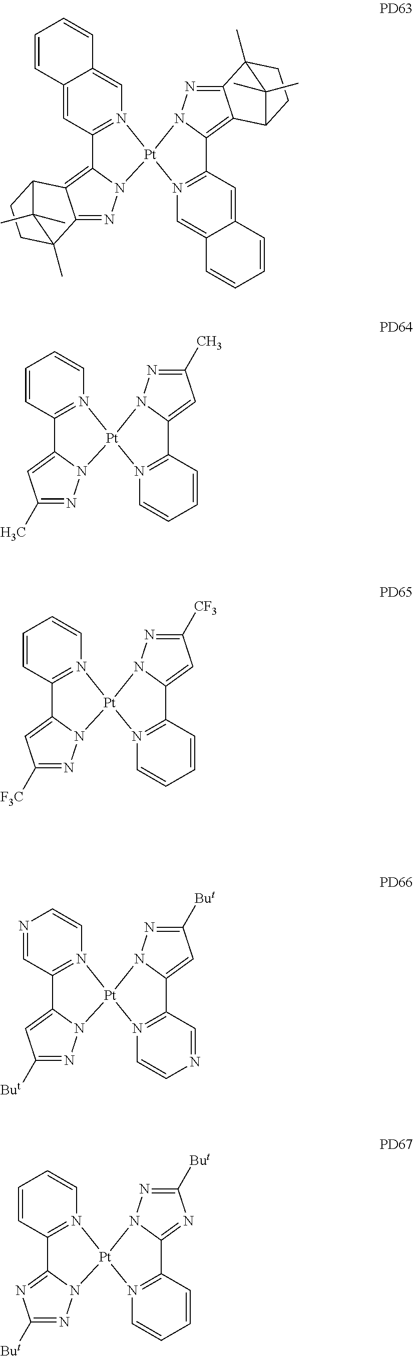

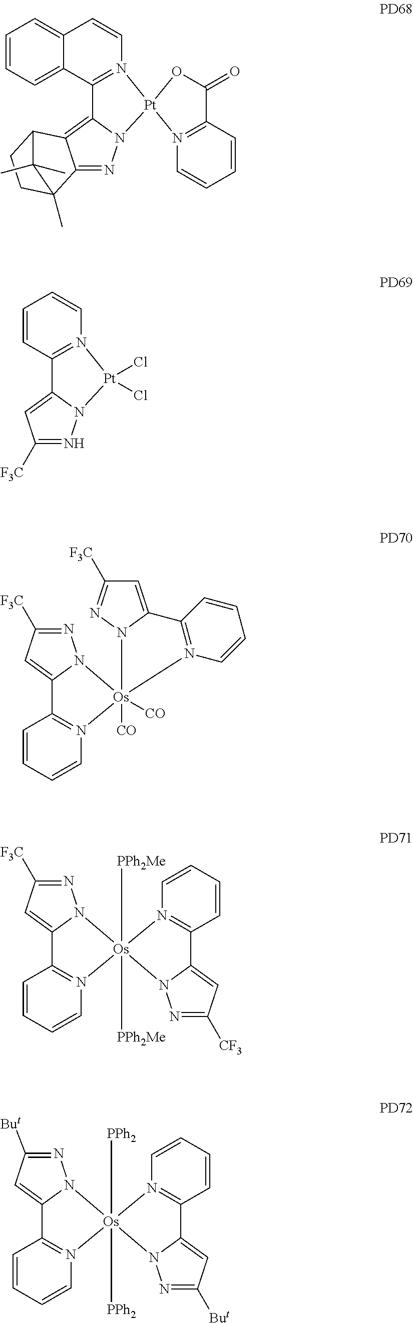

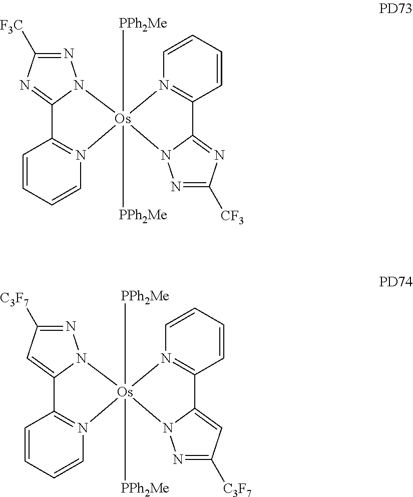

In an implementation, the phosphorescent dopant may include PtOEP below:

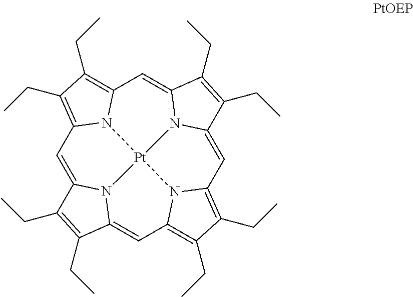

An amount of the dopant in the EML may be about 0.01 to about 15 parts by weight, based on about 100 parts by weight of a host, but the amount is not limited thereto.

A thickness of the EML may be about 100 Å to about 1,000 Å, e.g., about 200 Å to about 600 Å. When a thickness of the EML is within this range, light-emitting properties of the organic light-emitting device may be excellent without substantial increase in driving voltage.

The intermediate layer may be disposed on the EML.

The intermediate layer may be formed on the EML by using various methods such as vacuum deposition, spin coating, casting, LB deposition, inkjet printing, laser printing, or LITI. When the intermediate layer is formed by vacuum deposition and spin coating, the deposition conditions and the coating conditions of the intermediate layer may be referred to the deposition conditions and the coating conditions of the HIL.

The intermediate layer may be formed of a compound represented by Formula 1. In an implementation, the compound may include, e.g., at least one of compounds below:

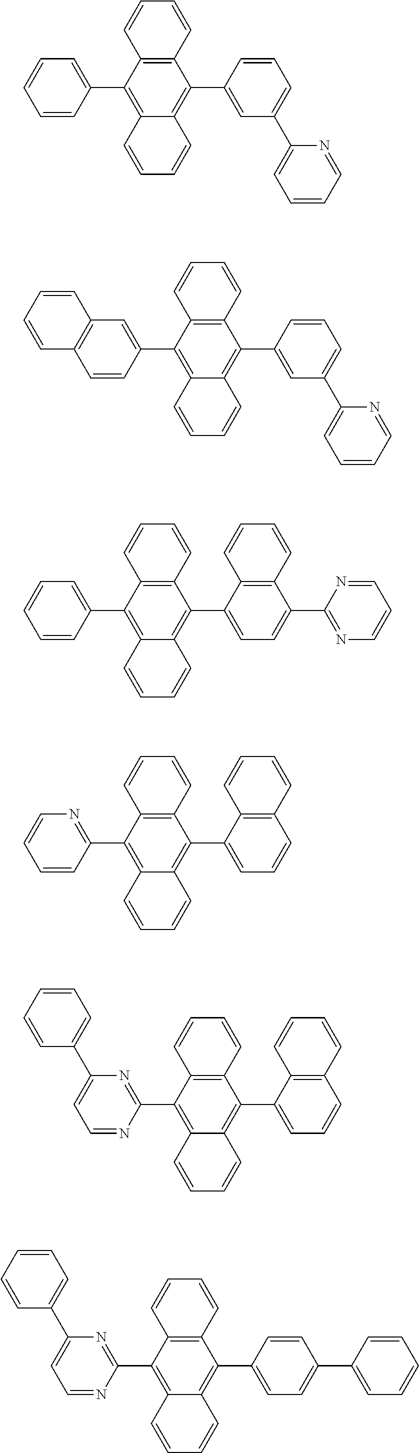 [SMILES: c1ccc(-c2c3ccccc3c(-c3cccc(-c4ccccn4)c3)c3ccccc23)cc1 ; c1ccc(-c2cccc(-c3c4ccccc4c(-c4ccc5ccccc5c4)c4ccccc34)c2)nc1 ; c1ccc(-c2c3ccccc3c(-c3ccc(-c4ncccn4)c4ccccc34)c3ccccc23)cc1 ; c1ccc(-c2c3ccccc3c(-c3cccc4ccccc34)c3ccccc23)nc1 ; c1ccc(-c2ccnc(-c3c4ccccc4c(-c4cccc5ccccc45)c4ccccc34)n2)cc1 ; c1ccc(-c2ccc(-c3c4ccccc4c(-c4nccc(-c5ccccc5)n4)c4ccccc34)cc2)cc1]

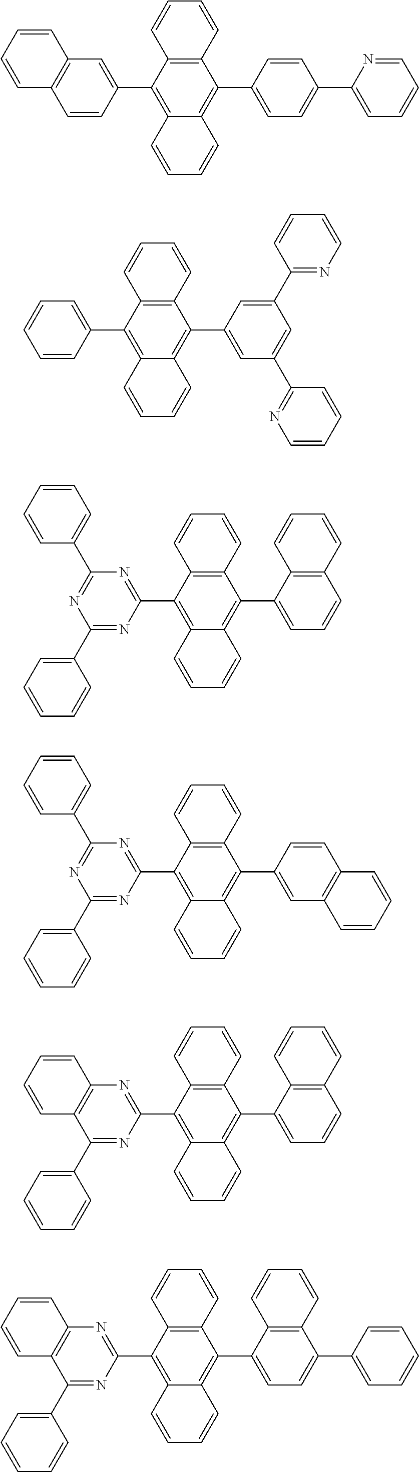

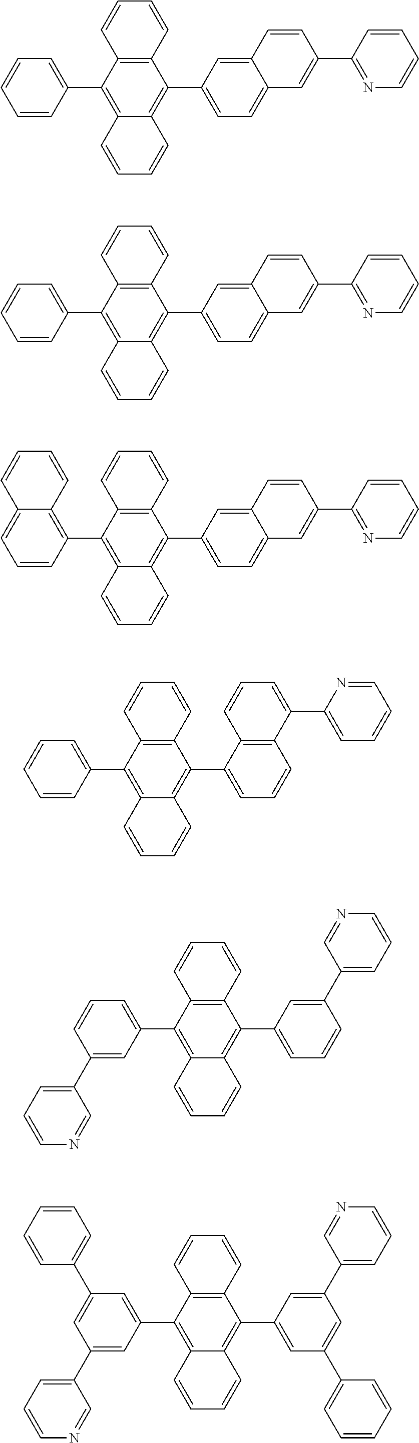 [SMILES: c1ccc(-c2c3ccccc3c(-c3ccc4cc(-c5ccccn5)ccc4c3)c3ccccc23)cc1 ; c1ccc(-c2c3ccccc3c(-c3ccc4cc(-c5ccccn5)ccc4c3)c3ccccc23)cc1 ; c1ccc(-c2ccc3cc(-c4c5ccccc5c(-c5cccc6ccccc56)c5ccccc45)ccc3c2)nc1 ; c1ccc(-c2c3ccccc3c(-c3cccc4c(-c5ccccn5)cccc34)c3ccccc23)cc1 ; c1cncc(-c2cccc(-c3c4ccccc4c(-c4cccc(-c5cccnc5)c4)c4ccccc34)c2)c1 ; c1ccc(-c2cc(-c3cccnc3)cc(-c3c4ccccc4c(-c4cc(-c5ccccc5)cc(-c5cccnc5)c4)c4ccccc34)c2)cc1]

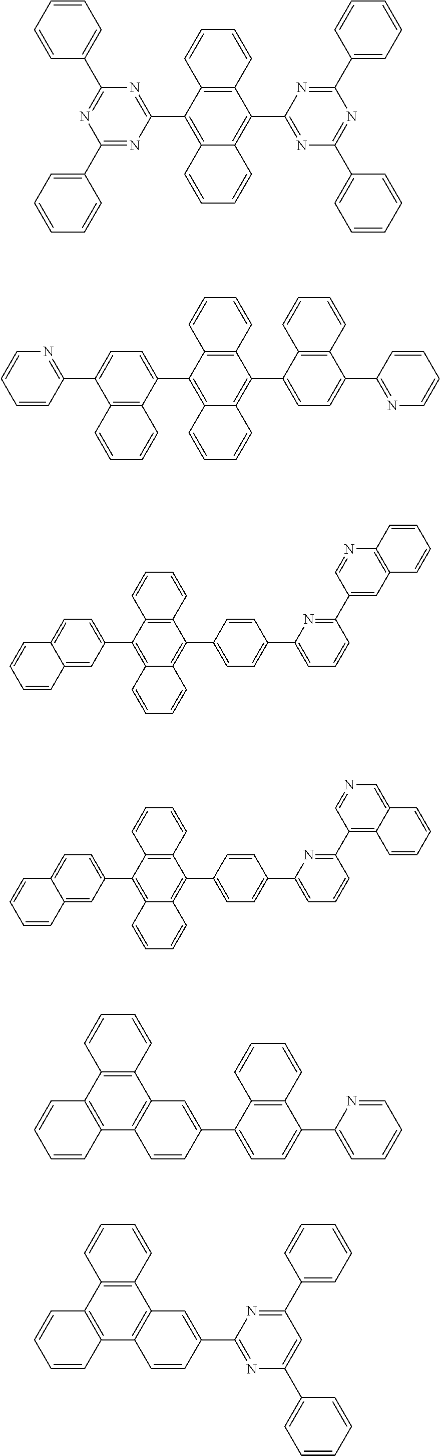 [SMILES: c1ccc(-c2nc(-c3ccccc3)nc(-c3c4ccccc4c(-c4nc(-c5ccccc5)nc(-c5ccccc5)n4)c4ccccc34)n2)cc1 ; c1ccc(-c2ccc(-c3c4ccccc4c(-c4ccc(-c5ccccn5)c5ccccc45)c4ccccc34)c3ccccc23)nc1 ; c1cc(-c2ccc(-c3c4ccccc4c(-c4ccc5ccccc5c4)c4ccccc34)cc2)nc(-c2cnc3ccccc3c2)c1 ; c1cc(-c2ccc(-c3c4ccccc4c(-c4ccc5ccccc5c4)c4ccccc34)cc2)nc(-c2cncc3ccccc23)c1 ; c1ccc(-c2ccc(-c3ccc4c5ccccc5c5ccccc5c4c3)c3ccccc23)nc1 ; c1ccc(-c2cc(-c3ccccc3)nc(-c3ccc4c5ccccc5c5ccccc5c4c3)n2)cc1]

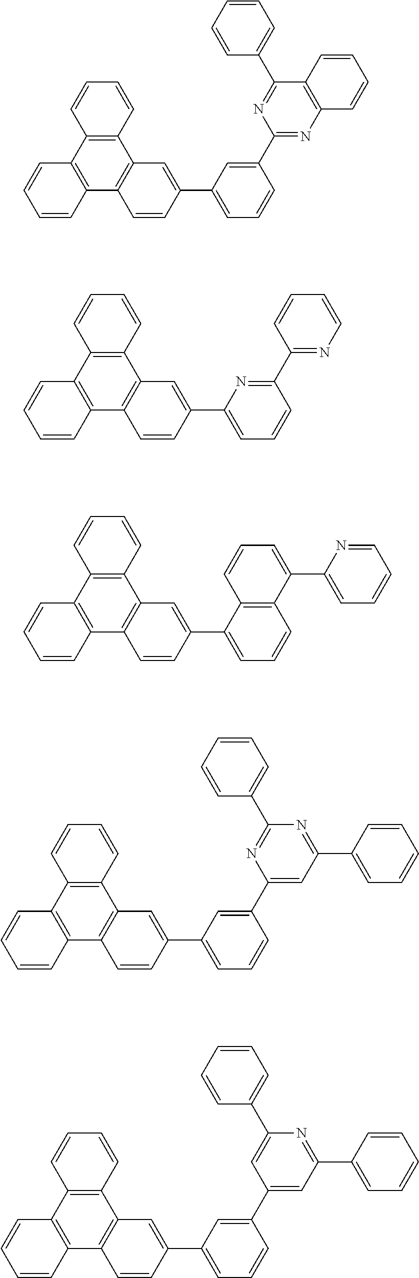 [SMILES: c1ccc(-c2nc(-c3cccc(-c4ccc5c6ccccc6c6ccccc6c5c4)c3)nc3ccccc23)cc1 ; c1ccc(-c2cccc(-c3ccc4c5ccccc5c5ccccc5c4c3)n2)nc1 ; c1ccc(-c2cccc3c(-c4ccc5c6ccccc6c6ccccc6c5c4)cccc23)nc1 ; c1ccc(-c2cc(-c3cccc(-c4ccc5c6ccccc6c6ccccc6c5c4)c3)nc(-c3ccccc3)n2)cc1 ; c1ccc(-c2cc(-c3cccc(-c4ccc5c6ccccc6c6ccccc6c5c4)c3)cc(-c3ccccc3)n2)cc1]

A thickness of the intermediate layer may be about 5 Å to about 400 Å, e.g., about 50 Å to about 300 Å. When a thickness of the intermediate layer is within the range, satisfactory properties of the organic light-emitting device may be obtained without substantial increase in driving voltage.

Next, an electron transport region may be disposed on the intermediate layer.

The electron transport region may include at least one selected from an HBL, an ETL, and an EIL, but is not limited thereto.

For example, the electron transport region may have a structure of ETL/EIL or a structure of HBL/ETL/EIL, wherein layers of each structure are sequentially stacked on the EML in the stated order, but the structure is not limited thereto.

In an exemplary embodiment, the organic layer 150 of the organic light-emitting device 10 may include an electron transport region between the EML and the second electrode 190. The electron transport region may include at least one of an ETL and an EIL.

The ETL may include at least one selected from BCP and Bphen above and Alg₃, Balq, TAZ, and NTAZ below:

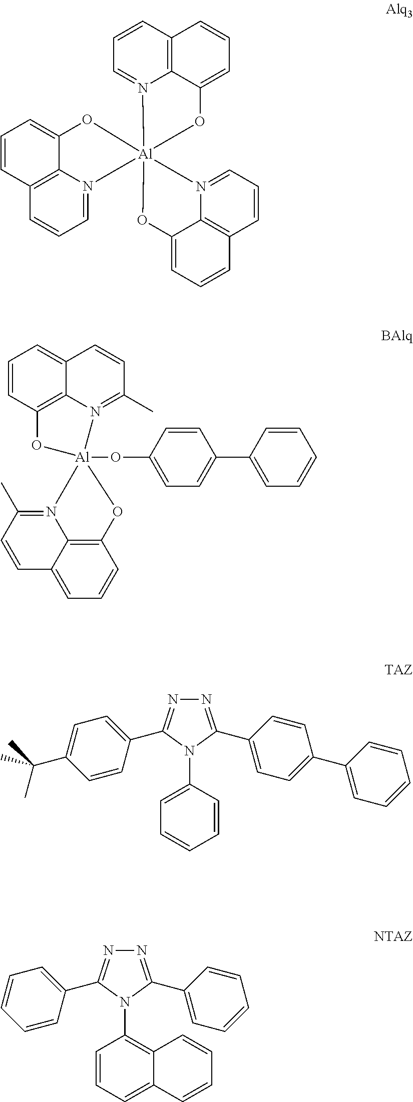

In an implementation, the ETL may include at least one compound selected from a compound represented by Formula 601 below and a compound represented by Formula 602 below.

Ar₆₀₁-[(L₆₀₁)ₓₑ₁-E₆₀₁]ₓₑ₂ <Formula 601>

In Formula 601,

Ar₆₀₁ may be selected from,

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene; and

a naphthalene, a heptalene, a fluorene, a spiro-fluorene, a benzofluorene, a dibenzofluorene, a phenalene, a phenanthrene, an anthracene, a fluoranthene, a triphenylene, a pyrene, a chrysene, a naphthacene, a picene, a perylene, a pentaphene, and an indenoanthracene, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₃-C₁₀ heterocycloalkyl group, a C₃-C₁₀ cycloalkenyl group, a C₃-Cₘ heterocycloalkenyl group, a C₆-C₆₀ aryl group, a C₆-C₆₀ aryloxy group, a C₆-C₆₀ arylthio group, a C₂-C₆₀ heteroaryl group, a monovalent non-aromatic condensed polycyclic group, a monovalent non-aromatic hetero-condensed polycyclic group, and —Si(Q₃₀₁)(Q₃₀₂)(Q₃₀₃) (here, Q₃₀₁ to Q₃₀₃ are each independently selected from a hydrogen, a C₁-C₆₀ alkyl group, a C₂-C₆₀ alkenyl group, a C₆-C₆₀ aryl group, and a C₂-C₆₀ heteroaryl group);

L₆₀₁ may be defined the same as L₂₀₁;

E₆₀₁ may be selected from,

a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group; and

a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a cyclopentyl group, a cyclohexyl group, a cycloheptyl group, a cyclopentenyl group, a cyclohexenyl group, a phenyl group, a pentalenyl group, an indenyl group, a naphthyl group, an azulenyl group, a heptalenyl group, an indacenyl group, an acenaphthyl group, a fluorenyl group, a spiro-fluorenyl group, a benzofluorenyl group, a dibenzofluorenyl group, a phenalenyl group, a phenanthrenyl group, an anthracenyl group, a fluoranthenyl group, a triphenylenyl group, a pyrenyl group, a chrysenyl group, a naphthacenyl group, a picenyl group, a perylenyl group, a pentaphenyl group, a hexacenyl group, a pentacenyl group, a rubicenyl group, a coroneryl group, an ovalenyl group, a pyrrolyl group, a thiophenyl group, a furanyl group, an imidazolyl group, a pyrazolyl group, a thiazolyl group, an isothiazolyl group, an oxazolyl group, an isooxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a phthalazinyl group, a naphthyridinyl group, a quinoxalinyl group, a quinazolinyl group, a cinnolinyl group, a carbazolyl group, a phenanthridinyl group, an acridinyl group, a phenanthrolinyl group, a phenazinyl group, a benzoimidazolyl group, a benzofuranyl group, a benzothiophenyl group, an isobenzothiazolyl group, a benzooxazolyl group, an isobenzooxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, a thiadiazolyl group, an imidazopyridinyl group, and an imidazopyrimidinyl group;

xe1 may be an integer selected from 0, 1, 2, and 3; and

xe2 may be an integer selected from 1, 2, 3, and 4.

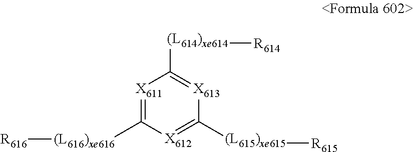

In Formula 602,

X₆₁₁ may be N or C-(L₆₁₁)ₓₑ₆₁₁-R₆₁₁, X₆₁₂ may be N or C-(L₆₁₂)ₓₑ₆₁₂-R₆₁₂, X₆₁₃ may be N or C-(L₆₁₃)ₓₑ₆₁₃-R₆₁₃, and at least one of X₆₁₁ to X₆₁₃ may be N;

each of L₆₁₁ to L₆₁₆ may be defined the same as L₂₀₁ above;

R₆₁₁ to R₆₁₆ may be each independently selected from,

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group; and

a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group, each substituted with at least one selected from a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₂₀ alkyl group, a C₁-C₂₀ alkoxy group, a phenyl group, a naphthyl group, a fluorenyl group, a spiro-fluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, and a triazinyl group;

xe611 to xe616 may be each independently an integer selected from 0, 1, 2, and 3.

The compound represented by Formula 601 and the compound represented by

Formula 602 may be selected from compounds ET1 to ET15 below:

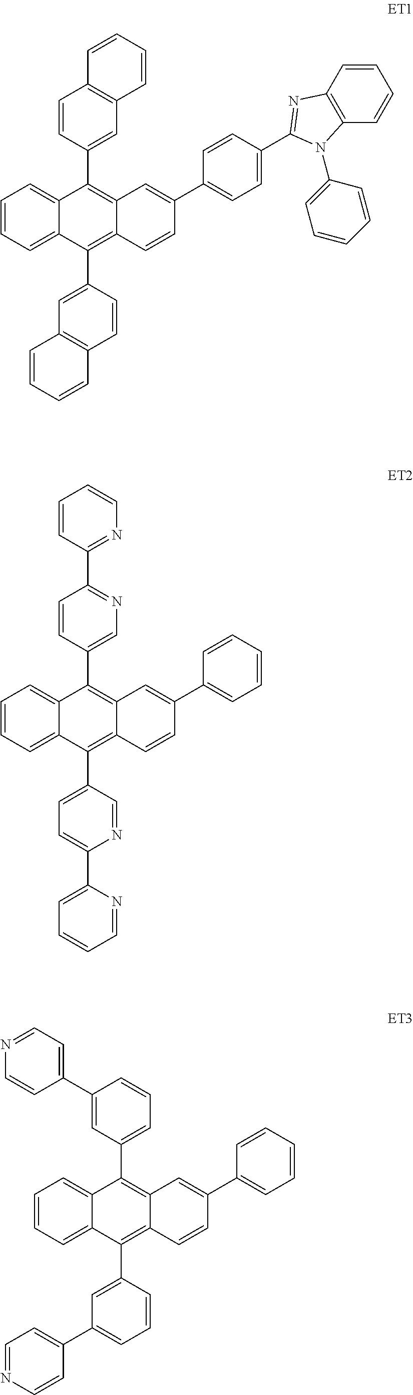 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

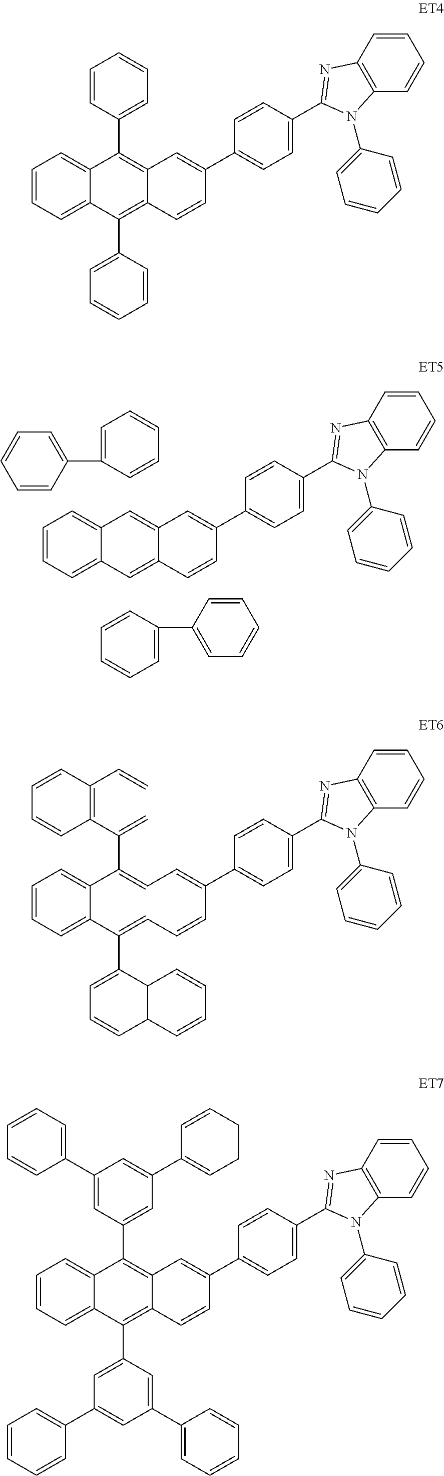

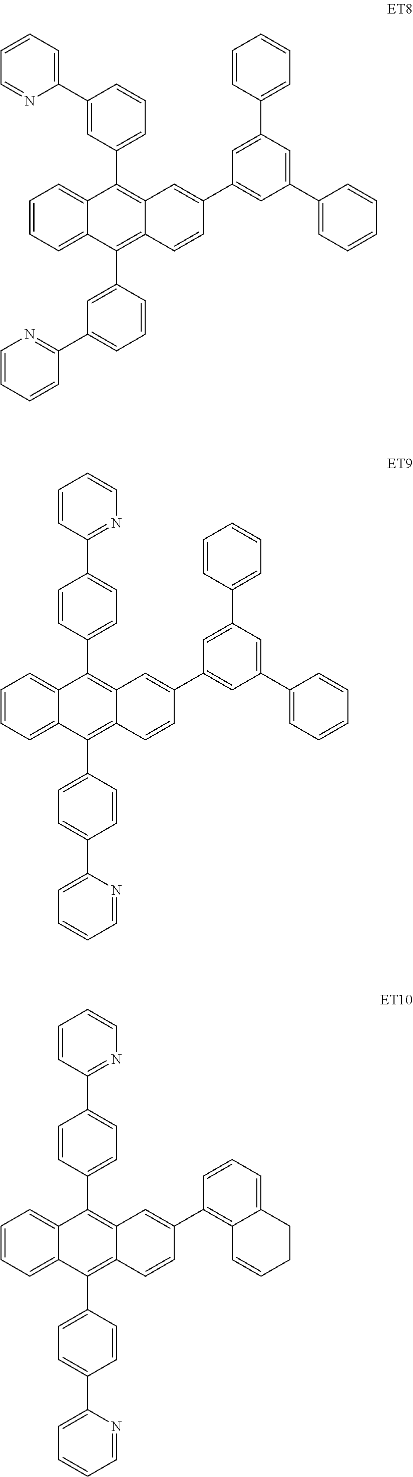 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; C1=Cc2c(cccc2-c2ccc3c(-c4ccc(-c5ccccn5)cc4)c4ccccc4c(-c4ccc(-c5ccccn5)cc4)c3c2)CC1]

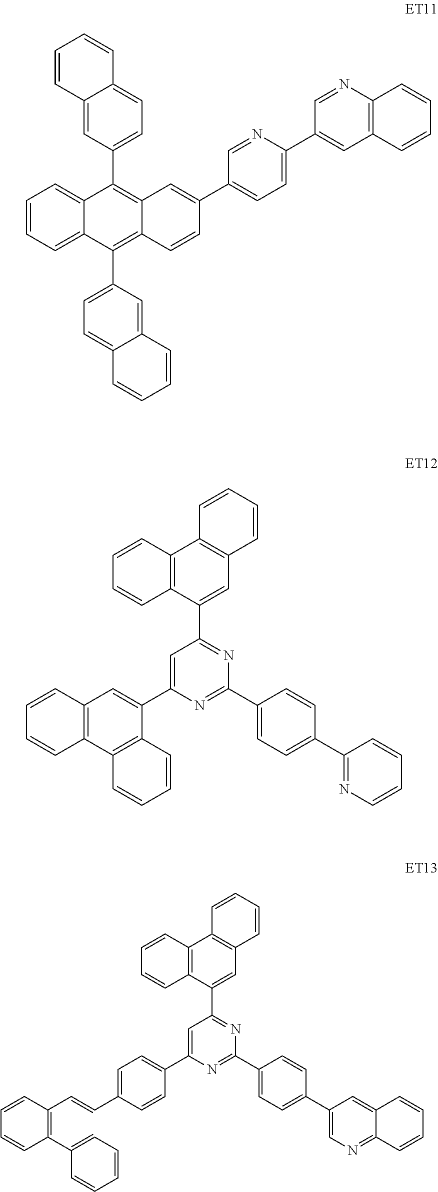 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-c2ccc(-c3nc(-c4cc5ccccc5c5ccccc45)cc(-c4cc5ccccc5c5ccccc45)n3)cc2)nc1 ; C(=C\c1ccccc1-c1ccccc1)/c1ccc(-c2cc(-c3cc4ccccc4c4ccccc34)nc(-c3ccc(-c4cnc5ccccc5c4)cc3)n2)cc1]

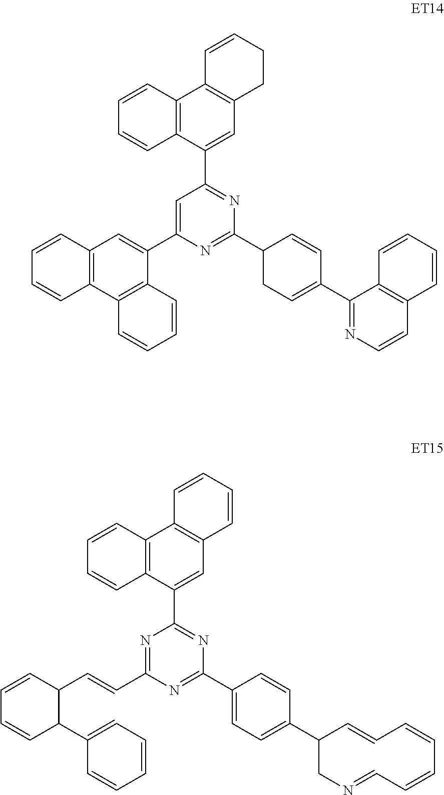 [SMILES: C1=Cc2c(cc(-c3cc(-c4cc5ccccc5c5ccccc45)nc(C4C=CC(c5nccc6ccccc56)=CC4)n3)c3ccccc23)CC1 ; C1=CC(/C=C/c2nc(-c3ccc(C4/C=C/C=C\C=C/C=N/C4)cc3)nc(-c3cc4ccccc4c4ccccc34)n2)C(c2ccccc2)C=C1]

A thickness of the ETL may be about 100 Å to about 1,000 Å, e.g., about 150 Å to about 500 Å. When a thickness of the ETL is within this range, satisfactory electron transporting properties of the organic light-emitting device may be obtained without substantial increase in driving voltage.

The ETL may further include a metal-containing material in addition to the materials above.

The metal-containing material may include a Li-complex. The Li-complex may include, e.g., compound ET-D1 (lithium quinolate (LiQ)) or ET-D2:

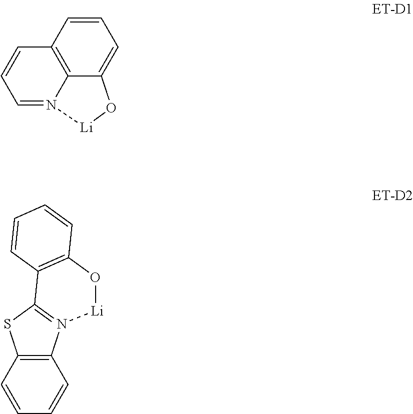

The electron transport region may include the HBL. When the EML uses a phosphorescent dopant, the HBL may be included to help reduce and/or prevent triplet excitons or holes from being diffused to the ETL.

When the electron transport region includes the HBL, the HBL may be formed on the EML by using various methods such as vacuum deposition, spin coating, casting, LB deposition, inkjet printing, laser printing, or LITI. When the HBL is formed by methods such as vacuum deposition and spin coating, the deposition conditions and the coating conditions of the HBL may be referred to the de deposition conditions and the coating conditions of the HIL.

The HBL may include, for example, at least one of BCP and Bphen below, but is not limited thereto:

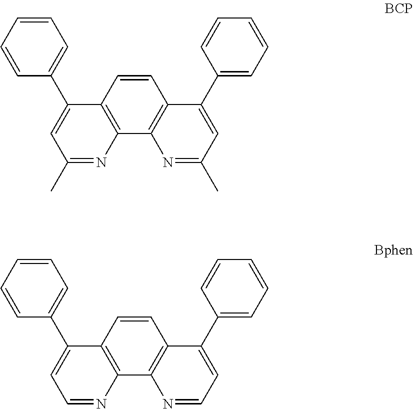 [SMILES: Cc1cc(-c2ccccc2)c2ccc3c(-c4ccccc4)cc(C)nc3c2n1 ; c1ccc(-c2ccnc3c2ccc2c(-c4ccccc4)ccnc23)cc1]

A thickness of the HBL may be about 20 Å to about 1,000 Å, e.g., about 30 Å to about 300 Å. When a thickness of the HBL is within this range, excellent hole blocking properties of the organic light-emitting device may be obtained without substantial increase in driving voltage.

The electron transport region may include the ETL. The ETL may be formed on the EML or the HBL by using various methods such as vacuum deposition, spin coating, casting, LB deposition, inkjet printing, laser printing, or LITI. When the ETL is formed by methods such as vacuum deposition and spin coating, the deposition conditions and the coating conditions of the ETL may be referred to the de deposition conditions and the coating conditions of the HIL.

The electron transport region may include the EIL that facilitates injection of electrons from the second electrode 190.

The EIL may be formed on the ETL by using various methods such as vacuum deposition, spin coating, casting, LB deposition, inkjet printing, laser printing, or LITI. When the EIL is formed by vacuum deposition and spin coating, the deposition conditions and the coating conditions of the EIL may be referred to the de deposition conditions and the coating conditions of the HIL.

The EIL may include at least one selected from LiF, NaCl, CsF, Li₂O, BaO, and LiQ.

A thickness of the EIL may be about 1 Å to about 100 Å, e.g., about 3 Å to about 90 Å. When a thickness of the EIL is within this range, satisfactory electron injecting properties of the organic light-emitting device may be obtained without substantial increase in driving voltage.

The second electrode 190 may be disposed on the organic layer 150. The second electrode 190 may be a cathode, which is an electron injection electrode. In an implementation, a material for forming the second electrode 190 may include a metal, an alloy, an electric conducting compound, and a mixture thereof having a low work function. For example, the second electrode 190 may be a thin film formed of lithium (Li), magnesium (Mg), aluminum (Al), aluminum-lithium (Al—Li), calcium (Ca), magnesium-indium (Mg—In), or magnesium-silver (Mg—Ag). In an implementation, ITO or IZO may be used as a material for forming the second electrode 190. The second electrode 190 may be a reflecteive electrode, a semi-transparent electrode, or a transparent electrode.

However, an organic layer of an organic light-emitting device according to an embodiment may be formed by using a deposition method using a compound according to an embodiment or by using a wet method, in which the organic light-emitting device is coated with the compound that is prepared as a solution.

An organic light-emitting device according to an embodiment may be included in various types of flat panel displays, e.g., a passive matrix organic light-emitting display apparatus and an active matrix organic light-emitting display apparatus. For example, when the organic light-emitting device is included in an active matrix organic light-emitting display apparatus, a first electrode located on a side of a substrate is a pixel electrode which may be electrically connected to a source electrode or a drain electrode of a thin film transistor. Also, the organic light-emitting device may be included in a flat panel display that may display images on both surfaces.

The organic light-emitting device has been described with reference to FIG. 1, but an organic light-emitting device is not limited thereto.

Hereinafter, the OLED according to one or more embodiments will now be described in greater detail with reference to the following examples. The compounds used in the following examples are all commonly known compounds which are easily obtainable by one skilled in the art).

The following Examples and Comparative Examples are provided in order to highlight characteristics of one or more embodiments, but it will be understood that the Examples and Comparative Examples are not to be construed as limiting the scope of the embodiments, nor are the Comparative Examples to be construed as being outside the scope of the embodiments. Further, it will be understood that the embodiments are not limited to the particular details described in the Examples and Comparative Examples.

### EXAMPLE

### Example 1

An ITO glass substrate was cut to a size of 50 mm×50 mm×0.5 mm, sonicated by using isopropyl alcohol and pure water each for 15 minutes, and cleaned by the exposure to ultraviolet rays for 30 minutes and then to ozone. Then, HT1 was vacuum deposited on the substrate to form an HTL having a thickness of 1,200 Å. Then, hosts including CBP and PH1 at a ratio of 1:1 and a dopant including 10 wt % Ir(ppy)₃ were vacuum deposited on the HTL to form an EML having a thickness of 300 Å. Afterwards, IL1 was vacuum deposited on the EML to form an intermediate layer having a thickness 200 Å. Then, Alq₃ was vacuum deposited on the intermediate layer to form an ETL having a thickness of 200 Å. LiF and Al were subsequently formed on the ETL to form an EIL having a thickness of 10 Å and a cathode having a thickness of 2,000 Å, respectively, thereby manufacturing an organic light-emitting device.

### Example 2

An organic light-emitting device having a structure of ITO/HT1 (1,200 Å)/CBP+PH1+10% Ir(ppy)₃ (300 Å)/IL1 (200 Å)/Alq₃ (200 Å)/LiF (10 Å)/Al (2,000 Å) was manufactured in the same manner as in Example 1, except that PH2 was used instead of PH1 as a host in an EML.

### Example 3

An organic light-emitting device having a structure of ITO/HT1 (1200 Å)/SPPO+BSB+10% Ir(ppy)₃ (300 Å)/IL1 (200 Å)/Alq₃ (200 Å)/LiF (10 Å)/Al (2000 Å) was manufactured in the same manner as in Example 1, except that SPPO and BSB were used as hosts in an EML.

### Example 4

An organic light-emitting device having a structure of ITO/HT1 (1,200 Å)/BSB+PH1+10% Ir(ppy)₃ (300 Å)/IL1 (200 Å)/Alq₃ (200 Å)/LiF (10 Å)/Al (2,000 Å) was manufactured in the same manner as in Example 1, except that BSB was used instead of CBP as a host in an EML.

### Example 5

An organic light-emitting device having a structure of ITO/HT1 (1,200 Å)/CBP+PH1+10% Ir(ppy)₃ (300 Å)/IL2 (200 Å)/Alq₃ (200 Å)/LiF (10 Å)/Al (2,000 Å) was manufactured in the same manner as in Example 1, except that IL2 was used instead of IL1 in forming an intermediate layer.

### Example 6

An organic light-emitting device having a structure of ITO/HT1 (1,200 Å)/CBP+PH1+10% Ir(ppy)₃ (300 Å)/IL3 (200 Å)/Alq₃ (200 Å)/LiF (10 Å)/Al (2,000 Å) was manufactured in the same manner as in Example 1, except that IL3 was used instead of IL1 in forming an intermediate layer.

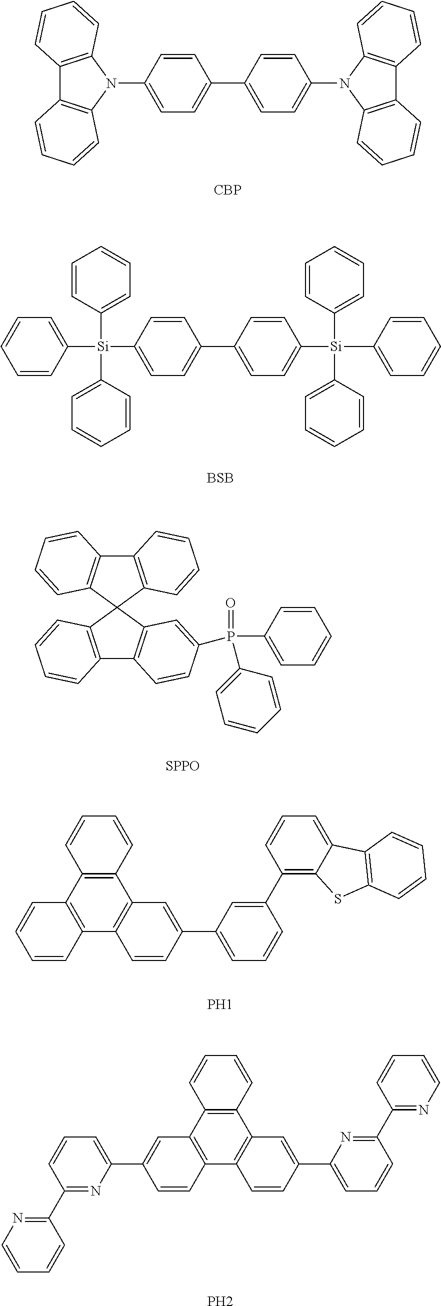

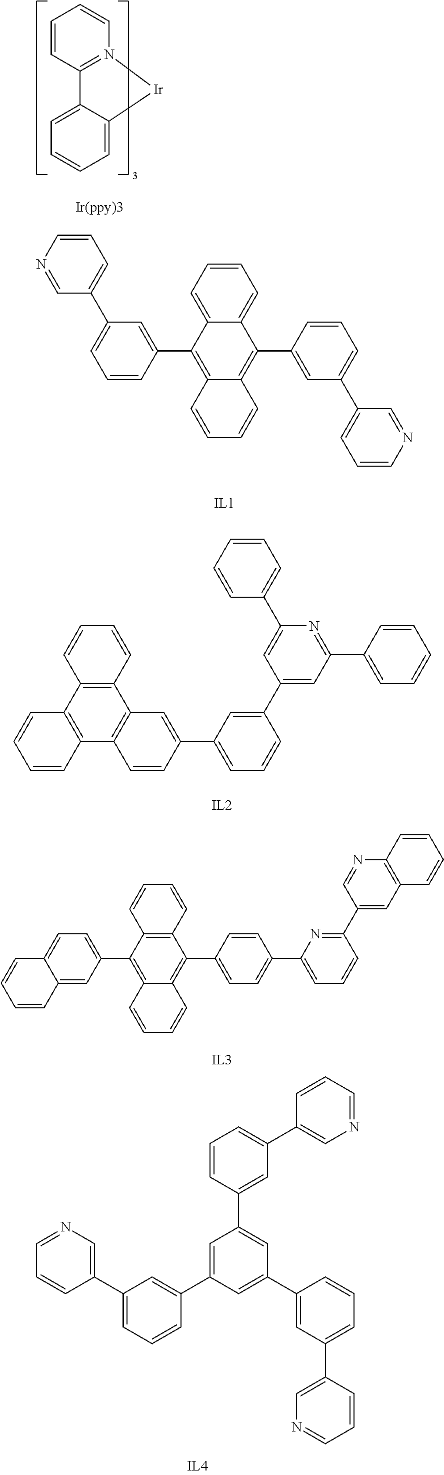

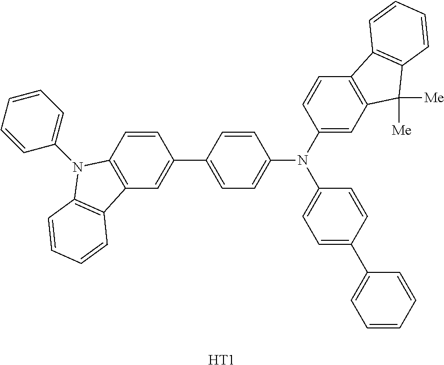 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; "HT1"]

### Comparative Example 1

### An Organic Light-Emitting Layer Having a Single Host and a Single ETL without an Intermediate Layer

An organic light-emitting device having a structure of ITO/HT1 (1,200 Å)/CBP+10% Ir(ppy)₃ (300 Å)/Alq₃ (400 Å)/LiF (10 Å)/Al (2,000 Å) was manufactured in the same manner as in Example 1.

### Comparative Example 2

### An Organic Light-Emitting Layer Having CBP as a Single Phosphorescent Host (a Case not Applying Two Different Hosts)

An organic light-emitting device having a structure of ITO/HT1 (1,200 Å)/CBP+10% Ir(ppy)₃ (300 Å) IL1 (200 Å)/Alq₃ (200 Å)/LiF (10 Å)/Al (2,000 Å) was manufactured in the same manner as in Example 1.

### Comparative Example 3

### An Organic Light-Emitting Device Having PH1 as a Triphenylene-Based Single Host (a Case not Applying Two Different Hosts)

An organic light-emitting device having a structure of ITO/HT1 (1,200 Å)/PH1+10% Ir(ppy)₃ (300 Å)/IL1 (200 Å)/Alq₃ (200 Å)/LiF (10 Å)/Al (2,000 Å) was manufactured in the same manner as in Example 1.

### Comparative Example 4

### An Organic Light-Emitting Device Having Satisfactory Hosts but not Including a Compound of Formula 1 for an Intermediate Layer

An organic light-emitting device having a structure of ITO/HT1 (1,200 Å)/CBP+PH1+10% Ir(ppy)₃ (300 Å)/IL4 (200 Å)/Alq₃ (200 Å)/LiF (10 Å)/Al (2,000 Å) was manufactured in the same manner as in Example 1.

Electron affinities of phosphorescent hosts and materials for an intermediate layer were measured and comparative results thereof are shown in Table 1, below.

TABLE 1

| | EA |
|---|---|
| | (electron affinity) |
| CBP | 3.0 eV |
| BSB | 2.3 eV |
| SPPO | 2.7 eV |
| PH1 | 2.2 eV |
| PH2 | 2.5 eV |
| IL1 | 2.8 eV |
| IL2 | 2.5 eV |
| IL3 | 2.8 eV |
| IL4 | 2.7 eV |

It was found that the organic light-emitting devices of Example 1 to 4 had excellent properties, compared to those of Comparative Examples 1 to 4, and the results thereof are shown in Table 2, below.

TABLE 2

| | Host in | | | | |
|---|---|---|---|---|---|
| | phosphorescent | Inter- | | Driving | |
| | EML | mediate | Efficiency | voltage | T90 |
| | [dopant Ir(ppy)³] | layer | (cd/A) | (V) | (hr) |
| Example 1 | CBP:PH1 | IL1 | 65 cd/A | 4.4 V | 211 hr |
| Example 2 | CBP:PH2 | IL1 | 68 cd/A | 4.5 V | 238 hr |
| Example 3 | SPPO:BSB | IL1 | 63 cd/A | 4.7 V | 196 hr |
| Example 4 | BSB:PH1 | IL1 | 65 cd/A | 4.7 V | 183 hr |
| Example 5 | CBP:PH1 | IL2 | 62 cd/A | 4.8 V | 192 hr |
| Example 6 | CBP:PH1 | IL3 | 64 cd/A | 4.7 V | 220 hr |
| Comparative | Single host CBP | None | 44 cd/A | 5.8 V | 49 hr |
| Example 1 | | | | | |
| Comparative | Single host CBP | IL1 | 48 cd/A | 5.3 V | 66 hr |
| Example 2 | | | | | |
| Comparative | Single host PH1 | IL1 | 51 cd/A | 5.5 V | 85 hr |
| Example 3 | | | | | |
| Comparative | CBP:PH1 | IL4 | 58 cd/A | 5.1 V | 160 hr |
| Example 4 | | | | | |

By way of summation and review, when a phosphorescent material is introduced to an organic light-emitting device, the organic light-emitting device may be manufactured as a device having a significantly high efficiency, compared to a device using a fluorescent material. Such a phosphorescent material may have good emission properties, and in order to ideally achieve a high efficiency in the organic light-emitting device, energy generated in the EML may be confined within the EML. In regard to a phosphorescent organic light-emitting device, in an effort to help reduce and/or prevent diffusion of triplet excitons to the outside of the EML, wherein the triplet excitons have a longer lifespan than single excitons, a material having a high triplet energy may be used for a layer adjacent to the EML, thereby manufacturing the organic light-emitting device having a high efficiency. In order to have triplet excitons that efficiently emit from a dopant, a phosphorescent host may be set to have a triplet energy higher than that of a dopant. In this regard, a host molecule may have a wide energy gap and a low electron affinity. Then, there may be hindrance to electron injection to a host, an increase in a driving voltage of the organic light-emitting device, and degradation of an emission efficiency of the organic light-emitting device. In addition, recombination of the holes and electrons may occur intensely on a side of the cathode from the EML where the electron carriers are accumulated, and thus, a light-emitting lifespan of the organic light-emitting device may be degraded.

As described above, according to the one or more of the embodiments, an organic light-emitting device may have a low driving voltage, a high efficiency, and a long lifespan.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting device, comprising:
an anode;
a cathode; and
an organic layer between the anode and the cathode, the organic layer including:
an emission layer (EML), the EML including a first host and a second host,
a hole transport region between the anode and the EML, the hole transport region including at least one of a hole injection layer (HIL), a hole transport layer (HTL), a buffer layer, or an electron blocking layer (EBL),
an electron transport region between the EML and the cathode, the electron transport region including at least one of a hole blocking layer (HBL), an electron transport layer (ETL), or an electron injection layer (EIL), and
an intermediate layer between the EML and the electron transport region;
wherein an electron affinity of a compound of the intermediate layer [EA_{intermediate layer}] and an electron affinity of the first host [EAₕₒₛₜ₁] satisfy a relationship represented by the following expression:
EA_{intermediate layer}≧EAₕₒₛₜ₁+0.3 eV.

2. The organic light-emitting device as claimed in claim 1, wherein the EML is a phosphorescent EML.

3. The organic light-emitting device as claimed in claim 1, wherein the EML is a phosphorescent EML, the EML including a dopant that emits phosphorescence having a main peak of at least 450 nm.

4. The organic light-emitting device as claimed in claim 1, wherein at least one of the first host or the second host is a compound that includes a triphenylene moiety or a carbazole moiety.

5. The organic light-emitting device as claimed in claim 1, wherein the electron affinity of the first host (EAₕₒₛₜ₁) and an electron affinity of the second host (EAₕₒₛₜ₂) satisfy a relationship represented by the following expression:
EAₕₒₛₜ₁<EAₕₒₛₜ₂.

6. The organic light-emitting device as claimed in claim 1, wherein:
the intermediate layer contacts the EML, and
the intermediate layer includes a compound in which a backbone structure of an aromatic hydrocarbon having at least 3 condensed polycyclic rings is substituted with an aromatic heteroaryl group having 3 or fewer nitrogen atoms.

7. The organic light-emitting device as claimed in claim 1, wherein the HTL includes a compound that has an ionization potential of 5.3 eV to about 5.8 eV.

8. The organic light-emitting device as claimed in claim 1, wherein the EML is a phosphorescent EML and the EML includes a dopant, the dopant including an Ir-complex, a Pt-complex, an Os-complex, or a Cu-complex.

9. The organic light-emitting device as claimed in claim 1, wherein the hole transport region includes a p-dopant.

10. The organic light-emitting device as claimed in claim 1, wherein the hole transport region includes a p-dopant, the p-dopant including a quinone derivative, a metal oxide, or a cyano group-containing compound.

11. The organic light-emitting device as claimed in claim 1, wherein the intermediate layer includes a compound represented by Formula 1 or 2 below: 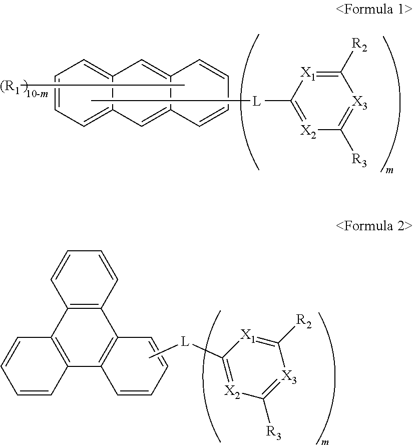
wherein, in Formulae 1 and 2,
X₁ to X₃ are each independently CR₄ or N, at least one of X₁ to X₃ being N;
L is a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₆-C₆₀ arylene group, or a substituted or unsubstituted C₂-C₆₀ heteroarylene group;
R₁ to R₄ are each independently a hydrogen, a deuterium, a halogen atom, a cyano group, a thiol group, a substituted or unsubstituted C₁-C₆₀ alkyl group, a substituted or unsubstituted C₁-C₆₀ alkoxy group, a substituted or unsubstituted C₂-C₆₀ alkenyl group, a substituted or unsubstituted C₆-C₆₀ aryl group, a substituted or unsubstituted C₆-C₆₀ aryloxy group, a substituted or unsubstituted C₁-C₆₀ heteroalkyl group having at least one selected from sulfur (S), nitrogen (N), oxygen (O), phosphorous (P), and silicon (Si), a substituted or unsubstituted C₂-C₆₀ heteroaryl group, or a substituted or unsubstituted C₂-C₆₀ heteroaryloxy group; and/or adjacent substituents of to R₂ to R₄ link together and form a ring; and
m is an integer of 1 to 9.

12. The organic light-emitting device as claimed in claim 11, wherein R₁ to R₄ are each independently a hydrogen, a deuterium, a substituted or unsubstituted C₁-C₃₀ alkyl group, or a group represented by one of Formulae 2a to 2x below: 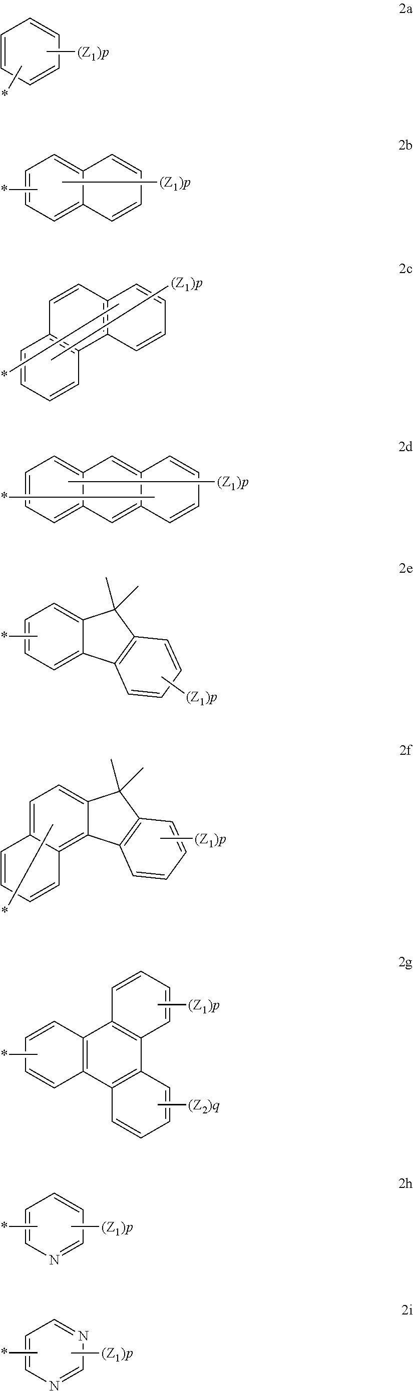 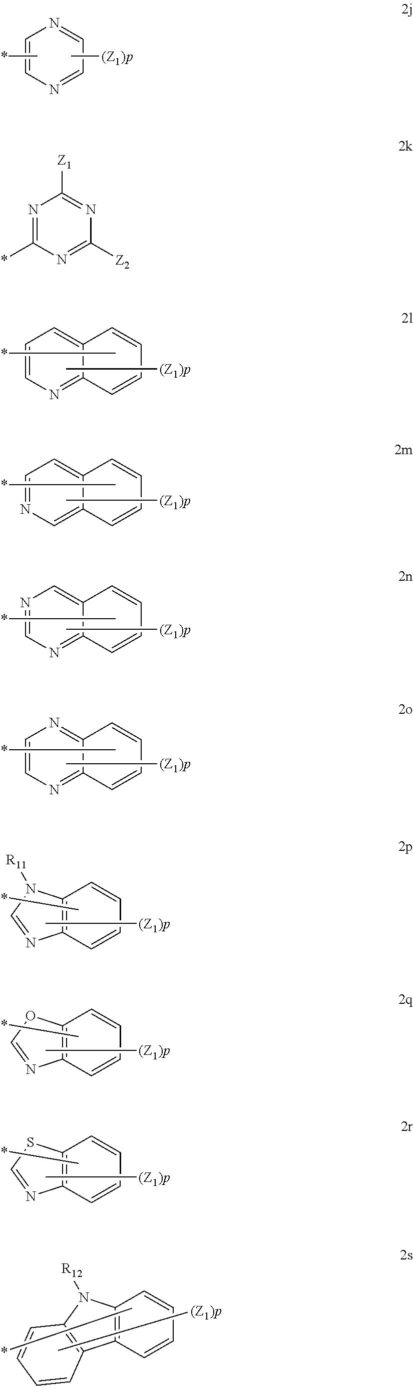 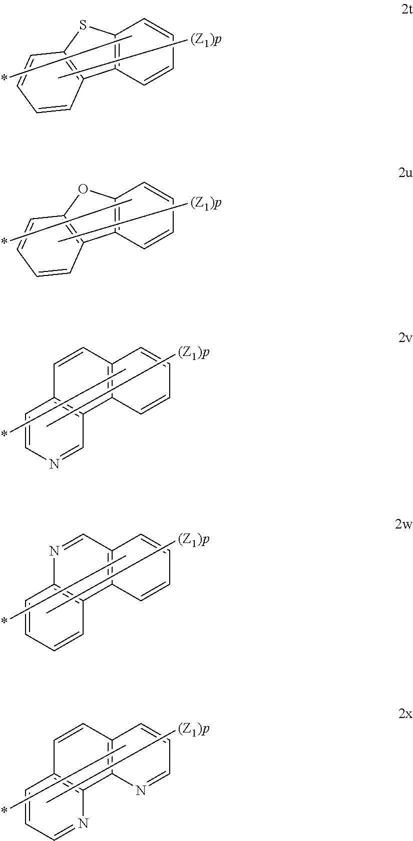
wherein, in Formulae 2a to 2x,
R₁₁, R₁₂, Z₁, and Z₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted monovalent non-aromatic condensed polycyclic group, and a substituted or unsubstituted monovalent non-aromatic hetero-condensed polycyclic group;
p and q are each independently an integer of 1 to 9;
when p and q are 2 or greater, a plurality of Z₁ and Z₂ are identical to or different from each other; and
* indicates a binding site with a neighboring atom.

13. The organic light-emitting device as claimed in claim 11, wherein L is a single bond or a group represented by one of Formulae 3a to 3x below: 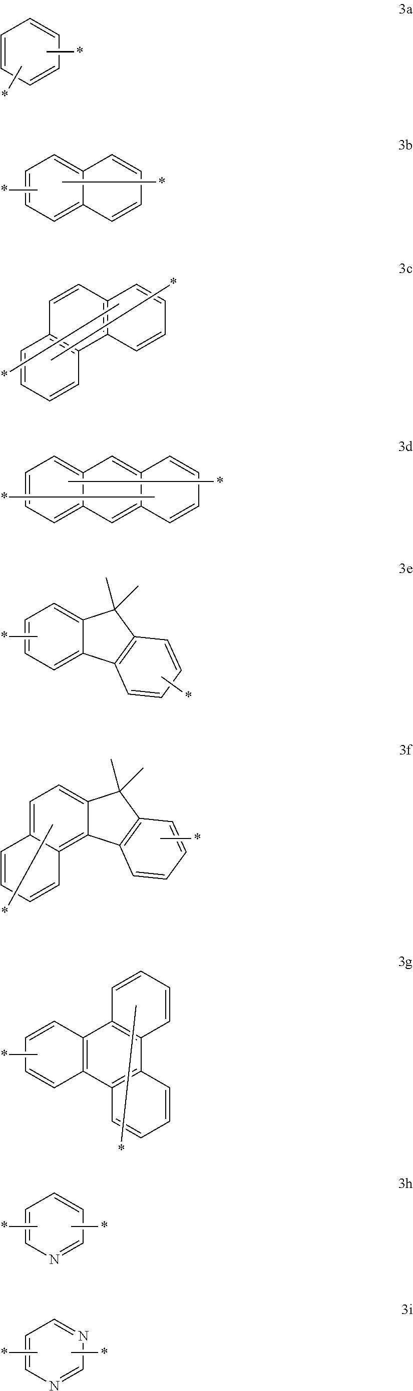 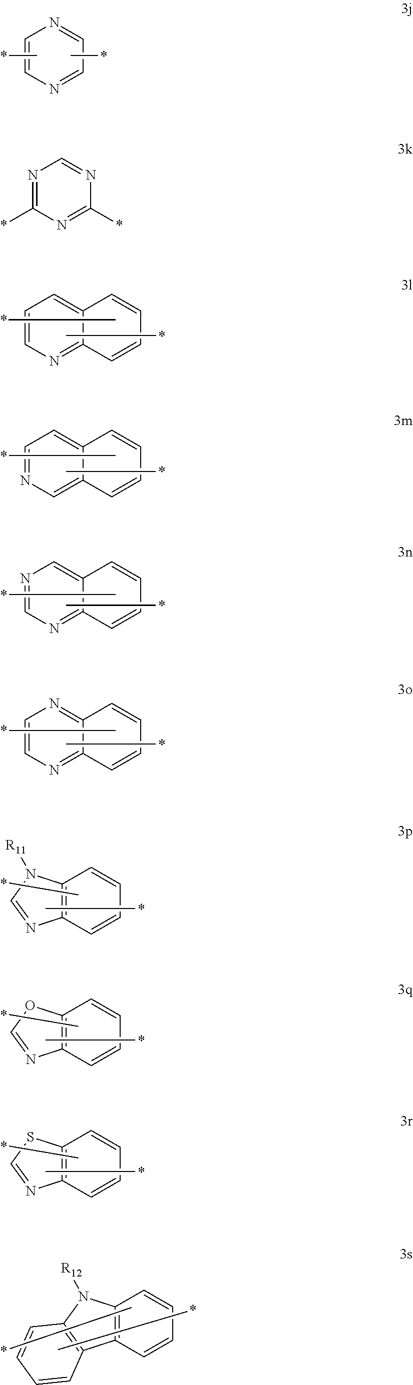 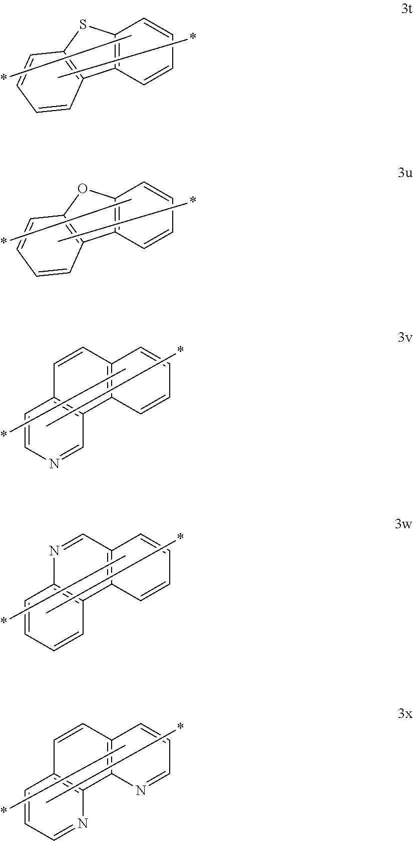
wherein, in Formulae 3a to 3x, R₁₁ and R₁₂ are each independently selected from a hydrogen, a deuterium, —F, —Cl, —Br, —I, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a substituted or unsubstituted C₁-C₂₀ alkyl group, a substituted or unsubstituted C₆-C₂₀ aryl group, a substituted or unsubstituted C₂-C₂₀ heteroaryl group, a substituted or unsubstituted non-aromatic condensed polycyclic group, and a substituted or unsubstituted monovalent non-aromatic hetero-condensed polycyclic group; and
* indicates a binding site with a neighboring atom.

14. The organic light-emitting device as claimed in claim 11, wherein m is an integer of 1 or 2.

15. The organic light-emitting device as claimed in claim 11, wherein the intermediate layer includes the compound represented by Formula 1, the compound represented by Formula 1 being represented by Formula 3 below: 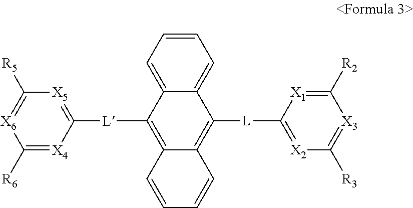
wherein, in Formula 3,
X₁ to X₃ are each independently CR₄ or N, at least one of X₁ to X₃ being N;
X₄ to X₆ are each independently CR₄ or N, at least one of X₄ to X₆ being N;
L and L′ are each independently a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₆-C₆₀ arylene group, or a substituted or unsubstituted C₂-C₆₀ heteroarylene group;
R₂ to R₆ are each independently a hydrogen, a deuterium, a halogen atom, a cyano group, a thiol group, a substituted or unsubstituted C₁-C₆₀ alkyl group, a substituted or unsubstituted C₁-C₆₀ alkoxy group, a substituted or unsubstituted C₂-C₆₀ alkenyl group, a substituted or unsubstituted C₆-C₆₀ aryl group, a substituted or unsubstituted C₆-C₆₀ aryloxy group, a substituted or unsubstituted C₁-C₆₀ heteroalkyl group having at least one selected from sulfur (S), nitrogen (N), oxygen (O), phosphorous (P), and silicon (Si), a substituted or unsubstituted C₂-C₆₀ heteroaryl group, or a substituted or unsubstituted C₂-C₆₀ heteroaryloxy group; or adjacent substituents of to R₂ to R₄ or R₄ to R₆ link together and form a ring.

16. The organic light-emitting device as claimed in claim 1, wherein the first host and the second host are each independently one of the following compounds:

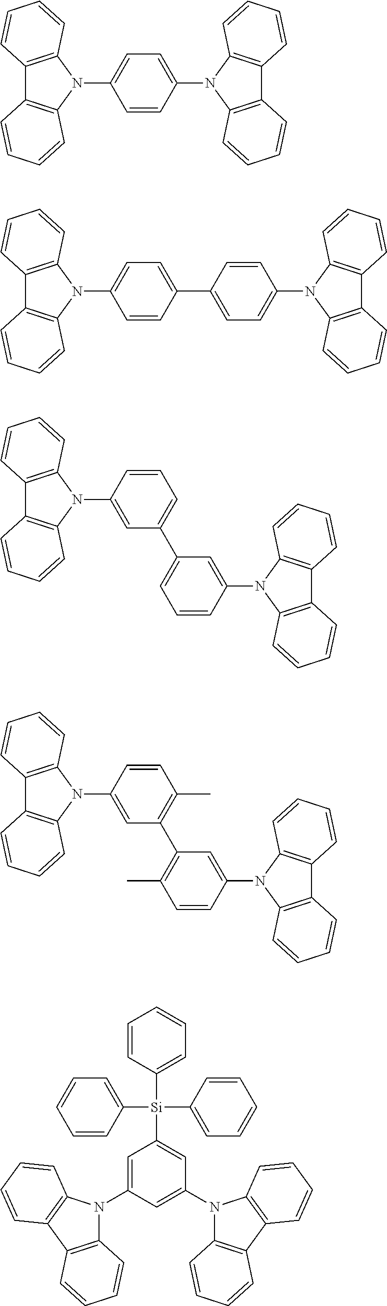

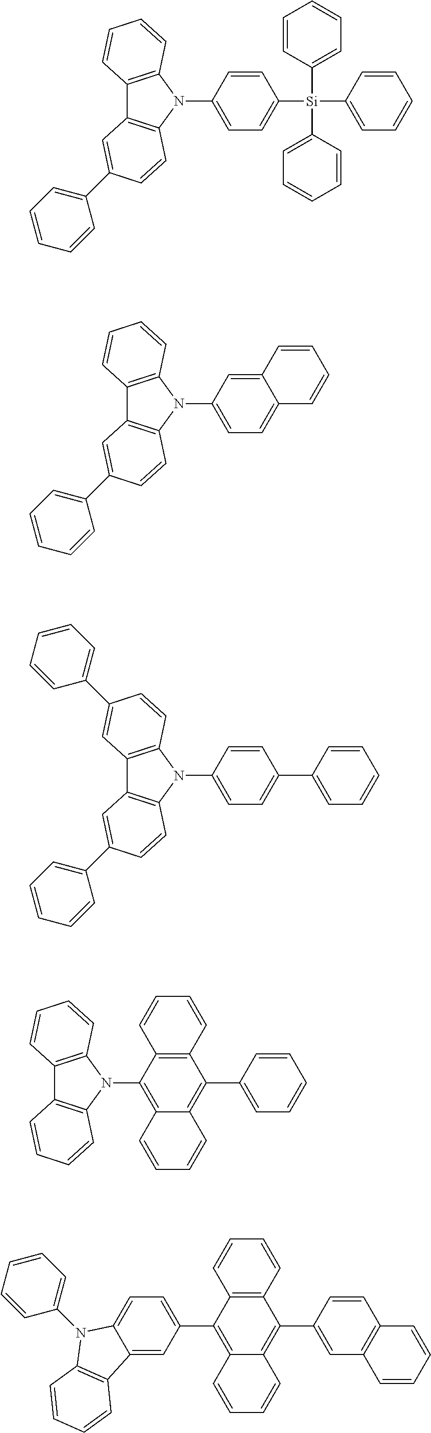 [SMILES: c1ccc(-c2ccc3c(c2)c2ccccc2n3-c2ccc([Si](c3ccccc3)(c3ccccc3)c3ccccc3)cc2)cc1 ; c1ccc(-c2ccc3c(c2)c2ccccc2n3-c2ccc3ccccc3c2)cc1 ; c1ccc(-c2ccc(-n3c4ccc(-c5ccccc5)cc4c4cc(-c5ccccc5)ccc43)cc2)cc1 ; c1ccc(-c2c3ccccc3c(-n3c4ccccc4c4ccccc43)c3ccccc23)cc1 ; c1ccc(-n2c3ccccc3c3cc(-c4c5ccccc5c(-c5ccc6ccccc6c5)c5ccccc45)ccc32)cc1]

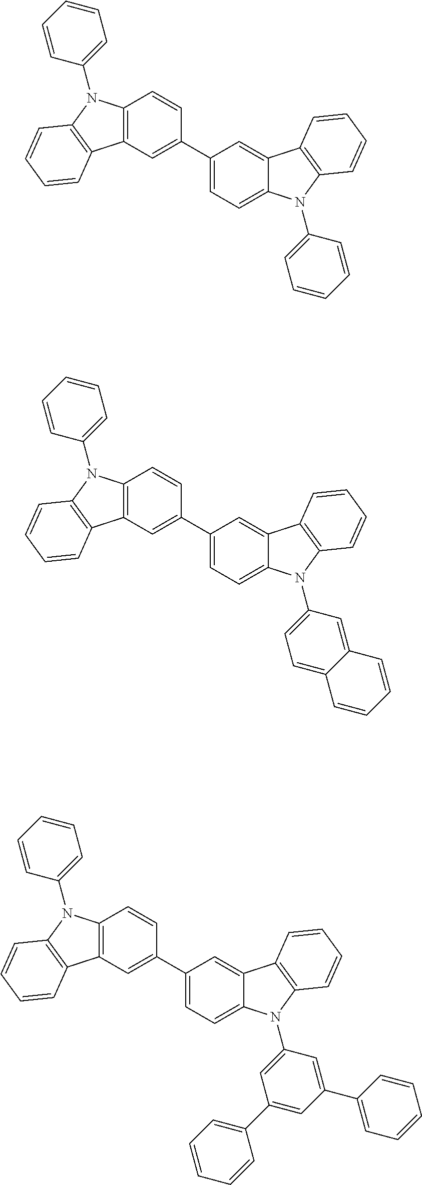 [SMILES: c1ccc(-n2c3ccccc3c3cc(-c4ccc5c(c4)c4ccccc4n5-c4ccccc4)ccc32)cc1 ; c1ccc(-n2c3ccccc3c3cc(-c4ccc5c(c4)c4ccccc4n5-c4ccc5ccccc5c4)ccc32)cc1 ; c1ccc(-c2cc(-c3ccccc3)cc(-n3c4ccccc4c4cc(-c5ccc6c(c5)c5ccccc5n6-c5ccccc5)ccc43)c2)cc1]

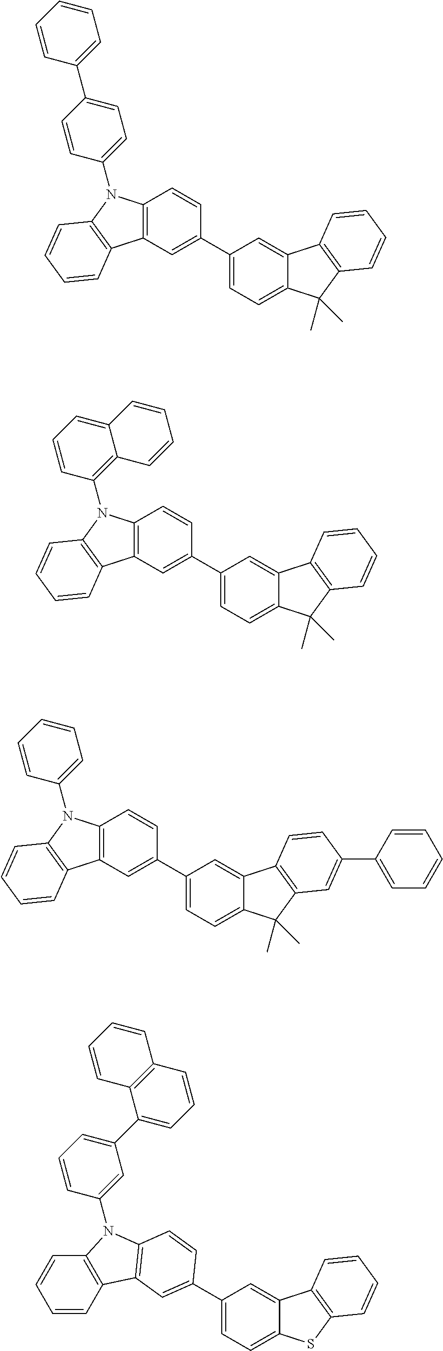 [SMILES: CC1(C)c2ccccc2-c2cc(-c3ccc4c(c3)c3ccccc3n4-c3ccc(-c4ccccc4)cc3)ccc21 ; CC1(C)c2ccccc2-c2cc(-c3ccc4c(c3)c3ccccc3n4-c3cccc4ccccc34)ccc21 ; CC1(C)c2ccc(-c3ccc4c(c3)c3ccccc3n4-c3ccccc3)cc2-c2ccc(-c3ccccc3)cc21 ; c1cc(-c2cccc3ccccc23)cc(-n2c3ccccc3c3cc(-c4ccc5sc6ccccc6c5c4)ccc32)c1]

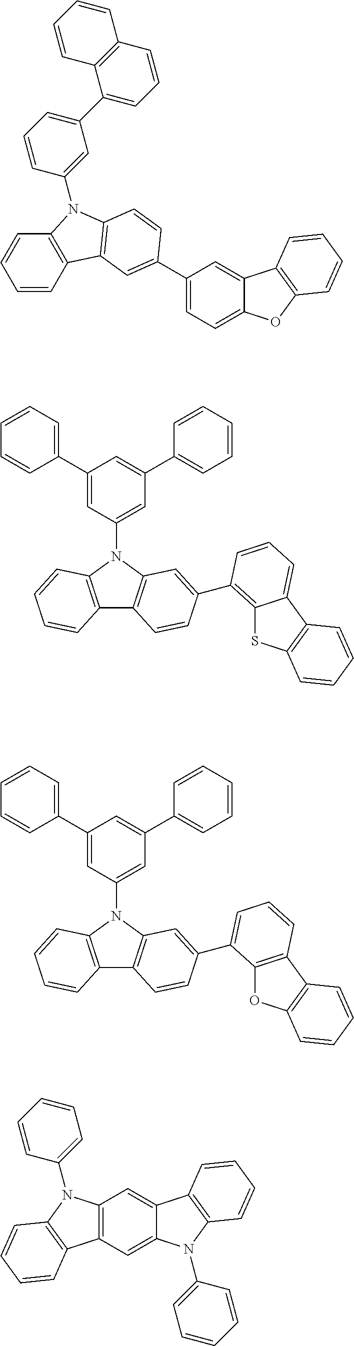 [SMILES: c1cc(-c2cccc3ccccc23)cc(-n2c3ccccc3c3cc(-c4ccc5oc6ccccc6c5c4)ccc32)c1 ; c1ccc(-c2cc(-c3ccccc3)cc(-n3c4ccccc4c4ccc(-c5cccc6c5sc5ccccc56)cc43)c2)cc1 ; c1ccc(-c2cc(-c3ccccc3)cc(-n3c4ccccc4c4ccc(-c5cccc6c5oc5ccccc56)cc43)c2)cc1 ; c1ccc(-n2c3ccccc3c3cc4c(cc32)c2ccccc2n4-c2ccccc2)cc1]

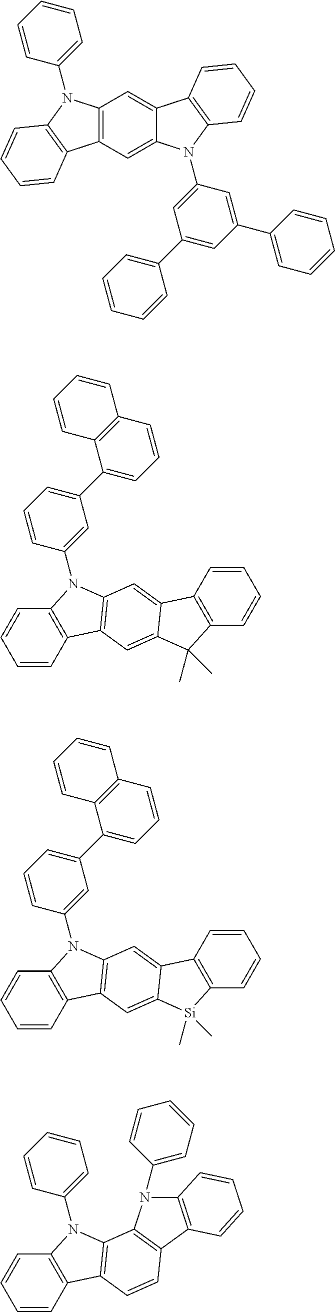 [SMILES: c1ccc(-c2cc(-c3ccccc3)cc(-n3c4ccccc4c4cc5c(cc43)c3ccccc3n5-c3ccccc3)c2)cc1 ; CC1(C)c2ccccc2-c2cc3c(cc21)c1ccccc1n3-c1cccc(-c2cccc3ccccc23)c1 ; C[Si]1(C)c2ccccc2-c2cc3c(cc21)c1ccccc1n3-c1cccc(-c2cccc3ccccc23)c1 ; c1ccc(-n2c3ccccc3c3ccc4c5ccccc5n(-c5ccccc5)c4c32)cc1]

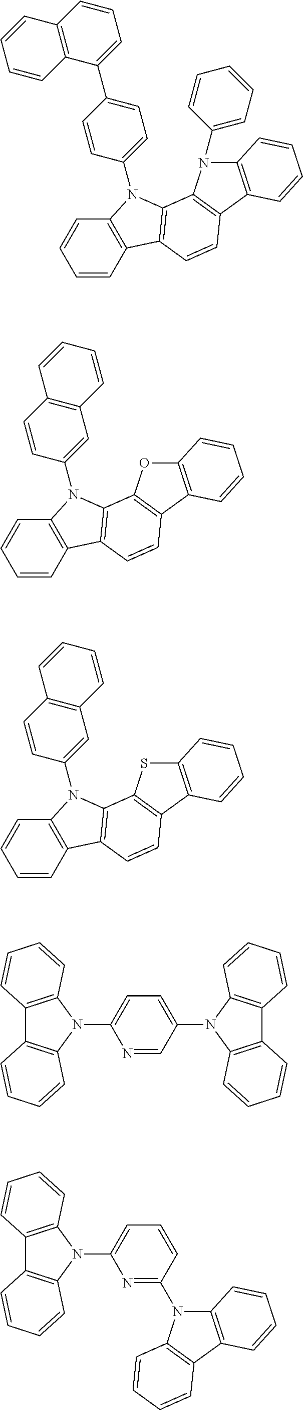 [SMILES: c1ccc(-n2c3ccccc3c3ccc4c5ccccc5n(-c5ccc(-c6cccc7ccccc67)cc5)c4c32)cc1 ; c1ccc2cc(-n3c4ccccc4c4ccc5c6ccccc6oc5c43)ccc2c1 ; c1ccc2cc(-n3c4ccccc4c4ccc5c6ccccc6sc5c43)ccc2c1 ; c1ccc2c(c1)c1ccccc1n2-c1ccc(-n2c3ccccc3c3ccccc32)nc1 ; c1cc(-n2c3ccccc3c3ccccc32)nc(-n2c3ccccc3c3ccccc32)c1]

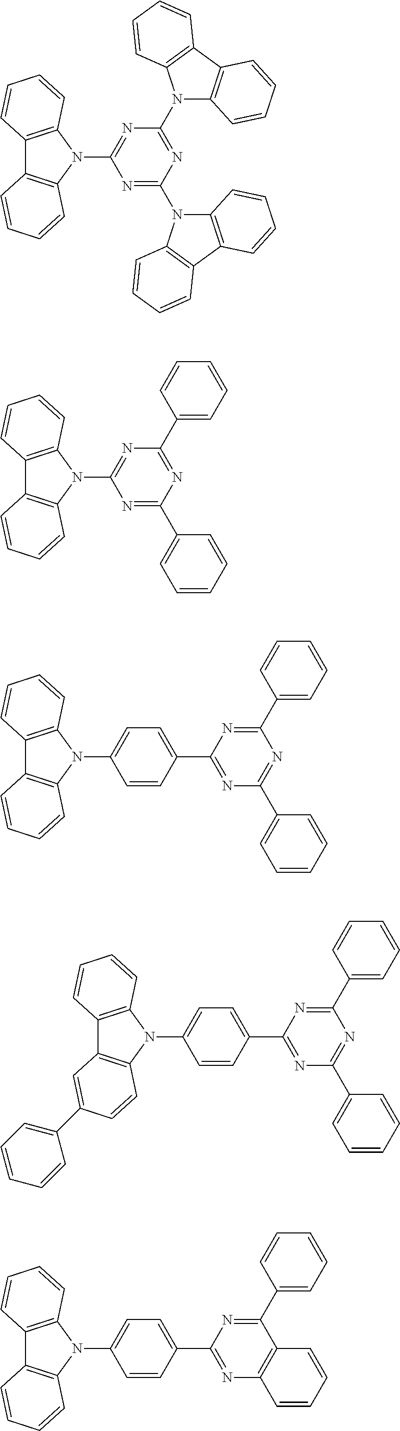 [SMILES: c1ccc2c(c1)c1ccccc1n2-c1nc(-n2c3ccccc3c3ccccc32)nc(-n2c3ccccc3c3ccccc32)n1 ; c1ccc(-c2nc(-c3ccccc3)nc(-n3c4ccccc4c4ccccc43)n2)cc1 ; c1ccc(-c2nc(-c3ccccc3)nc(-c3ccc(-n4c5ccccc5c5ccccc54)cc3)n2)cc1 ; c1ccc(-c2ccc3c(c2)c2ccccc2n3-c2ccc(-c3nc(-c4ccccc4)nc(-c4ccccc4)n3)cc2)cc1 ; c1ccc(-c2nc(-c3ccc(-n4c5ccccc5c5ccccc54)cc3)nc3ccccc23)cc1]

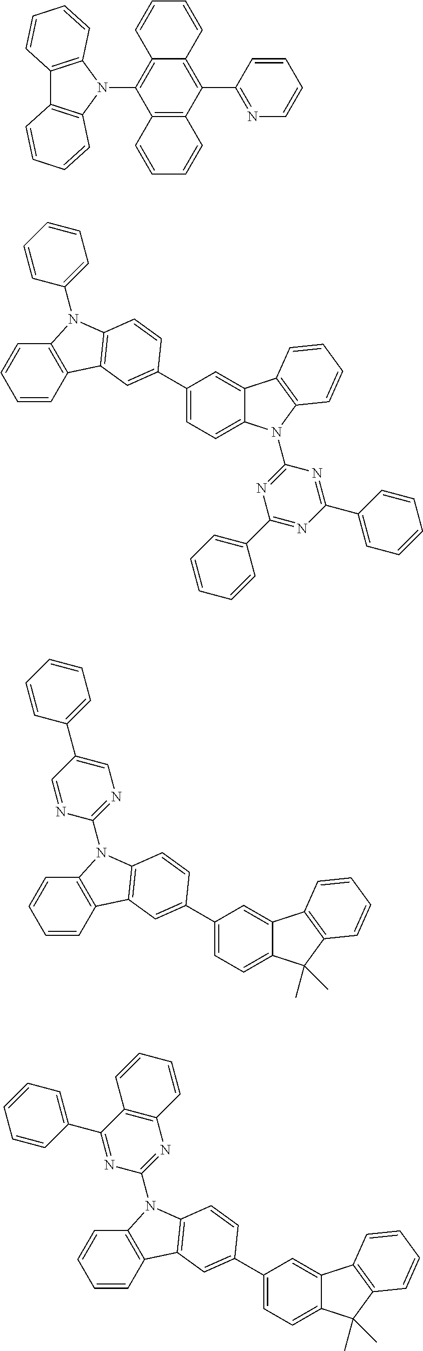 [SMILES: c1ccc(-c2c3ccccc3c(-n3c4ccccc4c4ccccc43)c3ccccc23)nc1 ; c1ccc(-c2nc(-c3ccccc3)nc(-n3c4ccccc4c4cc(-c5ccc6c(c5)c5ccccc5n6-c5ccccc5)ccc43)n2)cc1 ; CC1(C)c2ccccc2-c2cc(-c3ccc4c(c3)c3ccccc3n4-c3ncc(-c4ccccc4)cn3)ccc21 ; CC1(C)c2ccccc2-c2cc(-c3ccc4c(c3)c3ccccc3n4-c3nc(-c4ccccc4)c4ccccc4n3)ccc21]

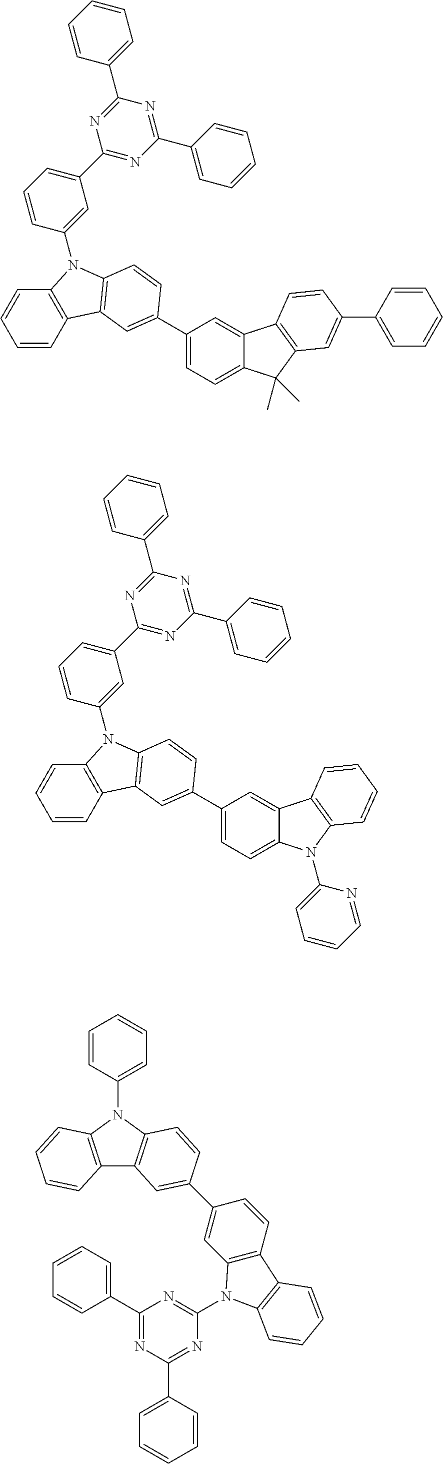 [SMILES: CC1(C)c2ccc(-c3ccc4c(c3)c3ccccc3n4-c3cccc(-c4nc(-c5ccccc5)nc(-c5ccccc5)n4)c3)cc2-c2ccc(-c3ccccc3)cc21 ; c1ccc(-c2nc(-c3ccccc3)nc(-c3cccc(-n4c5ccccc5c5cc(-c6ccc7c(c6)c6ccccc6n7-c6ccccn6)ccc54)c3)n2)cc1 ; c1ccc(-c2nc(-c3ccccc3)nc(-n3c4ccccc4c4ccc(-c5ccc6c(c5)c5ccccc5n6-c5ccccc5)cc43)n2)cc1]

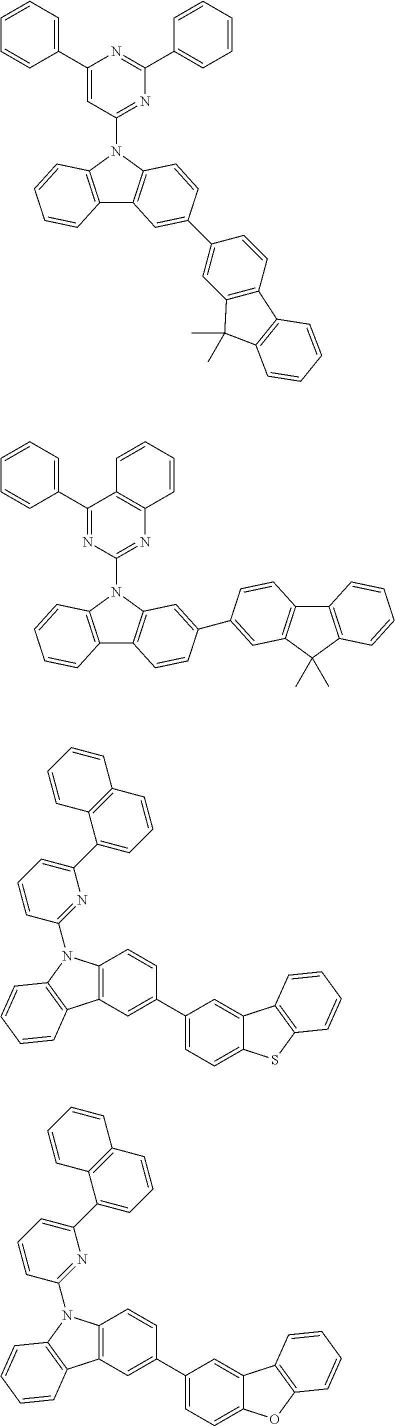

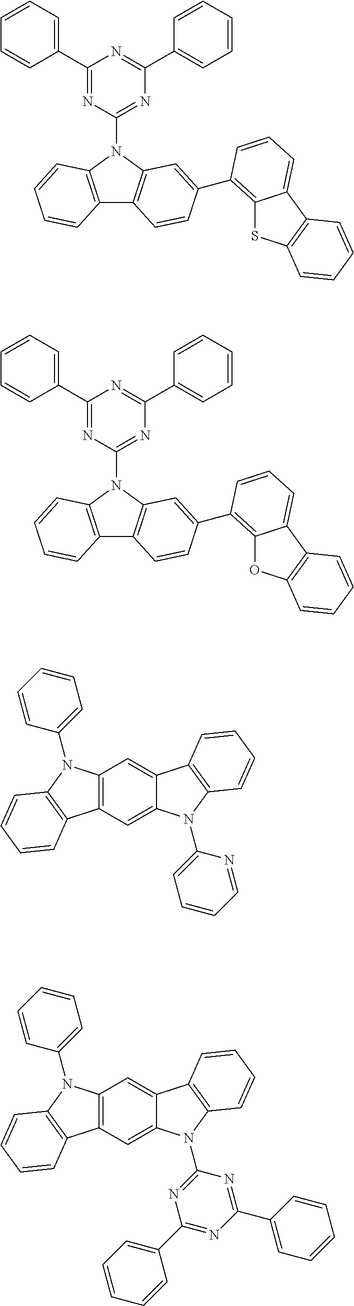 [SMILES: c1ccc(-c2nc(-c3ccccc3)nc(-n3c4ccccc4c4ccc(-c5cccc6c5sc5ccccc56)cc43)n2)cc1 ; c1ccc(-c2nc(-c3ccccc3)nc(-n3c4ccccc4c4ccc(-c5cccc6c5oc5ccccc56)cc43)n2)cc1 ; c1ccc(-n2c3ccccc3c3cc4c(cc32)c2ccccc2n4-c2ccccn2)cc1 ; c1ccc(-c2nc(-c3ccccc3)nc(-n3c4ccccc4c4cc5c(cc43)c3ccccc3n5-c3ccccc3)n2)cc1]

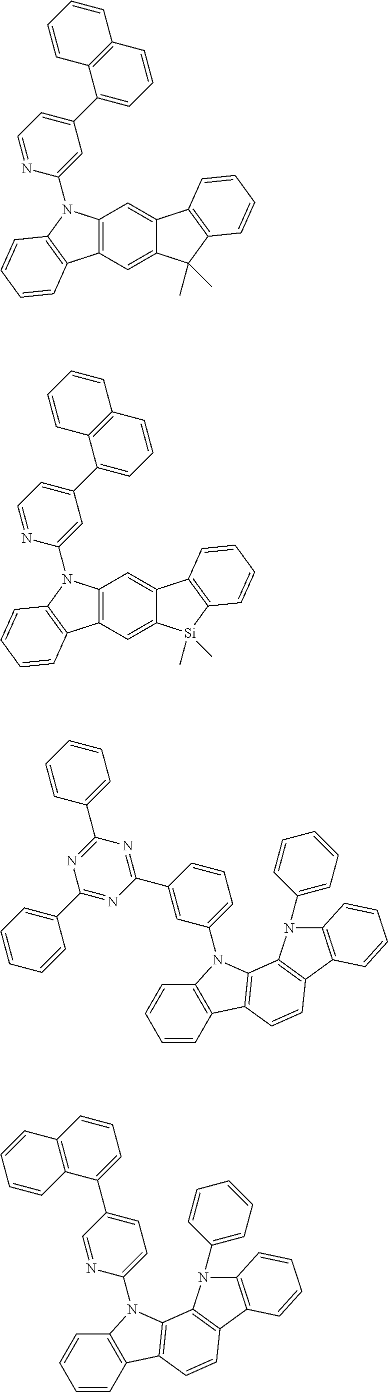 [SMILES: CC1(C)c2ccccc2-c2cc3c(cc21)c1ccccc1n3-c1cc(-c2cccc3ccccc23)ccn1 ; C[Si]1(C)c2ccccc2-c2cc3c(cc21)c1ccccc1n3-c1cc(-c2cccc3ccccc23)ccn1 ; c1ccc(-c2nc(-c3ccccc3)nc(-c3cccc(-n4c5ccccc5c5ccc6c7ccccc7n(-c7ccccc7)c6c54)c3)n2)cc1 ; c1ccc(-n2c3ccccc3c3ccc4c5ccccc5n(-c5ccc(-c6cccc7ccccc67)cn5)c4c32)cc1]

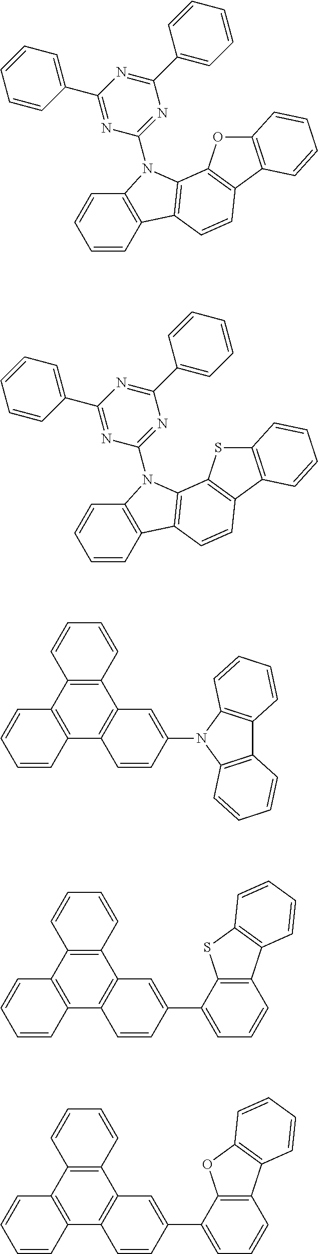 [SMILES: c1ccc(-c2nc(-c3ccccc3)nc(-n3c4ccccc4c4ccc5c6ccccc6oc5c43)n2)cc1 ; c1ccc(-c2nc(-c3ccccc3)nc(-n3c4ccccc4c4ccc5c6ccccc6sc5c43)n2)cc1 ; c1ccc2c(c1)c1ccccc1c1cc(-n3c4ccccc4c4ccccc43)ccc21 ; c1ccc2c(c1)sc1c(-c3ccc4c5ccccc5c5ccccc5c4c3)cccc12 ; c1ccc2c(c1)oc1c(-c3ccc4c5ccccc5c5ccccc5c4c3)cccc12]

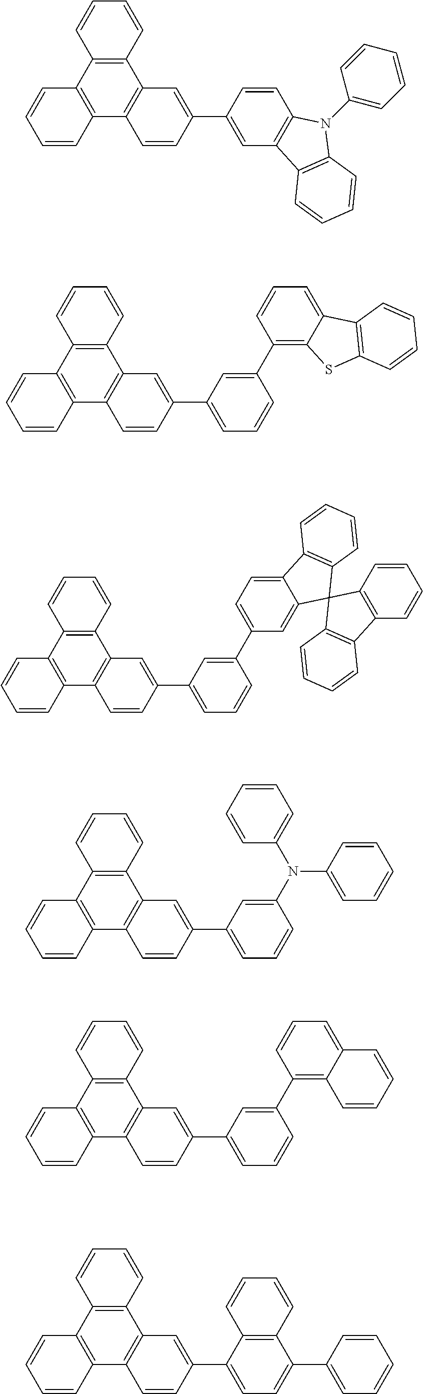

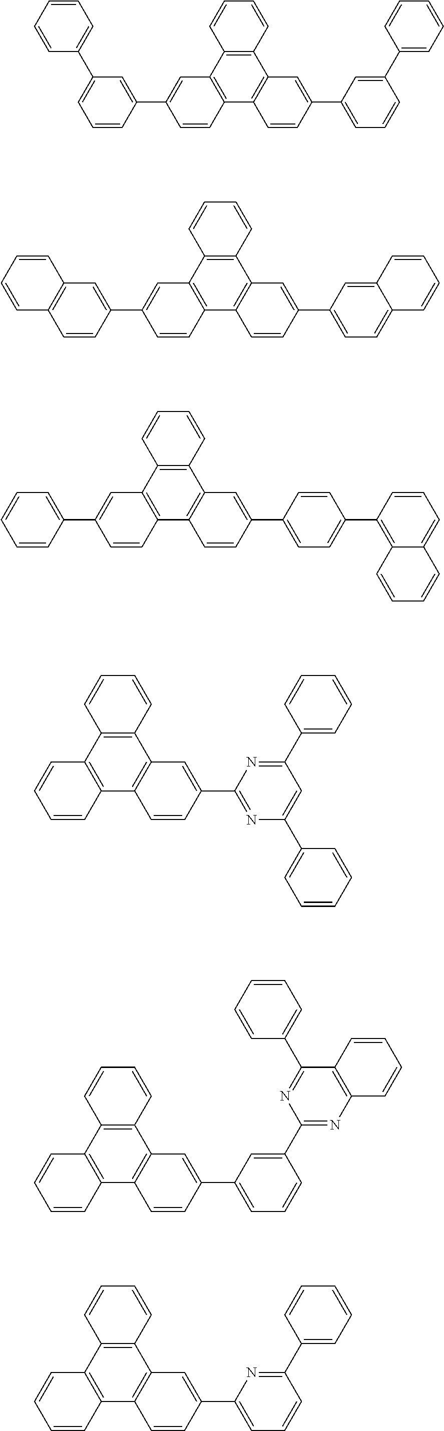

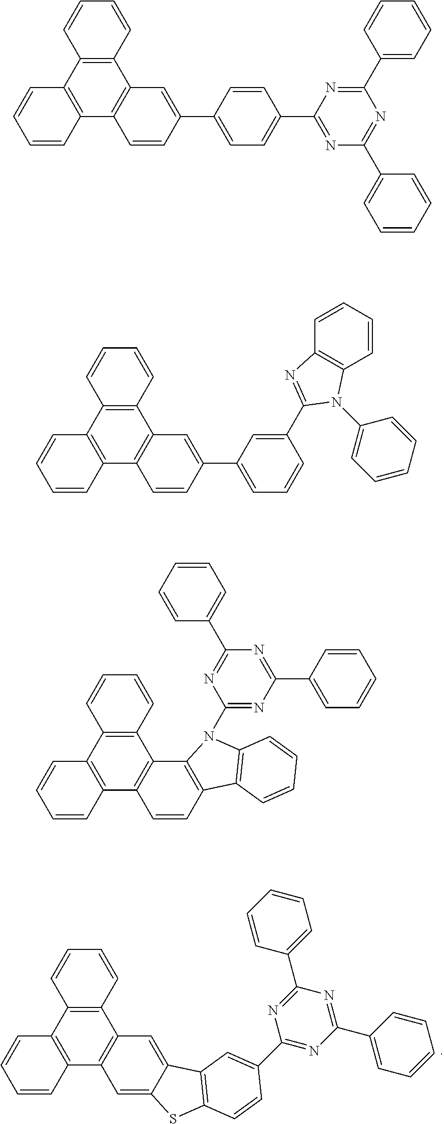 [SMILES: c1ccc(-c2nc(-c3ccccc3)nc(-c3ccc(-c4ccc5c6ccccc6c6ccccc6c5c4)cc3)n2)cc1 ; c1ccc(-n2c(-c3cccc(-c4ccc5c6ccccc6c6ccccc6c5c4)c3)nc3ccccc32)cc1 ; c1ccc(-c2nc(-c3ccccc3)nc(-n3c4ccccc4c4ccc5c6ccccc6c6ccccc6c5c43)n2)cc1 ; c1ccc(-c2nc(-c3ccccc3)nc(-c3ccc4sc5cc6c7ccccc7c7ccccc7c6cc5c4c3)n2)cc1]

17. The organic light-emitting device as claimed in claim 1, wherein the intermediate layer includes one of the following compounds:

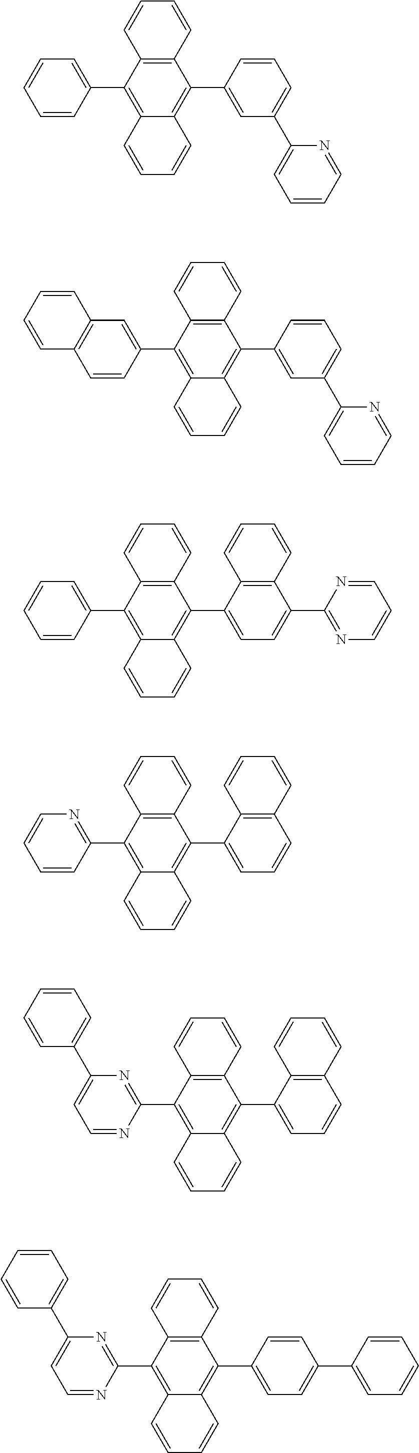 [SMILES: c1ccc(-c2c3ccccc3c(-c3cccc(-c4ccccn4)c3)c3ccccc23)cc1 ; c1ccc(-c2cccc(-c3c4ccccc4c(-c4ccc5ccccc5c4)c4ccccc34)c2)nc1 ; c1ccc(-c2c3ccccc3c(-c3ccc(-c4ncccn4)c4ccccc34)c3ccccc23)cc1 ; c1ccc(-c2c3ccccc3c(-c3cccc4ccccc34)c3ccccc23)nc1 ; c1ccc(-c2ccnc(-c3c4ccccc4c(-c4cccc5ccccc45)c4ccccc34)n2)cc1 ; c1ccc(-c2ccc(-c3c4ccccc4c(-c4nccc(-c5ccccc5)n4)c4ccccc34)cc2)cc1]

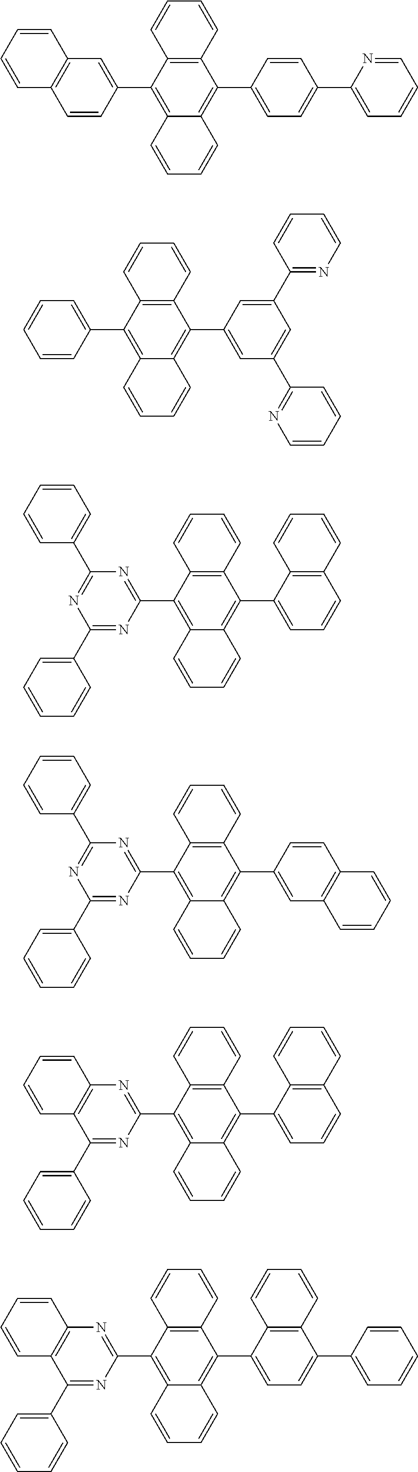

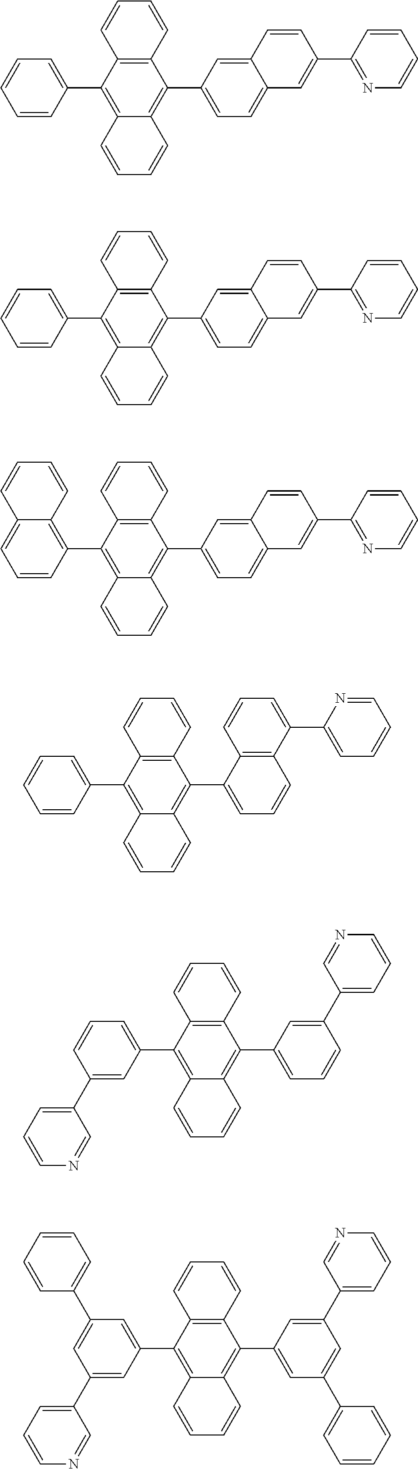 [SMILES: c1ccc(-c2c3ccccc3c(-c3ccc4cc(-c5ccccn5)ccc4c3)c3ccccc23)cc1 ; c1ccc(-c2c3ccccc3c(-c3ccc4cc(-c5ccccn5)ccc4c3)c3ccccc23)cc1 ; c1ccc(-c2ccc3cc(-c4c5ccccc5c(-c5cccc6ccccc56)c5ccccc45)ccc3c2)nc1 ; c1ccc(-c2c3ccccc3c(-c3cccc4c(-c5ccccn5)cccc34)c3ccccc23)cc1 ; c1cncc(-c2cccc(-c3c4ccccc4c(-c4cccc(-c5cccnc5)c4)c4ccccc34)c2)c1 ; c1ccc(-c2cc(-c3cccnc3)cc(-c3c4ccccc4c(-c4cc(-c5ccccc5)cc(-c5cccnc5)c4)c4ccccc34)c2)cc1]

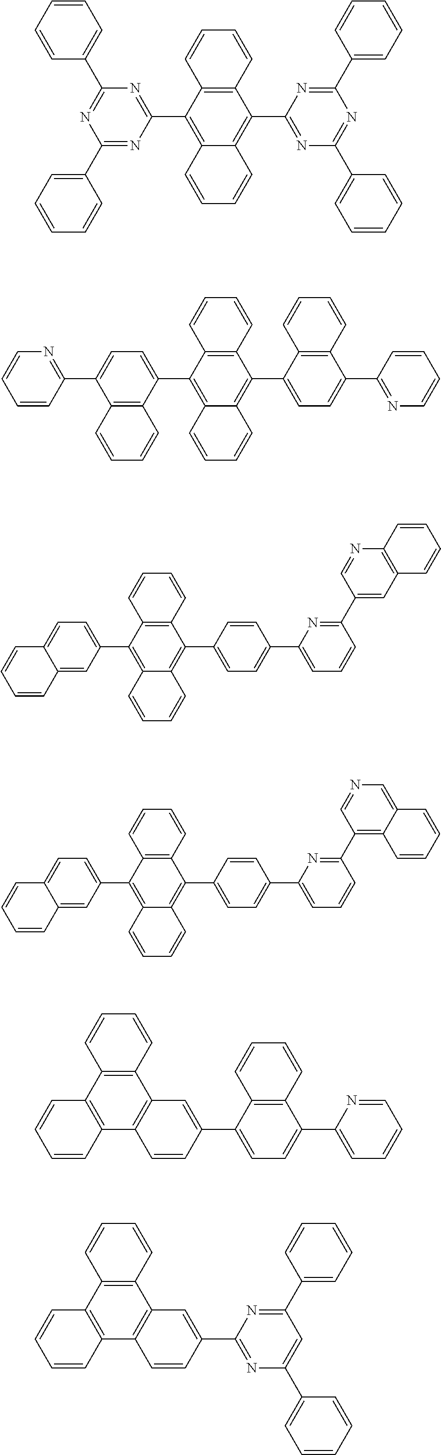 [SMILES: c1ccc(-c2nc(-c3ccccc3)nc(-c3c4ccccc4c(-c4nc(-c5ccccc5)nc(-c5ccccc5)n4)c4ccccc34)n2)cc1 ; c1ccc(-c2ccc(-c3c4ccccc4c(-c4ccc(-c5ccccn5)c5ccccc45)c4ccccc34)c3ccccc23)nc1 ; c1cc(-c2ccc(-c3c4ccccc4c(-c4ccc5ccccc5c4)c4ccccc34)cc2)nc(-c2cnc3ccccc3c2)c1 ; c1cc(-c2ccc(-c3c4ccccc4c(-c4ccc5ccccc5c4)c4ccccc34)cc2)nc(-c2cncc3ccccc23)c1 ; c1ccc(-c2ccc(-c3ccc4c5ccccc5c5ccccc5c4c3)c3ccccc23)nc1 ; c1ccc(-c2cc(-c3ccccc3)nc(-c3ccc4c5ccccc5c5ccccc5c4c3)n2)cc1]

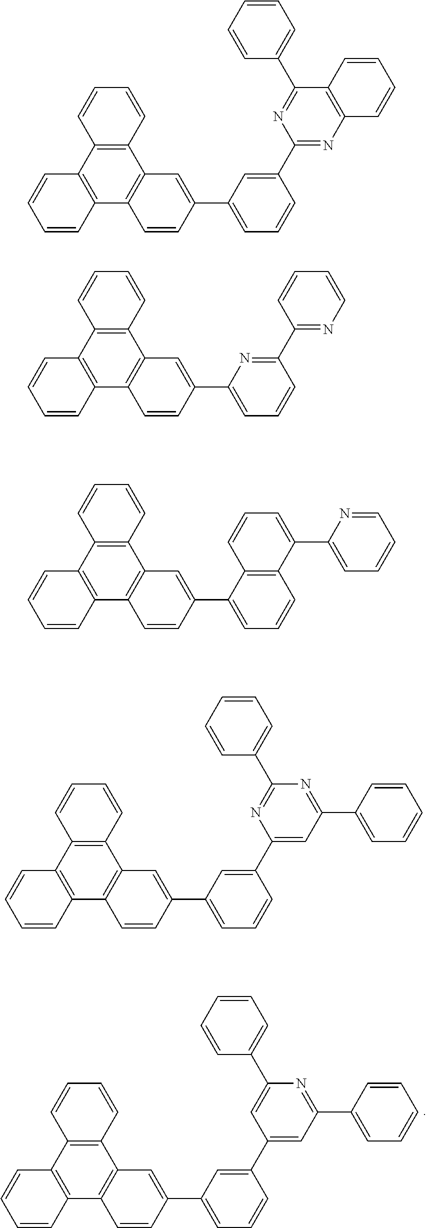

18. The organic light-emitting device as claimed in claim 1, wherein a thickness of the intermediate layer is about 5 Å to about 400 Å.

19. The organic light-emitting device as claimed in claim 1, wherein the organic layer is formed by performing a wet process.

20. A flat panel display comprising the organic light-emitting device as claimed in claim 1, wherein the first electrode of the organic light-emitting device is electrically connected to a source electrode or a drain electrode of a thin film transistor.
